(19) United States
(12) Patent Application Publication
(10) Pub. No.: US 2018/0018565 A1
(43) Pub. Date: Jan. 18, 2018

(54) SEMICONDUCTOR DEVICE, DISPLAY SYSTEM, AND ELECTRONIC DEVICE

(71) Applicant: Semiconductor Energy Laboratory Co., Ltd., Atsugi-shi (JP)

(72) Inventor: Yoshiyuki KUROKAWA, Sagamihara (JP)

(73) Assignee: Semiconductor Energy Laboratory Co., Ltd.

(21) Appl. No.: 15/645,316

(22) Filed: Jul. 10, 2017

(30) Foreign Application Priority Data
Jul. 14, 2016 (JP) 2016-139038

(51) Int. Cl. G06N 3/08; G09G 3/20; G09G 3/36; H01L 27/12

(52) U.S. Cl. CPC G06N 3/08; G09G 3/3225; H01L 27/124; H01L 27/1225; G09G 3/2096; H01L 27/1255; G09G 3/3648; G09G 2300/0426; G09G 2330/023

(57) ABSTRACT

The semiconductor device comprises a controller, a frame memory, and a register. The controller comprises a control circuit and a prediction circuit. The frame memory comprises a memory device and a monitor circuit. The register comprises a first memory circuit and a second memory circuit. The second memory circuit comprises a transistor which includes a metal oxide in a channel formation region. The prediction circuit is configured to predict the necessity of power supply to the register using a neural network and outputting a first signal corresponding to a result of the prediction to the control circuit. The control circuit is configured to save data stored in the first memory circuit to the second memory circuit on the basis of the first signal. The monitor circuit is configured to output a second signal containing information on power consumption of the memory device to the prediction circuit.

### BACKGROUND OF THE INVENTION

### 1. Field of the Invention

One embodiment of the present invention relates to a semiconductor device, a display system, and an electronic device.

Note that one embodiment of the present invention is not limited to the above technical field. Examples of the technical field of one embodiment of the present invention disclosed in this specification and the like include a semiconductor device, a display device, a light-emitting device, a power storage device, a memory device, a display system, an electronic device, a lighting device, an input device, an input/output device, a driving method thereof, and a manufacturing method thereof.

In this specification and the like, a semiconductor device generally means a device that can function by utilizing semiconductor characteristics. A transistor, a semiconductor circuit, an arithmetic device, a memory device, and the like are each an embodiment of the semiconductor device. In addition, an imaging device, an electro-optical device, a power generation device (e.g., a thin film solar cell and an organic thin film solar cell), and an electronic device each may include a semiconductor device.

### 2. Description of the Related Art

Flat panel displays typified by liquid crystal display devices and light-emitting display devices are widely used for displaying video. Although the transistors used in these display devices are mainly manufactured using silicon semiconductors, attention has been recently drawn to a transistor manufacturing technique that uses a metal oxide exhibiting semiconductor characteristics instead of a silicon semiconductor. For example, in Patent Documents 1 and 2, a technique is disclosed in which a transistor manufactured using zinc oxide or an In—Ga—Zn-based oxide as a semiconductor layer is used in a pixel of a display device.

### REFERENCE

### Patent Document

[Patent Document 1] Japanese Published Patent Application No. 2007-96055
[Patent Document 2] Japanese Published Patent Application No. 2007-123861

### SUMMARY OF THE INVENTION

An object of one embodiment of the present invention is to provide a novel semiconductor device. Another object of one embodiment of the present invention is to provide a semiconductor device with low power consumption. Another object of one embodiment of the present invention is to provide a semiconductor device capable of high-speed operation.

One embodiment of the present invention does not necessarily achieve all the objects listed above and only needs to achieve at least one of the objects. The description of the above objects does not preclude the existence of other objects. Other objects will be apparent from and can be derived from the description of the specification, the drawings, the claims, and the like.

A semiconductor device according to one embodiment of the present invention comprises a controller, a frame memory, and a register. The controller comprises a control circuit and a prediction circuit. The frame memory comprises a memory device and a monitor circuit. The register comprises a first memory circuit and a second memory circuit. The second memory circuit comprises a transistor which includes a metal oxide in a channel formation region. The prediction circuit is configured to predict the necessity of power supply to the register using a neural network and to output a first signal corresponding to a result of the prediction to the control circuit. The control circuit is configured to save data stored in the first memory circuit to the second memory circuit on the basis of the first signal. The monitor circuit is configured to output a second signal containing information on power consumption of the memory device to the prediction circuit. The prediction is performed using the second signal as input data.

In the semiconductor device according to one embodiment of the present invention, the neural network may be configured to perform learning with use of a learning signal and a teacher signal. The learning signal may be the second signal. The teacher signal may be a third signal containing information on a change of a video image displayed on a display portion.

In the semiconductor device according to one embodiment of the present invention, the neural network may be configured to perform the learning when the prediction is wrong.

In the semiconductor device according to one embodiment of the present invention, the neural network may comprise a neuron circuit and a synapse circuit. The synapse circuit may comprise an analog memory. The analog memory may comprise a transistor comprising a metal oxide in a channel formation region.

A display system according to one embodiment of the present invention comprises a control portion using the above-described semiconductor device; and a display portion. The control portion is configured to control display on the display portion. The display portion comprises a first display unit and a second display unit. The first display unit comprises a reflective liquid crystal element. The second display unit comprises a light-emitting element.

In the display system according to one embodiment of the present invention, each of the first display unit and the second display unit may comprise a transistor comprising a metal oxide in a channel formation region.

An electronic device according to one embodiment of the present invention comprises the above-described display system and is configured to generate a video signal in response to image data input from the outside and to display video on the basis of the video signal.

According to one embodiment of the present invention, a novel semiconductor device can be provided. According to one embodiment of the present invention, a semiconductor device with low power consumption is provided. According to one embodiment of the present invention, a semiconductor device capable of operating at high speed can be provided.

Note that the description of these effects does not preclude the existence of other effects. One embodiment of the present invention does not necessarily have all of these effects. Other effects will be apparent from and can be derived from the description of the specification, the drawings, the claims, and the like.

### BRIEF DESCRIPTION OF THE DRAWINGS

FIG. 1 shows a structure example of a display system.

FIGS. 2A to 2C each illustrate a configuration example of a neural network.

FIGS. 3A1 to 3C2 show a relationship between video and a waveform.

FIGS. 4A1 to 4B2 show a relationship between video and a waveform.

FIG. 5 is a flowchart showing an operation example of a semiconductor device.

FIG. 6 illustrates a structure example of a display system.

FIG. 7 illustrates a structure example of a display system.

FIGS. 8A and 8B each illustrate a configuration example of a neural network.

FIG. 9 illustrates a configuration example of a neural network.

FIGS. 10A to 10C illustrate structure examples of a hidden synapse circuit, an output synapse circuit, and an analog memory.

FIGS. 11A to 11C illustrate structure examples of an output neuron circuit, an output error circuit, and a hidden error circuit.

FIG. 12 is a flowchart showing an operation example of an arithmetic circuit.

FIG. 13 is a flowchart showing an operation example of an arithmetic circuit.

FIGS. 14A and 14B illustrate a structure example of a memory device.

FIG. 15 illustrates a structure example of a register.

FIG. 16 illustrates a structure example of a register.

FIGS. 17A to 17C each illustrate a structure example of a switch circuit.

FIGS. 18A and 18B each illustrate a structure example of a switch circuit.

FIG. 19 illustrates a structure example of a display system.

FIGS. 20A, 20B1, and 20B2 illustrate a structure example of a display device.

FIG. 21 illustrates a structure example of a pixel.

FIGS. 22A and 22B illustrate a structure example of a pixel.

FIG. 23 illustrates a structure example of a display device.

FIG. 24 illustrates a structure example of a display device.

FIGS. 25A to 25C illustrate a structure example of a transistor.

FIG. 26 shows an energy band structure.

FIG. 27 illustrates a structure example of a circuit.

FIG. 28 illustrates a structure example of a display module.

FIGS. 29A to 29D illustrate structure examples of electronic devices.

FIGS. 30A and 30B show structure examples of a communication system.

### DETAILED DESCRIPTION OF THE INVENTION

Embodiments of the present invention will be described below in detail with reference to the accompanying drawings. Note that one embodiment of the present invention is not limited to the following description of the embodiments and it is easily understood by those skilled in the art that the mode and details can be variously changed without departing from the spirit and scope of the present invention. Therefore, the present invention should not be interpreted as being limited to the description of the embodiments below.

One embodiment of the present invention includes, in its category, devices such as a semiconductor device, a memory device, a display device, an imaging device, and a radio frequency (RF) tag. The display device includes, in its category, a liquid crystal display device, a light-emitting device including pixels each provided with a light-emitting element typified by an organic light-emitting element, electronic paper, a digital micromirror device (DMD), a plasma display panel (PDP), a field emission display (FED), and the like.

In this specification and the like, a metal oxide means an oxide of a metal in a broad sense. Metal oxides are classified into an oxide insulator, an oxide conductor (including a transparent oxide conductor), an oxide semiconductor (also simply referred to as an OS), and the like. For example, a metal oxide used in a channel formation region of a transistor is called an oxide semiconductor in some cases. That is, a metal oxide that has at least one of an amplifying function, a rectifying function, and a switching function can be called a metal oxide semiconductor, or OS for short. In the following description, a transistor including a metal oxide in a channel formation region is also referred to as an OS transistor.

In this specification and the like, a metal oxide including nitrogen is also called a metal oxide in some cases. Moreover, a metal oxide including nitrogen may be called a metal oxynitride.

Furthermore, in this specification and the like, an explicit description “X and Y are connected” means that X and Y are electrically connected, X and Y are functionally connected, and X and Y are directly connected. Accordingly, without limitation to a predetermined connection relation, for example, a connection relation shown in drawings or text, another connection relation is included in the drawings or the text. Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, or a load) is not connected between X and Y, and the case where X and Y are connected without the element that allows the electrical connection between X and Y provided therebetween.

For example, in the case where X and Y are electrically connected, one or more elements that enable an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is turned on or off to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable a functional connection between X and Y (e.g., a logic circuit such as an inverter, a NAND circuit, or a NOR circuit; a signal converter circuit such as a DA converter circuit, an AD converter circuit, or a gamma correction circuit; a potential level converter circuit such as a power supply circuit (e.g., a step-up converter circuit or a step-down converter circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; and/or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

In addition, components denoted by the same reference numerals in different drawings represent the same components unless otherwise specified.

Even when independent components are electrically connected to each other in the drawing, one component has functions of a plurality of components in some cases. For example, when part of a wiring also functions as an electrode, one conductive film functions as a wiring and an electrode. Thus, “electrical connection” in this specification includes, in its category, such a case where one conductive film has functions of a plurality of components.

### Embodiment 1

In this embodiment, a semiconductor device, a display portion, and a display system of one embodiment of the present invention are described.

### <Structure Example of Display System>

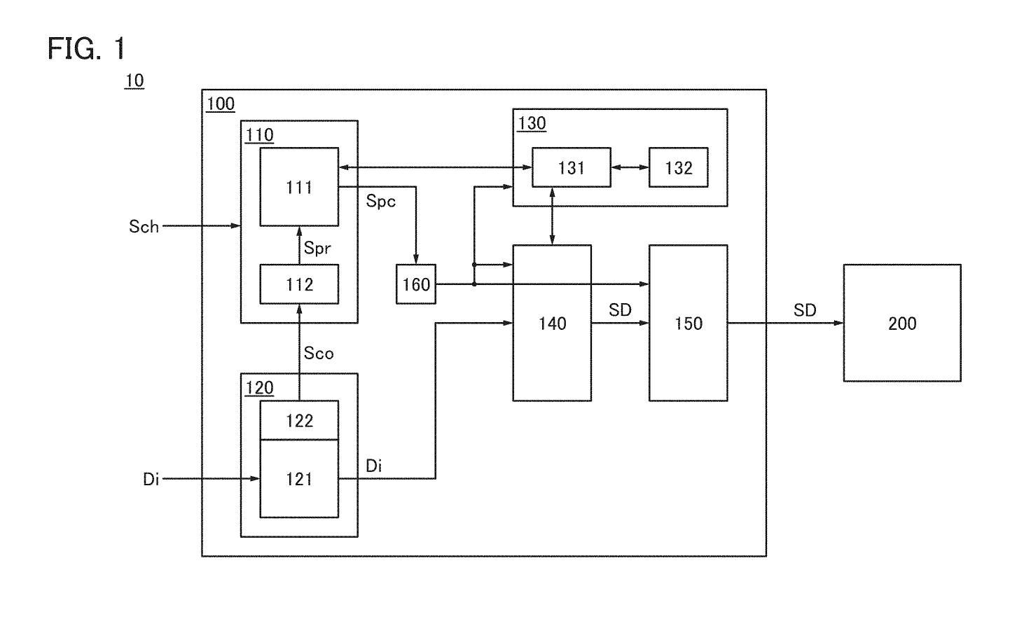

FIG. 1 shows a structure example of a display system 10 including a semiconductor device 100 and a display portion 200. The display system 10 has a function of generating a signal for displaying a predetermined video (hereinafter also referred to as a video signal) and a function of displaying video on the basis of the video signal.

The semiconductor device 100 has a function of generating a video signal and a function of controlling the video displayed on the display portion 200. The display portion 200 has a function of displaying video on the basis of the video signal input from the semiconductor device 100. The semiconductor device 100 in the display system 10 can be used for a control portion for controlling the display on the display portion 200. The details of the semiconductor device 100 and the display portion 200 will be described below.

The semiconductor device 100 includes a controller 110, a frame memory 120, a register 130, an image processing portion 140, a driver circuit 150, and a switch circuit 160.

The controller 110 has a function of controlling operations of the various kinds of circuits included in the semiconductor device 100. The controller 110 includes a control circuit 111 and a prediction circuit 112.

The control circuit 111 has a function of generating a signal for controlling operations of the circuits, such as the register 130, the image processing portion 140, the driver circuit 150, and the switch circuit 160, in accordance with a signal that is input from the outside. The prediction circuit 112 has a function of predicting, in accordance with a signal that is input from the outside, whether or not the semiconductor device 100 performs a predetermined operation. The predetermined operation is, for example, power supply as described later. The prediction result by the prediction circuit 112 is output to the control circuit 111 as a signal Spr. The control circuit 111 generates the signal for controlling operations of the circuits in accordance with the signal Spr.

Note that the prediction circuit 112 may be provided outside the semiconductor device 100. In that case, the signal Spr is input from the outside of the semiconductor device 100 to the control circuit 111.

The frame memory 120 is a memory portion having a function of storing image data (data Di) that corresponds to video displayed on the display portion 200 and outputting the data Di to the image processing portion 140. The frame memory 120 includes a memory device 121 and a monitor circuit 122.

The memory device 121 has a function of storing the data Di that is input from the outside. In addition, the memory device 121 has a function of outputting the data Di to the image processing portion 140. The monitor circuit 122 has a function of detecting information on power consumption of the memory device 121. The information detected by the monitor circuit 122 is output to the prediction circuit 112 as a signal Sco. Then, the prediction circuit 112 performs prediction on the basis of the signal Sco.

The register 130 has a function of storing data that is used for operations of the various kinds of circuits included in the semiconductor device 100. The data stored in the register 130 includes data the controller 110 uses in processing and data the image processing portion 140 uses in processing. The register 130 includes memory circuits 131 and 132.

Each of the memory circuits 131 and 132 has a function of storing data used for operations of the various kinds of circuits included in the semiconductor device 100. Data input to the register 130 from the outside and data output to the outside from the register 130 are stored in the memory circuit 131.

The memory circuit 132 has a function of storing data transferred from the memory circuit 131. Specifically, the memory circuit 132 has a function of holding the data stored in the memory circuit 131 when the data is saved into the memory circuit 132. Note that a transfer of data stored in the register 130 is controlled by the control circuit 111.

The memory circuit 132 is a circuit that can hold data even in a period during which no power is supplied to the memory circuit 132. In other words, the memory circuit 132 serves as a non-volatile memory circuit. Thus, it is possible to stop the power supply to the register 130 with the data held in the register 130. Note that a transistor whose off-state current is extremely small is preferably used in the memory circuit 132 in order to hold data stored in the memory circuit 132 even in a period during which power supply is stopped.

Here, an OS transistor is preferable as the transistor of the memory circuit 132. A metal oxide has a larger energy gap and a lower minority carrier density than a semiconductor of silicon or the like; therefore, the off-state current of a transistor containing the metal oxide can be extremely small. Accordingly, when an OS transistor is used in the memory circuit 132, a potential held in the memory circuit 132 can be held for a long time as compared with when a transistor containing silicon in its channel formation region (hereinafter also referred to as a Si transistor) is used. Thus, data can be held for a longer time even in a period during which the power supply to the register 130 is stopped. A specific structure example of the register 130 will be described in Embodiment 3.

The image processing portion 140 has a function of generating a video signal. Specifically, the image processing portion 140 has a function of generating a signal SD corresponding to the video signal by performing various kinds of image processing on the data Di input from the frame memory 120. For example, the image processing portion 140 has a function of performing gamma correction, light control, or color control.

The driver circuit 150 is a circuit having a function of supplying the signals SD to the display portion 200 at a predetermined timing. When the signal SD is input from the image processing portion 140 to the driver circuit 150, the signal SD is output from the driver circuit 150 to the display portion 200 at a predetermined timing. On the input of the signal SD, the display portion 200 displays a predetermined video in accordance with the signal SD. Note that the driver circuit 150 may be provided in the display portion 200.

The switch circuit 160 has a function of controlling the power supply to the register 130, the image processing portion 140, or the driver circuit 150. When a signal Spc for controlling the power supply is input from the control circuit 111 to the switch circuit 160, the conduction state of the switch circuit 160 is controlled in accordance with the signal Spc, and the power supply to the register 130, the image processing portion 140, or the driver circuit 150 is controlled. With the switch circuit 160, the power gating of the register 130, the image processing portion 140, or the driver circuit 150 can be performed.

In the configuration shown in FIG. 1, the power supply to the register 130, the image processing portion 140, and the driver circuit 150 is controlled by the switch circuit 160. Note that the power gating of the image processing portion 140 and the driver circuit 150 is not necessarily performed.

The switch circuit 160 can be formed using an OS transistor, in which case leakage of power can be reduced to be extremely low in a period during which power supply is stopped. A specific structure example of the switch circuit 160 will be described in Embodiment 3.

When there is no change in the video displayed on the display portion 200, or when the change is below a certain level, rewriting of the video can be skipped. In that case, generation of the signal SD in the semiconductor device 100 can be skipped, and thus the register 130, the image processing portion 140, or the driver circuit 150 performs no processing (stops operating). In the period during which the register 130, the image processing portion 140, or the driver circuit 150 stops operating under the control of the switch circuit 160, power supply to these circuits is stopped, whereby power consumption of the semiconductor device 100 can be reduced.

The necessity of the power supply to the register 130, the image processing portion 140, or the driver circuit 150 depends on a signal Sch input to the controller 110. The signal Sch is a signal containing information on a change of video displayed on the display portion 200. As the signal Sch, for example, a signal showing that the data Di is not input successively (that is, that the next image data has not yet been input), a control signal showing that there is no change in the content of the data Di, or the like can be used. When the signal Sch shows that there is no change in the video displayed on the display portion 200, or when the signal Sch shows that the change is below a certain level, power supply is stopped by the switch circuit 160.

Note that when the power supply to the register 130 is stopped, data stored in the memory circuit 131 is erased. However, the data stored in the register 130 can be held even in the period during which power supply is stopped in the case where the data stored in the memory circuit 131 is saved in advance into the memory circuit 132.

Note that before the power supply to the register 130 is stopped, the data stored in the memory circuit 131 needs to be saved into the memory circuit 132 after checking that there is no change in the video displayed on the display portion 200 or the change is below a certain level. Thus, the preparation period for the power gating of the register 130 is long; as a result, a reduction in the operation speed or in the effect of reducing power consumption of the semiconductor device 100 might occur.

However, in one embodiment of the present invention, the necessity of power supply can be predicted by the prediction circuit 112. Specifically, the prediction circuit 112 predicts the necessity of power supply on the basis of the signal Sco and outputs the signal Spr corresponding to the prediction result to the control circuit 111. When the signal Spr has a prediction result showing “power supply will be stopped”, the control circuit 111 outputs a control signal for saving data into the register 130 regardless of the presence or absence of the input of the signal Sch. In this manner, the stored data can be saved into the register 130 without waiting for the input of the signal Sch. Thus, the power gating of the register 130 can be performed at high speed.

Moreover, the prediction circuit 112 has a function of performing learning and prediction using a neural network. Specifically, the prediction circuit 112 can perform supervised learning using the signal Sco input from the monitor circuit 122 as a learning signal and using the signal Sch as a teacher signal. After performing the learning, the prediction circuit 112 predicts the necessity of power supply using the signal Sco as input data and outputs the signal Spr corresponding to the prediction result to the control circuit 111. In this manner, the neural network is used in the prediction circuit 112, and prediction can be performed with high accuracy.

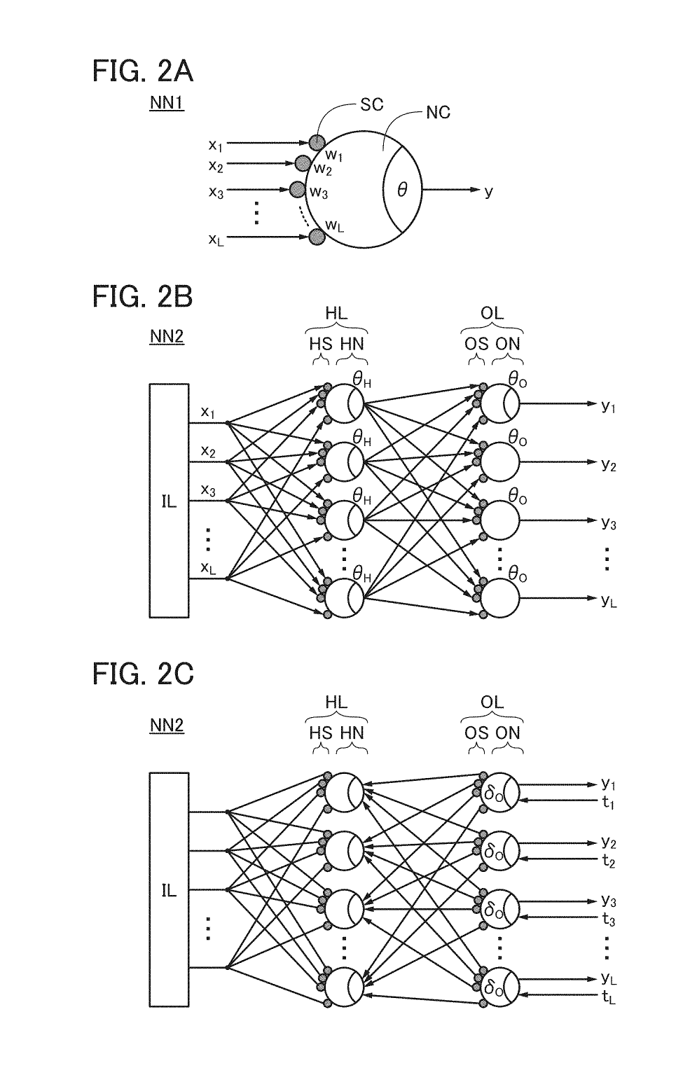

The neural network used for the prediction circuit 112 includes neuron circuits and a synapse circuit provided between the neuron circuits. FIG. 2A illustrates a configuration example of the neural network.

A neural network NN1 includes a neuron circuit NC and synapse circuits SC. Input data x₁ to x_{L} (L is a natural number) are input to the synapse circuits SC. In addition, the synapse circuits SC each have a function of storing a weight coefficient wᵢ (i is an integer greater than or equal to 1 and less than or equal to L). The weight coefficient wᵢ corresponds to the bonding strength between the neuron circuits NC.

When the input data x₁ to x_{L} are input to the synapse circuits SC, the sum of the products (xᵢwᵢ) for i=1 to L (i.e., x₁w₁+x₂w₂+ . . . +x_{L}w_{L}) of input data xᵢ input to the synapse circuit SC and the weight coefficient wᵢ stored in the synapse circuit SC, that is, a value obtained by the product-sum operation of xᵢ and wᵢ is supplied to the neuron circuit NC. When the value is larger than the threshold θ_{O} of the neuron circuit NC, the neuron circuit NC outputs a high-level signal. This phenomenon is referred to as firing of the neuron circuit NC.

FIG. 2B shows a model of a hierarchical perceptron neural network using the neuron circuits NC and the synapse circuits SC. The neural network NN2 includes an input layer IL, a hidden layer HL, and an output layer OL.

The input data xᵢ to x_{L} are output from the input layer IL. The hidden layer HL includes a hidden synapse circuit HS and hidden neuron circuits HN. The output layer OL includes output synapse circuits OS and output neuron circuits ON.

A value obtained by the product-sum operation using the input data xi and the weight coefficient wᵢ that is held in the hidden synapse circuit HS is supplied to the hidden neuron circuit HN. A value obtained by the product-sum operation using the output of the hidden neuron circuit HN and the weight coefficient w that is held in the output synapse circuit OS is supplied to the output neuron circuit ON. Output data y₁ to yₙ are output from the output neuron circuit ON. Note that a plurality of hidden layers HL may be provided in the neural network NN2.

As described above, the neural network NN2 to which a given input data is supplied has a function of outputting output data that is a value corresponding to a weight coefficient held in the synapse circuit SC and a threshold θ of the neuron circuit.

In addition, the neural network NN2 can perform supervised learning by the input of a teacher signal. FIG. 2C shows a model of the neural network NN2 which performs supervised learning using backpropagation.

Backpropagation is a method for changing a weight coefficient wᵢ of a synapse circuit so that the error between output data from a neural network and a teacher signal is reduced. Specifically, a weight coefficient wᵢ of the hidden synapse circuit HS is changed in accordance with an error δ_{O} that is determined on the basis of the output data y₁ to yₙ and the teacher signals t₁ to tₙ. In addition, a weight coefficient wᵢ of a synapse circuit SC in the previous stage is changed in accordance with the amount of change in the weight coefficient wᵢ of the hidden synapse circuit HS. In this manner, weight coefficients of the synapse circuits SC are sequentially changed on the basis of the teacher signals t₁ to tₙ, so that the neural network NN2 can perform learning.

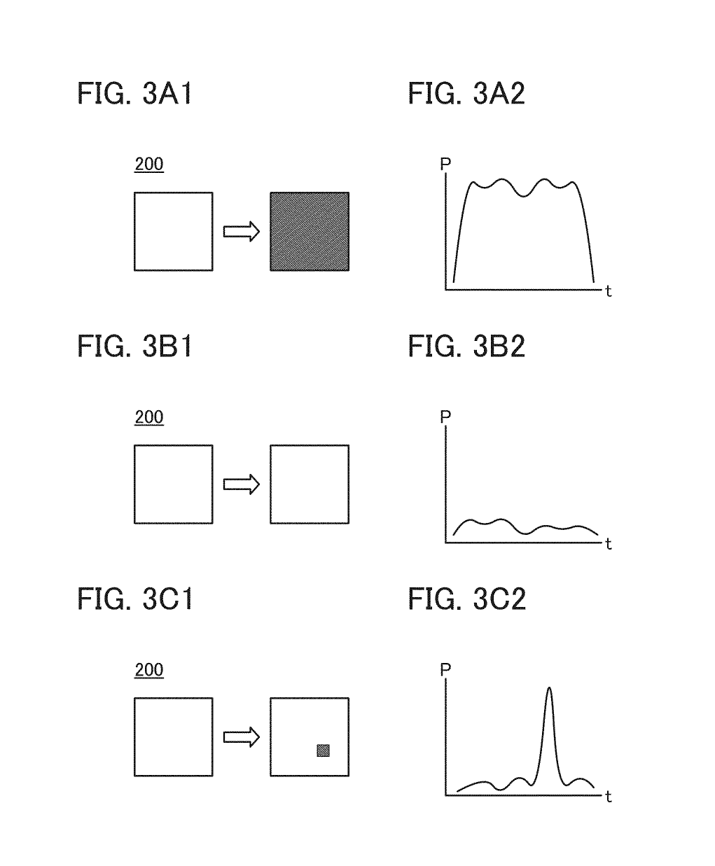

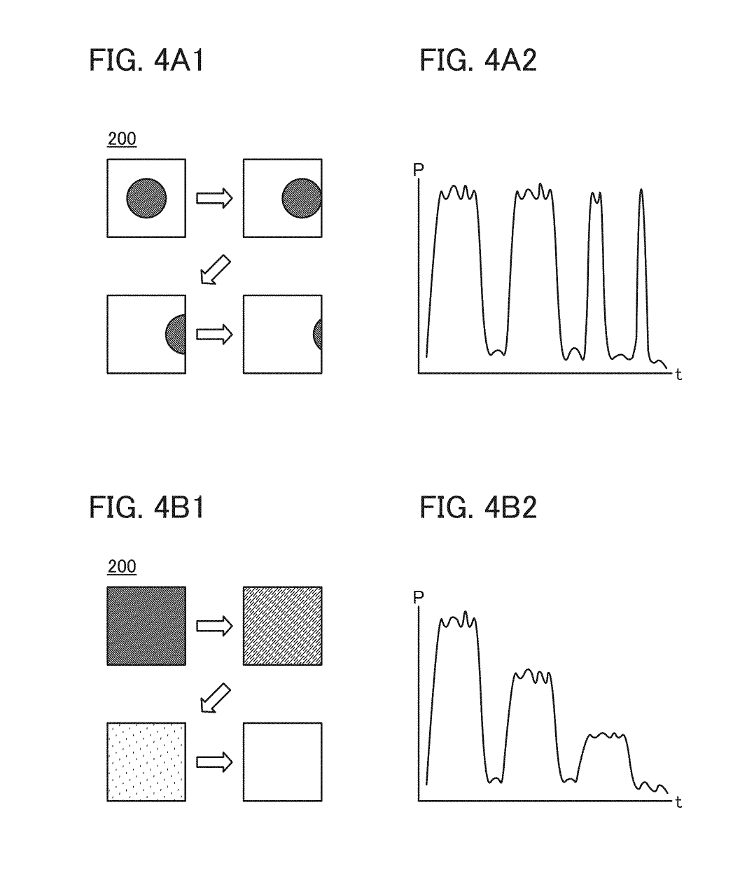

The neural network of the prediction circuit 112 can perform learning using the signal Sco input from the monitor circuit 122 as a learning signal. The signal Sco is a signal Sco containing information on power consumption of the memory device 121. As the signal, a waveform of a signal showing a change in power consumption over time; a signal showing the total amount, average, decrement, increment, maximum value or minimum value of power consumption; or the like can be used without particular limitation. In examples shown in FIGS. 3A1 to 3C2 and FIGS. 4A1 to 4B2, the waveform showing a change in power consumption over time of the memory device 121 (time t on the horizontal axis, power consumption P on the vertical axis) is input as the signal Sco to the prediction circuit 112.

For example, when data Di for rewriting the entire video displayed on the display portion 200 is input to the memory device 121 (FIG. 3A1), the power consumption P shown by the signal Sco can show a tendency to increase on the whole (FIG. 3A2). When data Di input to the memory device 121 does not show a change in video (FIG. 3B1), the power consumption P shown by the signal Sco can show a tendency to remain at a low level (FIG. 3B2). When data Di for rewriting part of the video is input to the memory device 121 (FIG. 3C1), the signal Sco can show a tendency to have a peak with a width smaller than a width in FIG. 3A2 (FIG. 3C2).

When data Di corresponding to video of an object which gradually moves out of the display is input to the memory device 121 (FIG. 4A1), the signal Sco can show a plurality of peaks which have similar widths and heights and then show a plurality of peaks whose widths are gradually reduced the (FIG. 4A2). When data Di corresponding to video which fades away is input to the memory device 121 (FIG. 4B1), the signal Sco can show a plurality of peaks gradually lowering in heights (FIG. 4B2).

Thus, the waveform showing a change over time in power consumption of the memory device 121 can have various characteristic shaps depending on video displayed on the display portion 200. Thus, when the change over time in power consumption is monitored, the presence or absence of a change of video displayed on the display portion 200 and large and small of the change can be predicted. The necessity of power supply can be predicted by using the signal Sco.

Pattern matching in which the signal Sco is compared with a pattern of a particular waveform can be used for the prediction. However, a large number of events occur in the waveform pattern matching. Accordingly, it takes much time in the comparison, and moreover, the number of waveform patterns that should be prepared for the comparison is large. In contrast, the above-described prediction using the signal Sco as an input signal for a neural network is more efficient.

Note that the video-waveform relationships shown in FIGS. 3A1 to 3C2 and FIGS. 4A1 to 4B2 are only examples and are not necessarily obtained. Prediction is achieved using the signal Sco as an input signal for a neural network as long as a change in video is somehow reflected to a waveform.

### <Operation Example of Semiconductor Device>

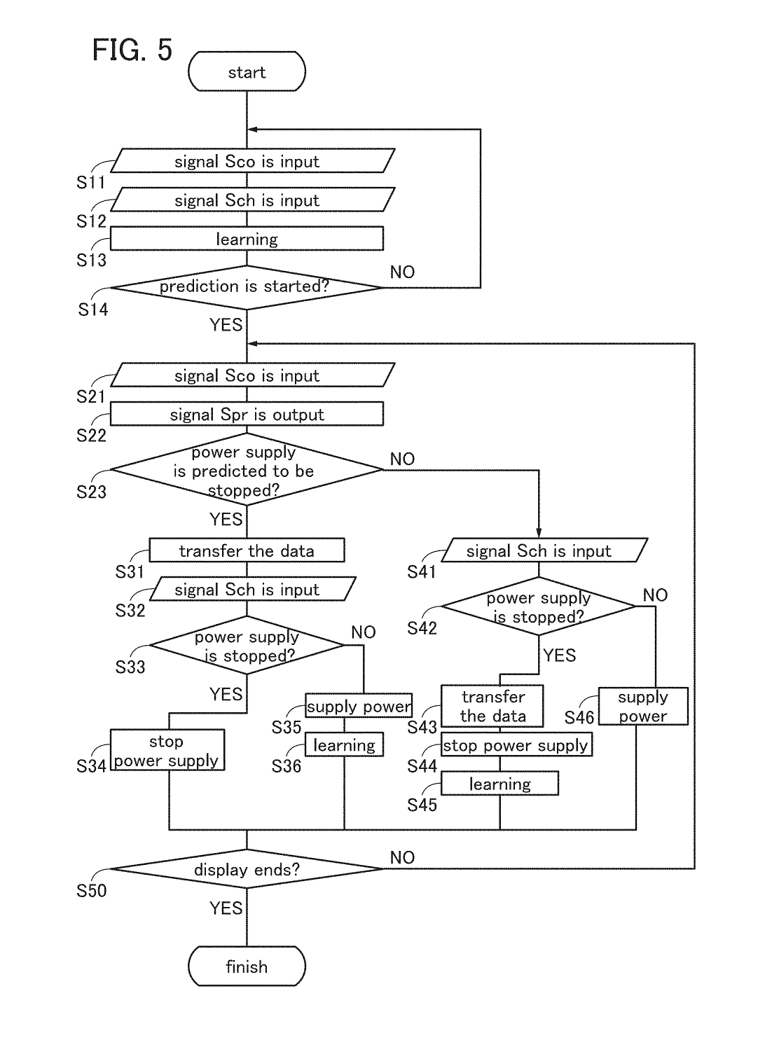

Next, an operation example of the semiconductor device 100 is specifically described. FIG. 5 is a flow chart showing the operation example of the semiconductor device 100. Mainly described here is an operation example of the prediction circuit 112 performing leaning and prediction using a neural network. Note that operation from Step S11 to Step S14 in FIG. 5 corresponds to learning by a neural network of the prediction circuit 112 (hereinafter also referred to as learning operation), and operation from Step S21 to Step S50 corresponds to prediction together with the learning by a neural network of the prediction circuit 112 (hereinafter also referred to as predicting operation). Note that the prediction is made by an inference (recognition) by the neural network.

Described below is an operation example in which the power supply to the register 130 is stopped when there is no change in video displayed on the display portion 200. However, as shown in FIG. 1, power gating of other circuits such as the image processing portion 140 or the driver circuit 150 may be performed as well.

### [Learning Operation]

First, the signal Sco is input to the prediction circuit 112 (Step S11). The signal Sco is a signal containing information on power consumption of the memory device 121 and is used here as a learning signal for a neural network. Then, the signal Sch is input to the prediction circuit 112 (Step S12). A signal showing the presence or absence of change in video displayed on the display portion 200 is used here as the signal Sch. The signal Sch is used here as a teacher signal for a neural network showing the necessity of the power supply to the register 130. Note that the input of the signal Sco to the prediction circuit 112 may be performed after the input of the signal Sch.

Then, the neural network performs supervised learning using the signal Sco and the signal Sch (Step S13). With the supervised learning, the prediction circuit 112 can predict the necessity of the power supply to the register 130 on the basis of the signal Sco.

When the learning continues without prediction (NO in Step S14), the neural network continues learning using new learning and teacher signals. In contrast, when prediction is started using the neural network which has performed the learning (YES in Step S14), the operation of the prediction circuit 112 moves to a predicting operation.

### [Predicting Operation]

In the predicting operation, first, the signal Sco is input to the prediction circuit 112 (Step S21). The signal Sco is used here as input data for the neural network. Then, the neural network predicts the necessity of the power supply to the register 130 on the basis of the signal Sco. The prediction result is output to the control circuit 111 as the signal Spr.

When the neural network predicts that the power supply to the register 130 will be stopped (YES in Step S23), the control circuit 111 outputs a control signal to the register 130 and transfers the data stored in the memory circuit 131 to the memory circuit 132 (Step S31). As a result, speculative saving of data stored in the register 130 is executed.

After that, the signal Sch is input to the control circuit 111 (Step S32), and the control circuit 111 determines whether to practically stop the power supply to the register 130 on the basis of the signal Sch. When the control circuit 111 determines to stop the power supply (YES in Step S33), the control circuit 111 outputs the signal Spc to the switch circuit 160 to stop the power supply to the register 130 (Step S34).

When the power supply is determined to be stopped in Step S33, the data saving in the register 130 has been already completed on the basis of the prediction in Step S23. Thus, there is no need to save data after the determination to stop the power supply, and thus, the power gating of the register 130 can be performed at high speed. In addition, a period during which the power supply is stopped can be increased, and power consumption can be efficiently reduced.

In contrast, when determining not to stop the power supply (NO in Step S33), the control circuit 111 outputs the signal Spc to the switch circuit 160 to supply power to the register 130 (Step S35). Then, the register 130 performs processing for generating a video signal.

Although the power supply is predicted to be stopped in Step S23, it is sometimes practically determined in Step S33 not to stop the power supply, which means the prediction by the prediction circuit 112 is wrong. In that case, the neural network performs learning with use of the signal Sco input in Step S21 and the signal Sch input in Step S32 as a learning signal and a teacher signal, respectively (Step S36). The prediction result on the basis of the signal Sco is corrected in this manner to increase the success rate of the following prediction.

When the neural network predicts that the power supply will not be stopped (NO in Step S23), the control circuit 111 does not save data in the register 130 and waits for the input of the signal Sch. Then, the signal Sch is input to the control circuit 111 (Step S41). The control circuit 111 determines whether to practically stop the power supply on the basis of the signal Sch.

When determining to stop the power supply (YES in Step S42), the control circuit 111 outputs a control signal to the register 130 and transfers the data stored in the memory circuit 131 to the memory circuit 132 (Step S43). Then, the control circuit 111 outputs the signal Spc to the switch circuit 160 and stops the power supply to the register 130 (Step S44). In such a case that speculative saving of the data stored in the register 130 is not executed at the determination of the necessity of the power supply on the basis of the signal Sch, the power supply to the register 130 is stopped after the data is saved as in normal cases.

Although the power supply is predicted not to be stopped in Step S23, it is sometimes practically determined in Step S42 to stop the power supply, which means the prediction by the prediction circuit 112 is wrong. In that case, the neural network performs learning with use of the signal Sco input in Step S21 and the signal Sch input in Step S41 as a learning signal and a teacher signal, respectively (Step S45). The prediction result on the basis of the signal Sco is corrected in this manner to increase the success rate of the following prediction.

In contrast, when determining not to stop the power supply (NO in Step S42), the control circuit 111 outputs the signal Spc to the switch circuit 160 to supply power to the register 130 (Step S46). Then, the register 130 performs processing for generating a video signal.

When the display of video on the display portion 200 ends after Step S34, S36, S45, or S46 (YES in Step S50), the prediction circuit 112 finishes prediction. In contrast, when the display of video on the display portion 200 continues (NO in Step S50), the prediction circuit 112 continues prediction (Step S21).

In the above prediction operation, the neural network predicts using the signal Sco and can also perform learning using the signal Sco as a learning signal when the prediction fails. Thus, the prediction circuit 112 can predict the necessity of power supply with the prediction accuracy increasing.

With the above-described operation, the semiconductor device 100 can predict a stop of the power supply to the register 130 and execute speculative saving of data. As a result, the increase in operation rate and the reduction in power consumption of the semiconductor device 100 can be achieved.

### <Modification Example of Display System>

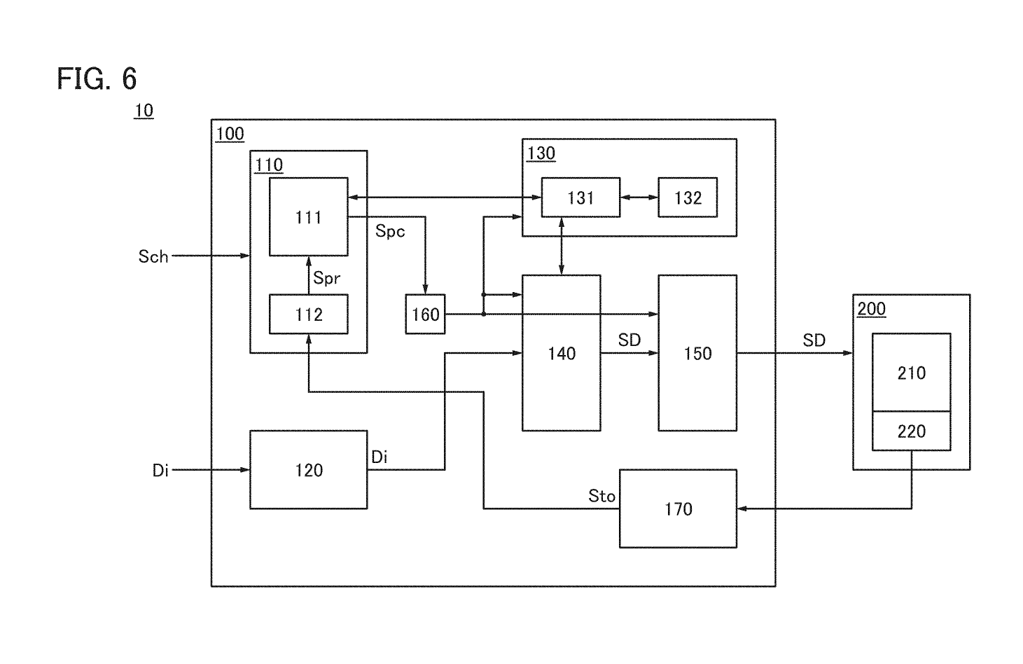

The prediction of a stop of power supply in the semiconductor device is performed on the basis of, but not limited to, the signal Sco. FIG. 6 shows another structure example of the display system 10. The semiconductor device 100 shown in FIG. 6 includes a touch sensor controller 170 instead of the monitor circuit 122 in FIG. 1. The display portion 200 in FIG. 6 includes a display unit 210 and a touch sensor unit 220.

The display unit 210 has a function of displaying video on the basis of the signal SD. The touch sensor unit 220 has a function of detecting information on a touch (hereinafter also referred to touch information), such as the presence or absence of a touch, the position of a touch, the period of time of a touch, and the movement of a touch. Video displayed on the display unit 210 can be switched on the basis of touch information the touch sensor unit 220 detects.

The touch sensor controller 170 has a function of controlling the operation of the touch sensor unit 220. The touch sensor controller 170 has a function of performing, if necessary, signal processing on touch information input from the touch sensor unit 220 and outputting the touch information as the signal Sto to the prediction circuit 112. In other words, the touch sensor controller 170 serves as a monitor circuit that monitors touch information.

The touch information relates to the change of video displayed on the display unit 210. For example, the contents and retention period of video displayed on the display unit 210 can be predicted depending on touch operations. In addition, the time interval of touch operations for switching video on the display unit 210 (e.g., operation of turning the pages), successive touch operations, and the like reflect user's habits and have a rule in some cases. Thus, the signal Sto containing touch information can be used as input data for predicting the presence or absence of a change of video, that is, the necessity of power supply to the register 130.

The signal Sto input to the prediction circuit 112 can be used as input data for a neural network of the prediction circuit 112 or a learning signal. Furthermore, the necessity of interruption of power supply is predicted on the basis of the signal Sto, and the speculative saving of data stored in the register 130 can be executed. Note that the operation of the prediction circuit 112 when the signal Sto is input is similar to that when the signal Sco is input.

Note that the prediction circuit 112 can perform learning while predicting as described above. The longer the user uses the display system 10, the more the neural network can perform learning and store information of user's habits. When a user continues to use it, the prediction accuracy of the display system 10 can be improved in accordance with the user.

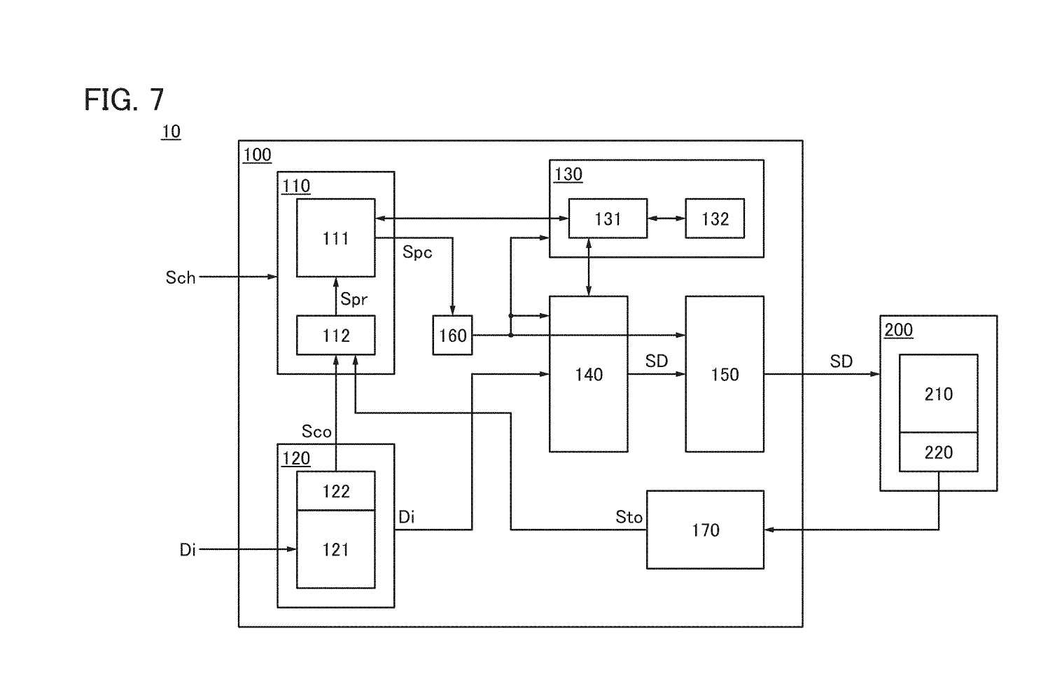

The semiconductor device 100 may include both of the monitor circuit 122 shown in FIG. 1 and the touch sensor controller 170 shown in FIG. 6. A structure example of the display system 10 with the semiconductor device 100 including the monitor circuit 122 and the touch sensor controller 170 is shown in FIG. 7.

In FIG. 7, the prediction circuit 112 in the semiconductor device 100 can predict the necessity of interruption of power supply using both of the signal Sco and the signal Sto as input data. Moreover, the prediction circuit 112 can perform learning with a neural network using both of the signal Sco and the signal Sto as learning signals. Owing to this, the success rate of prediction by the prediction circuit 112 can be increased. Moreover, the learning efficiency of neural network can be increased.

As described above, in one embodiment of the present invention, the necessity of power supply can be predicted with a neural network, in which a signal containing information on power consumption or a signal containing touch information is used as input data. The speculative saving of data stored in a register can be executed. The operation speed of a semiconductor device can be increased. The power consumption can be reduced.

In addition, one embodiment of the present invention can perform data saving at high speed owing to a memory circuit in which a register includes an OS transistor. As a result, the operation speed of the semiconductor device can be increased.

This embodiment can be combined with any of the other embodiments as appropriate.

### Embodiment 2

In this embodiment, a configuration example of a neural network that can be used for the prediction circuit described in the above embodiment is described.

### <Configuration Example of Neural Network>

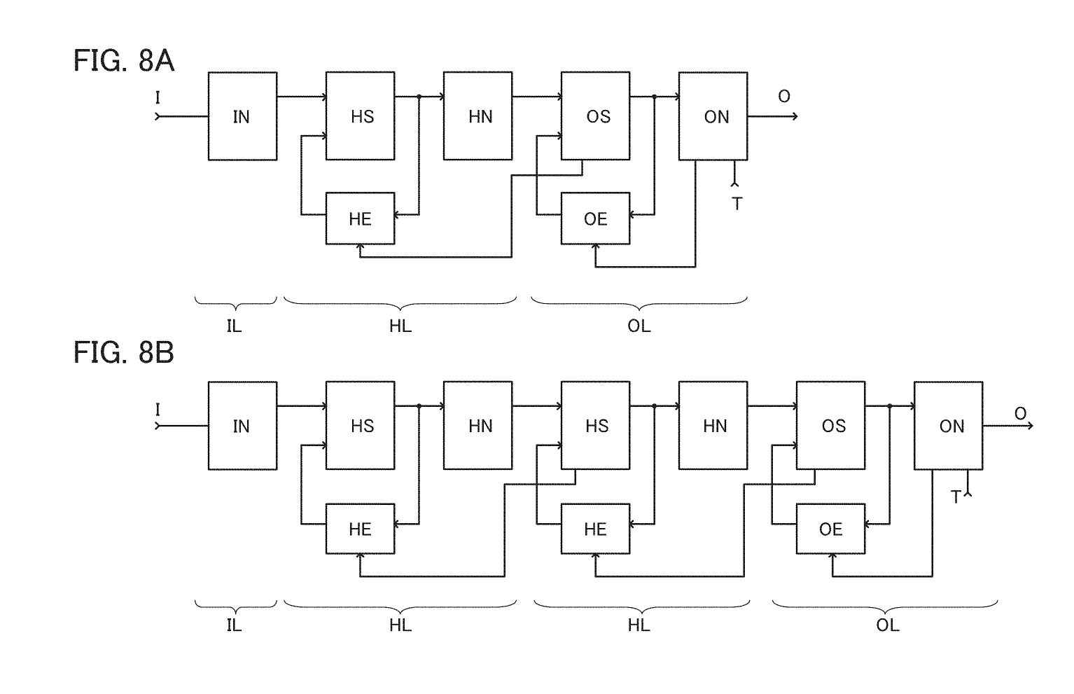

FIGS. 8A and 8B are block diagrams showing specific configuration examples of a neural network that can be used for the prediction circuit 112. FIG. 8A shows the input neuron circuit IN, the hidden neuron circuit HN, the output neuron circuit ON, the hidden synapse circuit HS, the output synapse circuit OS, a hidden error circuit HE, and an output error circuit OE. In the configuration shown in FIG. 8A, the input layer IL includes the input neuron circuit IN; the hidden layer HL includes the hidden neuron circuit HN, the hidden synapse circuit HS, and the hidden error circuit HE; and the output layer OL includes the output error circuit OE, the output neuron circuit ON, and the output synapse circuit OS. Note that a signal I, a signal T, and a signal O correspond to an input signal, a teacher signal T, and an output signal, respectively.

Note that the number of hidden layers HL may be two or more as shown in FIG. 8B. With such a structure, more complex learning can be achieved.

When the signal Sco containing information on power consumption of the memory device 121 (see FIG. 1) or the signal Sto containing touch information (see FIG. 6) is used as the signal I, an output signal corresponding to the prediction result on the necessity of power supply to the circuits such as the register 130 can be obtained.

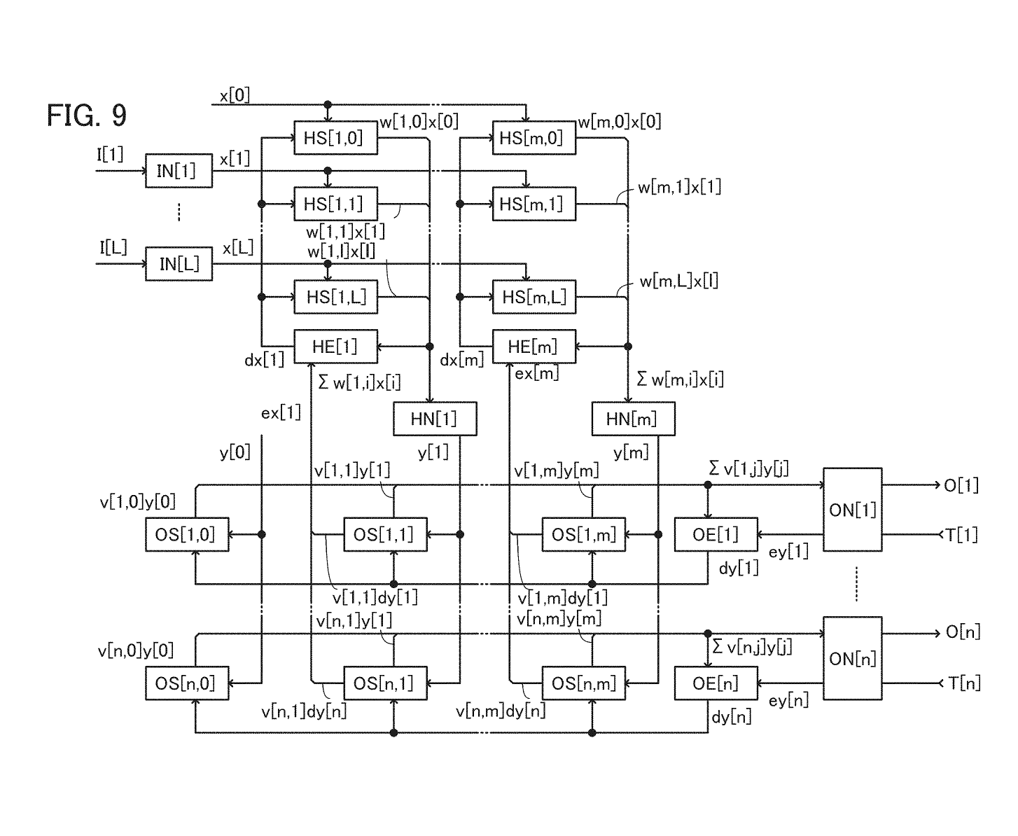

FIG. 9 is a block diagram showing the details of the configuration example of the neural network shown in FIGS. 8A and 8B. FIG. 9 shows the neural network including L input neuron circuits IN (L is a natural number), m hidden neuron circuits HN (m is a natural number), n output neuron circuits ON (n is a natural number), (L+1)×m hidden synapse circuits HS, (m+1)×n output synapse circuits OS, m hidden error circuits HE, and n output error circuits OE.

The circuit block diagram in FIG. 9 is described below.

An input neuron circuit IN[i] amplifies an input signal I[i] from the outside of the neural network with an amplifier or the like and generates an output signal x[i].

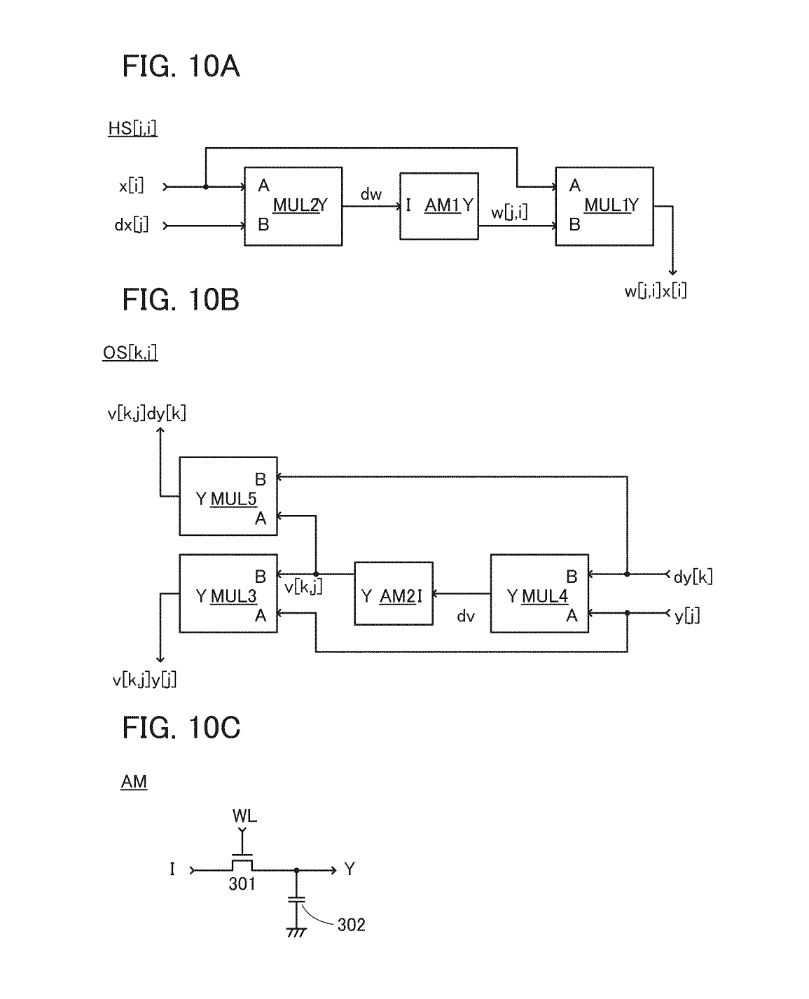

FIG. 10A shows a configuration of a hidden synapse circuit HS[j,i] (j and i are each a natural number). The hidden synapse circuit HS[j,i] includes an analog memory AM1, a multiplier circuit MUL1, and a multiplier circuit MUL2. The analog memory AM1 is configured to store data corresponding to a weight coefficient w[j,i] and output corresponding voltage. The multiplier circuit MUL1 is configured to multiply an output signal x[i] of the input neuron circuit IN by the weight coefficient w[j,i] stored in the analog memory AM1 to produce an output signal w[j,i]x[i]. Note that as the output signal w[j,i]x[i], current corresponding to the multiplication result is supplied. The multiplier circuit MUL2 is configured to multiply the output signal x[i] of the input neuron circuit IN by an output signal dx[j] of a hidden error circuit HE[j] to produce a signal dw. As the signal dw, current corresponding to the multiplication result is supplied. The signal dw is supplied as current corresponding to the amount of change in the weight coefficient w[j,i] stored in the analog memory AM1. That is, the multiplier circuit MUL2 corresponds to a writing circuit which changes data in the analog memory AM1. Note that in hidden synapse circuits HS[1,0] to HS[m,0], an input signal x[0] is supplied with −1, and the weight coefficients w[1,0] to w[m,0] are supplied with θ_{H}[1] to θ_{H}[m]; thus, current corresponding to −θ_{H}[1] to −θ_{H}[m] are supplied as output signals w[1,0]x[0] to w[m,0]x[0]. Note that the hidden synapse circuit HS is simply referred to as a circuit, in some cases.

The hidden neuron circuit HN[j] includes a resistor 321 which converts an input signal X into voltage and an amplifier which generates an output signal y[j]. The input signal X corresponds to Σ_{i=0˜L}w[j,i]x[i] that is the sum of the output signals w[j,i]x[i] (current) of the hidden synapse circuits HS[j,i]. The output signal y[j] from the amplifier has characteristics of f_{H}(X) in Formula 1 or characteristics approximated thereto when the input signal X is a variable.

[Formula 1]

f_{H}(X)=1/(1+e^{-α}^{_{H}}^{X}) (1)

In Formula 1, α_{H} is an arbitrary constant, which corresponds to the change rate of the output signal when X is 0. When Σ_{i=0˜L}w[j,i]x[i], which corresponds to the input signal X, exceeds 0, that is, when Σ_{i=1˜L}w[j,i]x[i] exceeds the threshold value MA f_{H}(X), which corresponds to the output signal y[j], comes close to 1, that is, becomes “H” (referred to as a high level or H level), which is expressed as firing of the hidden neuron circuit HN[j]. That is, the threshold value θ_{H} corresponds to a threshold value at which the hidden neuron circuit HN[j] fires.

FIG. 10B shows a configuration of an output synapse circuit OS[k,j]. The output synapse circuit OS[k,j] includes an analog memory AM2, a multiplier circuit MUL3, a multiplier circuit MUL4, and a multiplier circuit MUL5. The analog memory AM2 is configured to store data corresponding to the weight coefficient v[k,j] to output corresponding voltage. The multiplier circuit MUL3 is configured to multiply an output signal y[j] of the hidden neuron circuit HN[j] by the weight coefficient v[k,j] stored in the analog memory AM2 so that current corresponding to the multiplication result is output as an output signal v[k,j]y[j]. The multiplier circuit MUL4 is configured to multiply the output signal y[j] of the hidden neuron circuit HN[j] by an output signal dy[k] of an output error circuit OE[k] so that current corresponding to the multiplication result is supplied to the analog memory AM2 as a signal dv. The signal dv is supplied as current corresponding to the amount of change in the weight coefficient v[k,j] stored in the analog memory AM2. The multiplier circuit MUL5 is configured to multiply the output signal dy[k] of the output error circuit OE[k] by the weight coefficient v[k,j] stored in the analog memory AM2 so that current corresponding to the multiplication result is supplied as an output signal v[k,j]dy[k]. Note that in output synapse circuits OS[1,0] to OS[n,0], an input signal y[0] is supplied with −1, and weight coefficients v[1,0] to v[n,0] are supplied with θ_{O}[1] to θ_{O}[n]; thus, current corresponding to −θ_{O}[1] to −θ_{O}[n] are supplied as output signals v[1,0]y[0] to v[n,0]y[0]. Note that the output synapse circuit OS is simply referred to as a circuit, in some cases.

FIG. 10C shows a configuration of an analog memory AM which can be used as any of the analog memories AM1 and AM2 in the hidden synapse circuit HS[j,i] and the output synapse circuit OS[k,j]. The analog memory AM includes a transistor 301 and a capacitor 302. When the transistor 301 is an OS transistor, an ideal analog memory can be formed. Thus, because it is not necessary to mount a large scale capacitor for holding data and to recover analog data by regular refresh operation, reduction in a chip area and reduction in power consumption are possible. Note that in updating data, current corresponding to the amount of change is supplied; thus, ηᵥ or η_{w} (constant) can be changed by adjustment of a period during which a signal line WL is set to “H”.

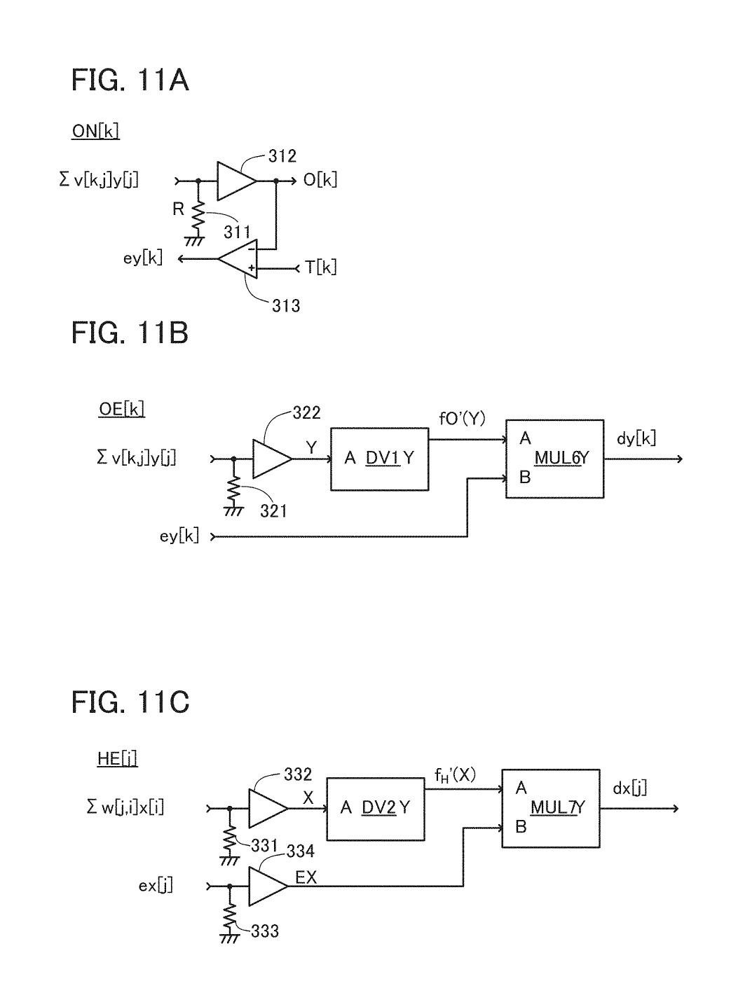

FIG. 11A shows a configuration of an output neuron circuit ON[k]. The output neuron circuit ON[k] includes a resistance 311 which converts an input signal Y into voltage and an amplifier 312 which generates the output signal O[k]. The input signal Y corresponds to Σ_{j=0˜m}v[k,j]y[j] that is the sum of the output signals v[k,j]y[j] (current) of the output synapse circuits OS[k,j]. The output signal O[k] of the amplifier 312 has characteristics of f_{O}(Y) in Formula 2 or has characteristics approximated thereto when the input signal Y is a variable.

[Formula 2]

f_{O}(Y)=1/(1+e^{-α}^{_{O}}^{Y}) (2)

In Formula 2, α_{O} is an arbitrary constant, which corresponds to the change rate of the output signal when Y is 0. When Σ_{j=0˜m}v[k,j]y[j], which corresponds to the input signal Y, exceeds 0, that is, Σ_{j=1˜m}v[k,j]y[j] exceeds the threshold value θ_{O}[k], f_{O}(Y), which corresponds to the output signal O[k], comes close to 1, that is, becomes “H”, which is expressed as firing of the output neuron circuit ON[k]. That is, the threshold value θ_{O}[k] corresponds to a threshold value at which the output neuron circuit ON[k] fires.

Learning means that the neural network shown in FIG. 9 stores data corresponding to the weight coefficients w[j,i] and v[k,j] in the analog memories AM1 and AM2 so that the neural network can output desired output signals O[1] to O[n] when predetermined input signals I[1] to I[L] are input. More specifically, arbitrary values are given to the weight coefficients w[j,i] and v[k,j] as initial values, input data used for the learning are given to the input signals I[1] to I[L] of the input neuron circuits, and then teacher signals are given to input signals T[1] to T[n] of the output neuron circuits as output expected values, whereby the weight coefficients w[j,i] and v[k,j] are converged so that the sum of squared errors between the output signals O[1] to O[n] and the input signals T[1] to T[n] of the output neuron circuits is minimized.

The gradient of the weight coefficient v[k,j] follows the relationship in Formula 3.

[Formula 3]

∂E/∂v[k,j]=∂E/∂ey[k]·∂ey[k]/∂O[k]·∂O[k]/∂Y·∂Y/∂v[k,j]=ey[k]·(−1)·f_{O}′(Y)·α₀y(j) (3)

In Formula 3, Y is expressed as Y=α₀Σ_{j=0˜m}v[k,j]y[j]. Thus, the weight coefficient v[k,j] only needs to be changed by the equivalent of ηᵥ·ey[k]·f_{O}′(Y)·y[j]. Note that ηᵥ is a constant.

The gradient of the weight coefficient w[j,i] follows the relationship in Formula 4.

[Formula 4]

∂E/∂w[j,i]=Σ∂E/∂ey[k]·∂ey[k]/∂O[k]·∂O[k]/∂Y·∂Y/∂y[j]·∂y[j]/∂X·∂X/∂w[j,i]=Σey[k]·(−1)·f_{O}′(Y)·α₀v[k,j]·f_{H}′(X)·α_{H}x(i) (4)

In Formula 4, X=α_{H}Σ_{i=0˜m}w[j,i]x[i] and Y=α₀Σ_{j=0˜m}v[k,j]y[j]. The weight coefficient w[j,i] only needs to be changed by the equivalent of η_{w}·(Σ_{j=0˜m}ey[k]·f_{O}′(Y)·v[k,j])·f_{H}′(X)·x[i]. In the output neuron circuit ON[k] in FIG. 11A, a difference between the teacher signal T[k] and the output signal O[k] is acquired by an amplifier 313, whereby the difference is output as a differential signal ey[k]. Note that η_{w} is a constant. In some cases, the output neuron circuit ON is simply referred to as a circuit.

FIG. 11B is a configuration of an output error circuit OE[k]. The output error circuit OE[k] includes a differentiating circuit DV1 for generating an output signal f_{O}′(Y) with respect to the signal Y and a multiplier circuit MUL6 to which the output signal f_{O}′(Y) and the differential signal ey[k] are input as input signals. The output error circuit OE[k] includes the resistor 321 which converts an input signal to voltage and an amplifier 322 which generates a signal Y. The input signal corresponds to a signal Σ_{j=0˜m}v[k,j]y[j] that is the sum of the output signals v[k,j]y[j] (current) of the output synapse circuits OS[k,j] and the differential signal ey[k] that is the output signal of the output neuron circuit ON[k].

FIG. 11C is a configuration of a hidden error circuit HE[j]. The hidden error circuit HE[j] includes a resistor 331 which converts an input signal into voltage, an amplifier 332 which generates a signal X, a resistor 333 which converts a signal ex[j] into voltage, and an amplifier 334 which generates a signal EX. The input signal corresponds to a signal Σ_{i=0˜L}w[j,i]x[i] that is the sum of the output signals w[j,i]x[i] (current) of the hidden synapse circuits HS[j,i] and a signal Σ_{k=1˜L}v[k,j]dy[k]=Σ_{k=1˜L}ey[k]·f_{O}′(Y)·v[k,j]=ex[j] that is the output signals v[k,j]dy[k] of the output synapse circuits OS[k,j], that is the sum of currents ey[k]·f_{O}′(Y)·v[k,j].

As described above, the neural network shown in FIG. 9 can update the weight coefficients w[j,i] and v[k,j] and can store data corresponding to the weight coefficients w[j,i] and v[k,j] in the analog memories so that the neural network can output desired output signals O[1] to O[n] when predetermined input signals I[1] to I[L] are input. In other words, the learning in the prediction circuit 112 can be achieved. A variety of parameters obtained by the learning in the prediction circuit 112 can be stored in the register 130.

In the neural network of the prediction circuit 112, the learning is performed in such a manner that a learning signal is provided as an input signal of the input neuron circuit, a teacher signal corresponding to the learning signal is provided as an input signal of the output neuron circuit, and analog memory data are updated in accordance with a differential signal.

With the above-described configuration, a hierarchical neural network, which includes an analog circuit with smaller circuit size and which does not need refresh operation for retention of data in the analog memory, can be provided.

Note that a convolutional neural network (CNN) in which the above-described neural network is used as a feature extraction filter of convolution or a fully connected arithmetic circuit can be used for the prediction circuit 112. Weight coefficients of the feature extraction filter can be determined using random numbers. Owing to this, even when a waveform pattern matching the signal Sco or the signal Sto is not easily expected, features can be extracted and the learning can be performed efficiently.

As described above, the use of the arithmetic circuit of one embodiment of the present invention can achieve calculation of weighting addition and calculation of an update amount of a weight coefficient in a neural network.

### <Operation Example of Arithmetic Circuit>

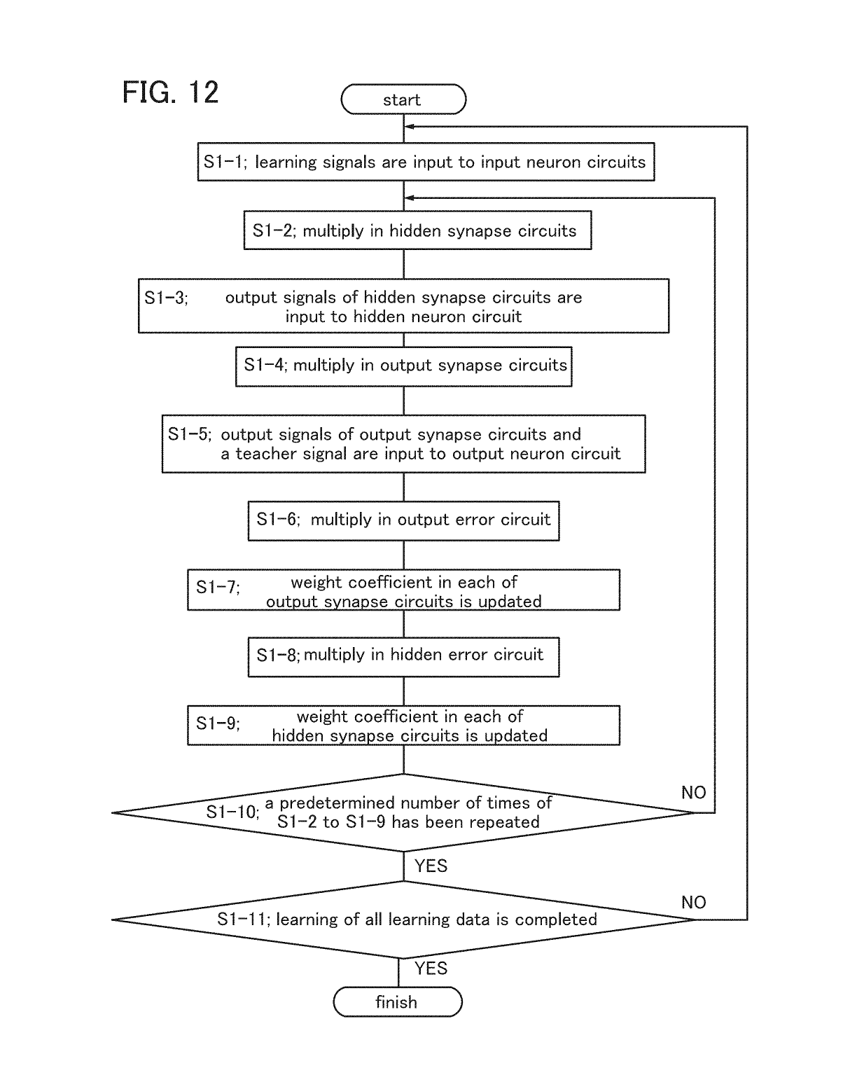

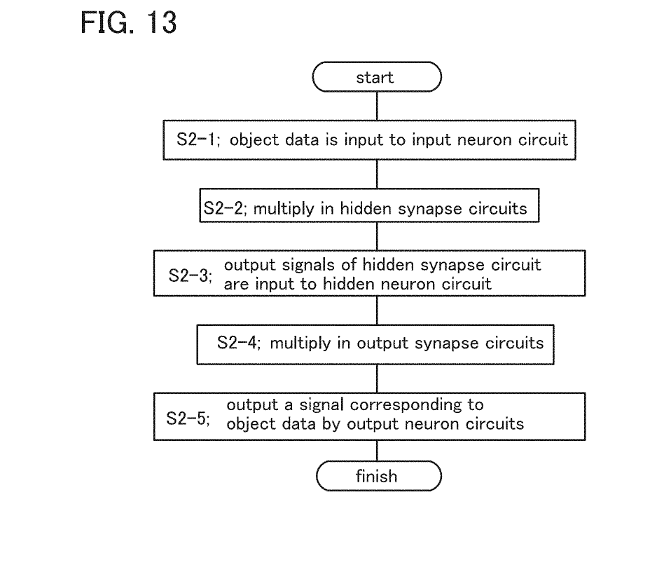

The operation of an arithmetic circuit refers to the following operation: a learning signal is input to an arithmetic circuit including the above-described neural network so that the arithmetic circuit learns the learning signal, then, object data is input to the arithmetic circuit, and then, a parameter corresponding to the object data is output. FIG. 12 and FIG. 13 are flow charts of the operation of the arithmetic circuit. Note that in an operation example below, an arithmetic circuit including the neural network shown in FIG. 9 is described.

### [Learning]

The data-learning operation of the arithmetic circuit is described first with reference to FIG. 9 and FIG. 12.

### [Step S1-1]

At Step S1-1, learning signals are input from the outside to the input neuron circuits IN. The learning signals correspond to input signals I[1] to I[L] in FIG. 9. Note that the learning signals correspond to, in the display device described in Embodiment 1, the signal Sco containing information on power consumption of the memory device 121, the signal Sto containing touch information, and the like. The number of input neuron circuits IN to which the learning signals are input is determined in response to kind of learning signal. The output signal x of an input neuron circuit IN to which a learning signal does not need to be input preferably has a fixed value. In addition, power supplied to the input neuron circuit IN is preferably interrupted. Here, there is L kinds of learning signal, and the value of an i-th learning signal is denoted by a learning signal I[i]. The learning signals I[1] to I[L] are input to the input neuron circuits IN[1] to IN[L], respectively.

### [Step S1-2]

In Step S1-2, output signals x[1] to x[L] are input from the input neuron circuit IN[1] to IN[L] to hidden synapse circuits HS[1,1] to HS[1,L]. In Step S1-2, a signal x[0] with a constant value is input to hidden synapse circuits HS[1,0] to HS[m,0]. The hidden synapse circuits HS[1,0] to HS[1,L] each output a signal w[1,i]x[i] obtained by multiplying the output signal x[i] by a weight coefficient w[1,i] held in the analog memory AM1, to a hidden error circuit HE[1] and a hidden neuron circuit HN[1].

The above operation is also performed in hidden synapse circuits HS[m,0] to HS[m,L], and an output signal w[m,i]x[i] is output to a hidden error circuit HE[m] and a hidden neuron circuit HN[m].

### [Step S1-3]

In Step S1-3, Σw[1,i]x[i] that is the sum of the output signals of the hidden synapse circuits HS[1,0] to HS[1,L] is input to the hidden neuron circuit HN[1]. Similarly, Σw[m,i]x[i] that is the sum of the output signals of the hidden synapse circuits HS[m,0] to HS[m,L] is input to the hidden neuron circuit HN[m].

Note that the number of the hidden neuron circuits HN[1] to HN[m] can be changed corresponding to learning signals. It is preferable that data which makes an output signal y a fixed value be input to a hidden neuron circuit HN for which input of learning is not necessary. Moreover, it is preferable that supply of power to such a hidden neuron circuit HN be stopped. Here, the number of the hidden neuron circuits HN is m, and an input value of a j-th hidden neuron circuit HN is expressed as Σw[j,i]x[i].

### [Step S1-4]

In Step S1-4, output signals y[1] to y[m] are input from the hidden neuron circuits HN[1] to HN[m] to output synapse circuits OS[1,1] to OS[1,m]. In Step S1-4, a signal y[0] that is a constant value is input to the output synapse circuits OS[1,0] to OS[n,0]. The output synapse circuits OS[1,0] to OS[1,m] each output an output signal v[1,j]y[j] obtained by multiplying the output signal y[j] by the weight coefficient v[1,j] held in the analog memory AM2, to an output error circuit OE[1] and an output neuron circuit ON[1].

The above operation is also performed in the output synapse circuits OS[n, 0] to OS[n,m], and an output signal v[n,j]y[j] is output to the output error circuit OE[n] and the output neuron circuit ON[n].

### [Step S1-5]

In Step S1-5, Σv[1,j]y[j] that is the sum of the output signals of the output synapse circuits OS[1,0] to OS[1,m] is input to the output neuron circuit ON[1]. Similarly, Σv[n,j]y[j] that is the sum of the output signals of the output synapse circuits OS[n,0] to OS[n,m] is input to the output neuron circuit ON[n]. The output neuron circuits ON[1] to ON[n] output the output signals O[1] to O[n].

The output neuron circuit ON[1] outputs a differential signal ey[1] to the output error circuit OE[1] based on Σv[1,j]y[j] that is the sum of the output signals of the output synapse circuits OS[1,0] to OS[1,m] and a teacher signal T[1] from the outside. Similarly, the output neuron circuit ON[n] outputs a differential signal ey[n] to the output error circuit OE[n] based on Σv[n,j]y[j] that is the sum of the output signals of the output synapse circuits OS[n,0] to OS[n,m] and the teacher signal T[n] from the outside.

### [Step S1-6]

In Step S1-6, a differential signal ey[1] and Σv[1,j]y[j] that is the sum of the output signals of the output synapse circuits OS[1,0] to OS[1,m] are input from the output neuron circuit ON[1] to the output error circuit OE[1]. The output error circuit OE[1] outputs an output signal dy[1] obtained by multiplying the differential signal ey[1] by a signal obtained by differentiating Σv[1,j]y[j], to the output synapse circuits OS[1,0] to OS[1,m].

Similarly, in Step S1-6, the differential signal ey[n] and Σv[n,j]y[j] that is the sum of the output signals of the output synapse circuits OS[n,0] to OS[n,m] are input from the output neuron circuit ON[n] to the output error circuit OE[n]. The output error circuit OE[n] outputs an output signal dy[n] obtained by multiplying the differential signal ey[n] by a signal obtained by differentiating Σv[n,j]y[j], to the hidden synapse circuits OS[n,0] to OS[n,m].

### [Step S1-7]

In Step S1-7, based on the output signal dy[1], the weight coefficient y[1,j] held in the analog memory AM2 in each of the output synapse circuits OS[1,0] to [1,m] is updated. Similarly, in Step S1-7, based on the output signal dy[n], a weight coefficient v[n,j] held in the analog memory AM2 in each of the output synapse circuits OS[n,0] to OS[n,m] is updated.

In addition, in output synapse circuits OS[1,1] to OS[n,1], output signals v[1,1]dy[1] to v[n,1]dy[n] obtained by multiplying the updated coefficients v[1,1] to v[n,1] by the output signals dy[1] to dy[n] are input to the hidden error circuit HE[1]. Similarly, in the output synapse circuits OS[1,m] to OS[n,m], output signals v[1,m]dy[1] to v[n,1]dy[n] obtained by multiplying the updated coefficients v[1,m] to v[n,m] by the output signals dy[1] to dy[n] are input to the hidden error circuit HE[m].

### [Step S1-8]

In Step S1-8, Σw[1,i]x[i] that is the sum of the output signals of the hidden synapse circuits HS[1,0] to HS[1,L], and ex[1] that is the sum of the output signals of the output synapse circuits OS[1,1] to OS[n,1] are input to the hidden error circuit HE[1]. The hidden error circuit HE[1] outputs an output signal dx[1] obtained by multiplying the signal ex[1] by a signal obtained by differentiating Σw[1,i]x[i], to the hidden synapse circuits HS[1,O] to HS[1,L].

Similarly, in Step S1-8, Σw[m,i]x[i] that is the sum of the output signals of the hidden synapse circuits HS[m,0] to HS[m,L], and ex[m] that is the sum of the output signals of the output synapse circuits OS[1,m] to OS[n,m] are input to the hidden error circuit HE[m]. The hidden error circuit HE[m] outputs an output signal dx[m] obtained by multiplying the signal ex[m] by a signal obtained by differentiating Σw[m,i]x[i], to the hidden synapse circuits HS[m,0] to HS[m,L].

### [Step S1-9]

In Step S1-9, based on the output signal dx[1], the weight coefficient w[1,i] held in the analog memory AM1 in each of the hidden synapse circuits HS[1,0] to HS[1,L] is updated to a weight coefficient dw[1,i]. Similarly, in Step S1-9, based on the output signal dx[m], the weight coefficient w[m,i] held in the analog memory AM1 in each of the hidden synapse circuits HS[m,0] to HS[m,L] is updated to a weight coefficient dw[m,i].

Hereafter, Step S1-2 to Step S1-9 are repeated for a predetermined number of times based on the updated weight coefficients dw[1,i] to dw[m,i].

### [Step S1-10]

In Step S1-10, judgement whether a predetermined number of times of Step S1-2 to Step S1-9 has been repeated is made. When the number of times has reached the predetermined number of times, the learning using learning signal is completed.

Ideally, the predetermined number of times is preferably set such that the error between the output signals O[1] to O[n] and the teacher signals T[1] to T[n] falls within a control value; however, it may be an arbitrary number of times empirically determined.

### [Step S1-11]

In Step S1-11, whether or not the learning data has been all learned is determined. If the learning of learning data has not been completed, Steps S1-1 to S1-10 are repeated, whereas if the learning of all the learning data has completed, Steps S1-1 to S1-10 are completed. Note that after the learning of all the learning data is completed once, the leaning may be performed again.

In the hierarchical perceptron neural network, it is preferable that there be multiple hidden layers, that is, a multilayer hidden synapse circuit and a multilayer hidden neuron circuit. When the multilayer hidden synapse circuit and the multilayer hidden neuron circuit are provided, update of the weight coefficients can be repeatedly performed, so that learning efficiency can be improved.

### [Parameter Output]

Next described with reference to FIG. 13 is an operation of inputting the object data to the arithmetic circuit including the neural network in FIG. 9 that has learned the data beforehand and of outputting the results.

### [Step S2-1]

In Step S2-1, object data is input from the outside to the input neuron circuit IN.

### [Step S2-2]

In Step S2-2, the output signals x[1] to x[L] corresponding to object data are input from the input neuron circuit IN[1] to IN[L] to the hidden synapse circuits HS[1,1] to IN[1,L]. In Step S2-2, the signal x[0] that is a constant value is input to the hidden synapse circuits HS[1,0] to HS[m,0]. The hidden synapse circuits HS[1,0] to HS[1,L] output an output signal w[1,i]x[i] obtained by multiplying the output signal x[i] by the weight coefficient w[1,i] held in learning Step S1-9, to the hidden neuron circuit HN[1].

The above operation is also performed in the hidden synapse circuits HS[m,0] to HS[m,L], and the output signal w[m,i]x[i] is output to the hidden neuron circuit HN[m].

### [Step S2-3]

In Step S2-3, Σw[1,i]x[i] that is the sum of the output signals of the hidden synapse circuits HS[1,0] to HS[1,L] is input to the hidden neuron circuit HN[1]. Similarly, Σw[m,i]x[i] that is the sum of the output signals of the hidden synapse circuit HS[m,0] to HS[m,L] is input to the hidden neuron circuit HN[m].

### [Step S2-4]

In Step S2-4, the output signals y[1] to y[m] are input from the hidden neuron circuits HN[1] to HN[m] to the output synapse circuits OS[1,1] to OS[n,1]. In Step S2-4, a signal y[0] that is a constant value is input to the output synapse circuits OS[1,0] to OS[n,0]. The output synapse circuits OS[1,0] to OS[1,m] output the output signal v[1,j]y[j] obtained by multiplying the output signal y[j] by the weight coefficient v[11] held in the analog memory AM2, to the output neuron circuit ON[1].

The above operation is also performed in the output synapse circuits OS[n,0] to OS[n,m], and the output signal v[n,j]y[j] is output to the output neuron circuit ON[n].

### [Step S2-5]

In Step S2-5, Σv[1,j]y[j] that is the sum of the output signals of the output synapse circuits OS[1,0] to OS[1,m] are input to the output neuron circuit ON[1]. Similarly, Σv[n,j]y[j] that is the sum of the output signals of the output synapse circuits OS[n,0] to OS[n,m] are input to the output neuron circuit ON[n]. The output neuron circuits ON[1] to ON[n] output the output signals O[1] to O[n].

Since values of the weight coefficients are determined by the learning, object data that are signals showing the necessity of power supply to the register 130, the image processing portion 140, the driver circuit 150, and the like can be output as the output signals O[1] to O[n].

Through Steps S1-1 to S1-10 and Steps S2-1 to S2-5 as described above, the arithmetic circuit including a neural network shown in FIG. 9 learns a learning signal and then outputs a signal corresponding to the object data.

By the above operation, the learning in the hierarchical perceptron neural network and output of parameters from the neural network are achieved.

When the neural network described in this embodiment is used for the prediction circuit 112 in Embodiment 1, a semiconductor device capable of predicting the necessity of power supply can be provided.

This embodiment can be combined with any of the other embodiments as appropriate.

### Embodiment 3

In this embodiment, a specific structure example of a circuit including the semiconductor device described in the above embodiments is described.

### <Structure Example of Frame Memory>

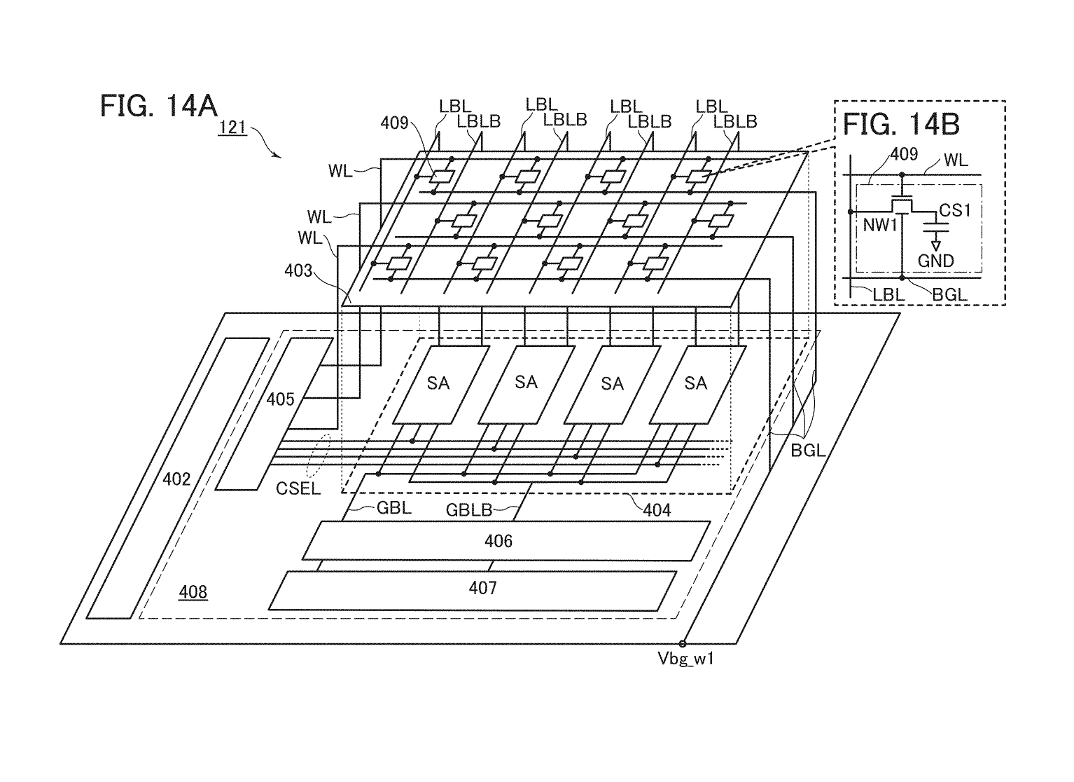

First described is a structure example of the frame memory 120. FIG. 14A shows a structure example of the memory device 121 included in the frame memory 120. The memory device 121 includes a control portion 402, a cell array 403, and a periphery circuit 408. The periphery circuit 408 includes a sense amplifier circuit 404, a driver circuit 405, a main amplifier 406, and an input/output circuit 407.

The control portion 402 has a function of controlling the memory device 121. For example, the control portion 402 has a function of controlling the driver circuit 405, the main amplifier 406, and the input/output circuit 407.

A plurality of wirings WL and CSEL are connected to the driver circuit 405. The driver circuit 405 generates signals output to the plurality of wirings WL and CSEL.

The cell array 403 includes a plurality of memory cells 409. The memory cells 409 are connected to wirings WL, LBL (or LBLB), and BGL. The wiring WL is a word line. The wirings LBL and LBLB are local bit lines. Although a folded-bit-line method is employed for the configuration of the cell array 403 in the example of FIG. 14A, an open-bit-line method can also be employed.

FIG. 14B illustrates a configuration example of the memory cell 409. The memory cell 409 includes a transistor MW1 and a capacitor CS1. The memory cell 409 has a circuit configuration similar to that of a memory cell for a dynamic random access memory (DRAM). The transistor MW1 in this example is a transistor having a back gate. The back gate of the transistor MW1 is electrically connected to a wiring BGL. A voltage Vbg_w1 is input to the wiring BGL.

The transistor MW1 is an OS transistor. Since an OS transistor has an extremely low off-state current, the frequency of refresh operation of the memory device 121 of the frame memory 120 can be reduced because leakage of charge from the capacitor CS1 can be suppressed by forming the memory cell 409 using an OS transistor. The memory device 121 of the frame memory 120 can retain image data for a long time even when power supply is stopped. Moreover, by setting the voltage Vbg_w1 to a negative voltage, the threshold voltage of the transistor MW1 can be shifted to the positive potential side and thus the retention time of the memory cell 409 can be increased.

Here, an off-state current refers to a current that flows between a source and a drain of a transistor in an off state. The off-state current of an OS transistor normalized on the channel width can be, for example, lower than or equal to 10×10⁻²¹ A/mm (10 zA/μm) with a source-drain voltage of 10 V at room temperature (approximately 25° C.). It is preferable that the off-state current of the OS transistor used as the transistors 301a and Tr1 be lower than or equal to 1×10⁻¹⁸ A, lower than or equal to 1×10⁻²¹ A, or lower than or equal to 1×10⁻²⁴ A at room temperature (approximately 25° C.). Alternatively, the off-state current is preferably lower than or equal to 1×10⁻¹⁵ A, lower than or equal to 1×10⁻¹⁸ A, or lower than or equal to 1×10⁻²¹ A at 85° C.

A metal oxide contained in a channel formation region of an OS transistor is preferably an oxide semiconductor containing at least one of indium (In) and zinc (Zn). Typical examples of the metal oxide include an In oxide, a Zn oxide, an In—Zn oxide, and an In-M-Zn oxide (element M is Al, Ti, Ga, Y, Zr, La, Ce, Nd, or Hf). A reduction in impurities serving as electron donors, such as hydrogen, and a reduction in oxygen vacancies can make a metal oxide i-type (intrinsic) or substantially i-type. Such a metal oxide can be referred to as a highly purified metal oxide. The carrier density of the metal oxide can be, for example, lower than 8×10¹⁵ cm⁻³, preferably lower than 1×10¹¹ cm⁻³, further preferably lower than 1×10¹⁰ cm⁻³ and higher than or equal to 1×10⁻⁹ cm⁻³.

The metal oxide has a large energy gap. Electrons are unlikely to be excited, and the effective mass of a hole is large. Thus, an avalanche breakdown and the like are less likely to occur in some cases in an OS transistor than in a Si transistor. Since hot-carrier degradation or the like due to the avalanche breakdown is inhibited, the OS transistor has high drain withstand voltage and can be driven at high drain voltage. Thus, when the OS transistor is used as each of the transistors 301a and Tr1b, the range of potentials to be held in the capacitor CS1 can be widened.

The transistors included in the circuits other than the memory cell 409 may be transistors other than the OS transistor. For example, a transistor in which a channel formation region is formed in a part of a substrate that contains a single-crystal semiconductor other than a metal oxide may be used. Examples of this kind of substrate include a single-crystal silicon substrate and a single-crystal germanium substrate. In addition, a transistor whose channel formation region is formed in a film containing a semiconductor material other than a metal oxide can also be used as the transistor 460. For example, a transistor in which an amorphous silicon film, a microcrystalline silicon film, a polycrystalline silicon film, a single-crystal silicon film, an amorphous germanium film, a microcrystalline germanium film, a polycrystalline germanium film, or a single-crystal germanium film is used for its semiconductor layer can be used. For example, when the transistor included in the circuits other than the memory cell 409 is a Si transistor formed over a silicon wafer, the cell array 403 can be stacked over the sense amplifier circuit 404. As a result, the circuit area of the memory device 121 can be reduced, leading to the reduction in size of the semiconductor device.

The cell array 403 is stacked over the sense amplifier circuit 404. The sense amplifier circuit 404 includes a plurality of sense amplifiers SA. The sense amplifiers SA are electrically connected to adjacent wirings LBL and LBLB (a pair of local bit lines), wirings GBL and GBLB (a pair of global bit lines), and the plurality of wirings CSEL. The sense amplifiers SA have a function of amplifying the potential difference between the wirings LBL and LBLB.

In the sense amplifier circuit 404, one wiring GBL is provided for four wirings LBL, and one wiring GBLB is provided for four wirings LBLB. However, the configuration of the sense amplifier circuit 404 is not limited to the configuration example of FIG. 14A.

The main amplifier 406 is connected to the sense amplifier circuit 404 and the input/output circuit 407. The main amplifier 406 has a function of amplifying the potential difference between the wirings GBL and GBLB. The main amplifier 406 is not necessarily provided.

The input/output circuit 407 has a function of outputting a potential corresponding to a write data to the wirings GBL and GBLB or the main amplifier 406 and a function of outputting the potentials of the wirings GBL and GBLB or an output potential of the main amplifier 406 to the outside as read data. The sense amplifier SA from which data is read and the sense amplifier SA to which data is written can be selected using the signal of the wiring CSEL. Therefore, there is no need to provide a selection circuit such as a multiplexer in the input/output circuit 407. Thus, the input/output circuit 407 can have a simple circuit configuration and a small occupied area.

### <Structure Example of Register>

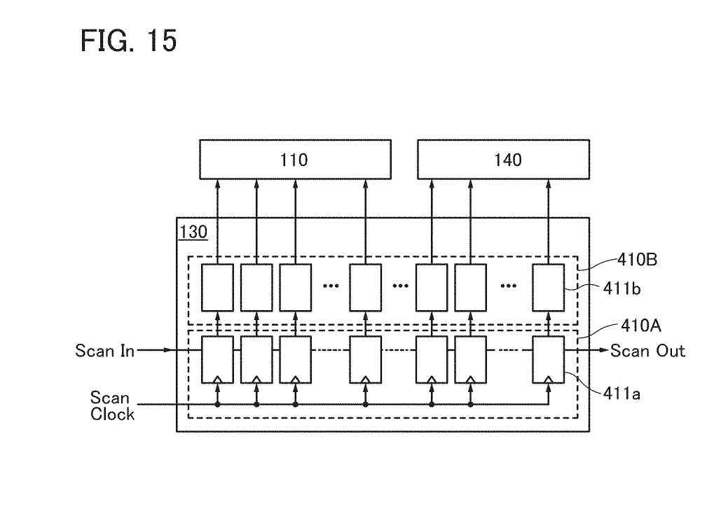

Next, a structure example of the register 130 is described. FIG. 15 is a block diagram illustrating a configuration example of the register 130. The register 130 includes a scan chain register portion 410A and a register portion 410B. The scan chain register portion 410A includes a plurality of registers 411a. The scan chain register is formed by the plurality of registers 411a. The register portion 410B includes a plurality of registers 411b.

The register 411a is a nonvolatile register which does not lose data even when power is broken. Here, the register 411a is provided with a memory circuit including an OS transistor to be nonvolatile.

In contrast, the register 411b is a volatile register. There is no particular limitation on the circuit configuration of the register 411b, and a latch circuit, a flip-flop circuit, or the like is used as long as data can be stored. The controller 110 and the image processing portion 140 access the register portion 410B and take data from the corresponding register 411b. The processing by the controller 110 and the image processing portion 140 is controlled in accordance with data supplied from the register portion 410B.

Note that the scan chain register portion 410A corresponds to the memory circuit 132 in FIG. 1 and other drawings. The register portion 410B corresponds to the memory circuit 131 in FIG. 1 and other drawings.

To update data stored in the register 130, data in the scan chain register portion 410A are changed first. Then, the data in the registers 411a of the scan chain register portion 410A are rewritten. Finally, the data in the register 411a of the scan chain register portion 410A are loaded into the respective registers 411b of the register portion 410B at the same time.

Accordingly, the controller 110 and the image processing portion 140 can perform various kinds of processing using the data updated at the same time. The operation of the semiconductor device can be stable because simultaneity can be maintained in data update. Since the scan chain register portion 410A and the register portion 410B are provided, data in the scan chain register portion 410A can be updated during operation of the controller 110 and the image processing portion 140.

In execution of power gating of the semiconductor device, power is broken after data is stored (saved) into the retention circuit of the register 411a. After the power is restarted, normal operation is restarted after data in the register 411a is restored (loaded) into the register 411b. Note that if the data stored in the register 411a does not match with the data stored in the register 411b, the data in the register 411b is preferably saved into the register 411a, and then the data is preferably stored again in the retention circuit of the register 411a. For example, while updated data is inserted into the scan chain register portion 410A, the match between data does not occur.

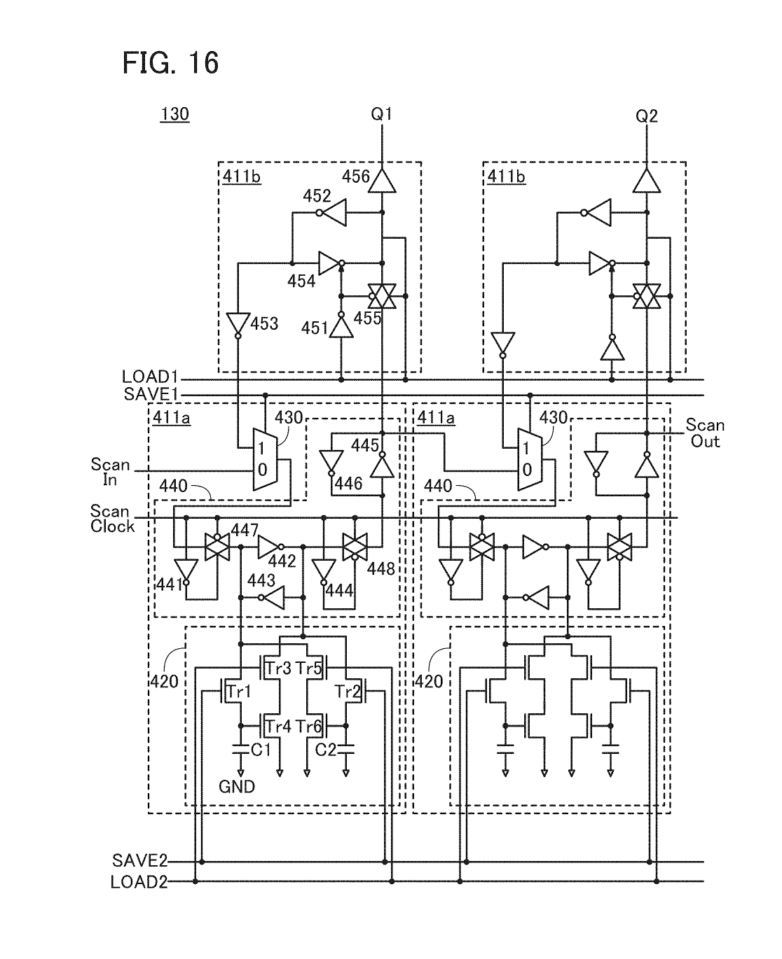

FIG. 16 illustrates an example of a circuit configuration of the register 411a and the register 411b. FIG. 16 illustrates two registers 411a of the scan chain register portion 410A and two registers 411b corresponding to these registers 411a.

The register 411a includes a retention circuit 420, a selector 430, and a flip-flop circuit 440. A scan flip-flop circuit comprises the selector 430 and the flip-flop circuit 440.

A signal SAVE2 and a signal LOAD2 are input to the retention circuit 420. The retention circuit 420 includes transistors Tr1 to Tr6 and capacitors C1 and C2. The transistors Tr1 and Tr2 are OS transistors. The transistors Tr1 and Tr2 may be OS transistors each having a back gate in a manner similar to that of the transistor NW1 of the memory cell 409 (see FIG. 14B).

A 3-transistor gain cell comprises the transistors Tr1, Tr3, and Tr4 and the capacitor C1. Another 3-transistor gain cell comprises the transistors Tr2, Try, and Tr6 and the capacitor C2. The two gain cells store complementary data that the flip-flop circuit 440 retains. When the transistors Tr1 and Tr2, which are OS transistors here, are turned off, the charges accumulated in the capacitors C1 and C2 can be held for a long time. Thus, the data held in the register 130 is saved into the capacitors C1 and C2, whereby the data can be held for a long time in the register 130 even when power supply is stopped. Note that in the register 411a, the transistors other than the transistor Tr1 and the transistor Tr2 may be Si transistors.

The retention circuit 420 stores complementary data the flip-flop circuit 440 retains in response to the signal SAVE2 and loads the retained data into the flip-flop circuit 440 in response to the signal LOAD2.

An output terminal of the selector 430 is connected to an input terminal of the flip-flop circuit 440. An input terminal of the register 411b is connected to an output terminal. The flip-flop circuit 440 includes inverters 441 to 446 and analog switches 447 and 448. The on/off state of each of the analog switches 447 and 448 are controlled by a scan clock signal (“Scan Clock”). The flip-flop circuit 440 is not limited to the circuit configuration shown in FIG. 16 and a variety of flip-flop circuits can be employed.

One of two input terminals of the selector 430 is connected to the output terminal of the register 411b. The other is connected to an output terminal of the flip-flop circuit 440 in the previous stage. Note that data is input from the outside of the register 130 to the input terminal of the selector 430 in the first stage of the scan chain register portion 410A.

The register 411b includes inverters 451 to 453, a clocked inverter 454, an analog switch 455, and a buffer 456. The register 411b loads the data of the flip-flop circuit 440 in response to a signal LOAD1. Si transistors can be used as transistors of the register 411b.

### <Structure Example of Switch Circuit>

Next, a structure example of the switch circuit 160 is described.

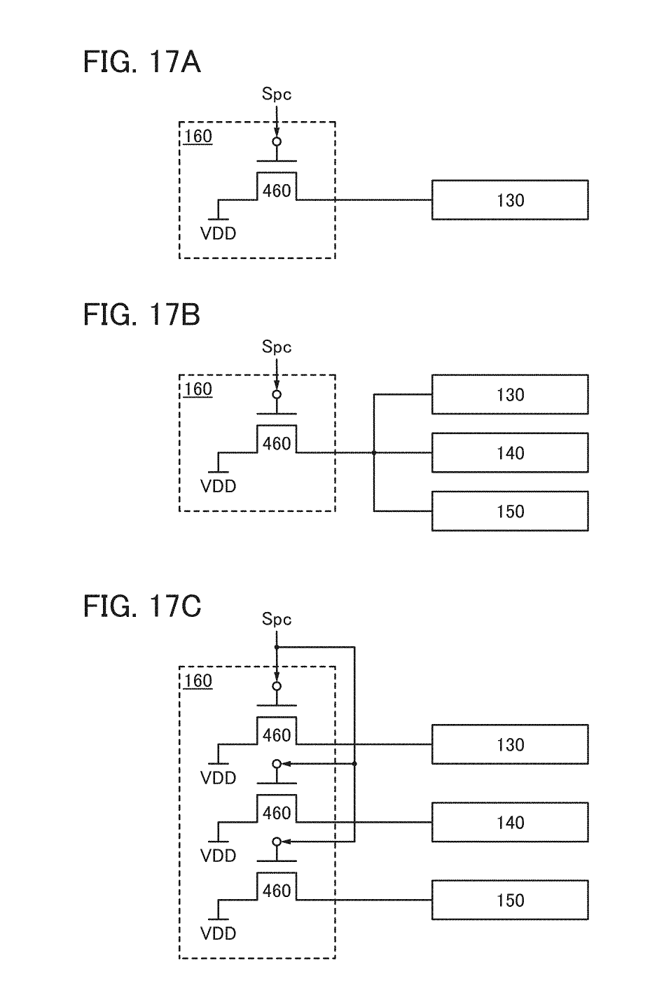

FIG. 17A shows the structure example of the switch circuit 160 for controlling the power gating of the register 130. The switch circuit 160 includes a transistor 460. A gate of the transistor 460 is connected to a terminal to which the signal Spc is input. One of a source and a drain of the transistor 460 is connected to the register 130, and the other thereof is connected to a wiring to which a power supply potential (a high power supply potential VDD, here) is supplied. Note that the transistor 460 is an n-channel transistor here but may be a p-channel transistor.

Note that a source of a transistor in this specification and the like means a source region that is part of a semiconductor layer functioning as a channel formation region, a source electrode connected to the semiconductor layer, or the like. Similarly, a drain of a transistor means a drain region that is part of the semiconductor layer, a drain electrode connected to the semiconductor layer, or the like. A gate of a transistor means a gate electrode or the like.

The terms “source” and “drain” of a transistor interchange with each other depending on the conductivity type of the transistor or levels of potentials supplied to the terminals. In general, in an n-channel transistor, a terminal to which a lower potential is supplied is called “source”, and a terminal to which a higher potential is supplied is called “drain”. In a p-channel transistor, a terminal to which a lower potential is supplied is called “drain”, and a terminal to which a higher potential is supplied is called “source”. In this specification, although the connection relationship of the transistors is described assuming that the source and the drain are fixed in some cases for convenience, actually, the terms of the source and the drain interchange with each other depending on the relationship of the potentials.

When a high-level potential as the signal Spc is supplied from the controller 110, whereby the transistor 460 is turned on and the power supply potential VDD is supplied to the register 130. As a result, power is supplied to the register 130. In contrast when a low-level potential as the signal Spc is supplied from the controller 110, the transistor 460 is turned off and the supply of power supply potential VDD to the register 130 is stopped. As a result, power supply to the register 130 is stopped.

Here, an OS transistor is preferably used as the transistor 460. This is because the off-state current of the transistor 460 can be sufficiently reduced in the period when the low-level potential is supplied as the signal Spc. Thus, leakage of power supplied to the register 130 can be extremely small in the period during which the transistor 460 is off, and power consumption can be reduced more efficiently. Note that the transistor 460 is not necessarily the OS transistor.

FIG. 17B shows a structure example in which power gating is performed for the register 130, the image processing portion 140, and the driver circuit 150. The transistor 460 is connected to the register 130, the image processing portion 140, and the driver circuit 150 as shown in FIG. 17B, whereby power supply to these circuits can be controlled at the same time. Consequently, the area of the switch circuit 160 can be reduced.

The transistor 460 may be provided for the register 130, the image processing portion 140, and the driver circuit 150 as shown in FIG. 17C. In this case, power supply potentials of these circuits can be individually determined.

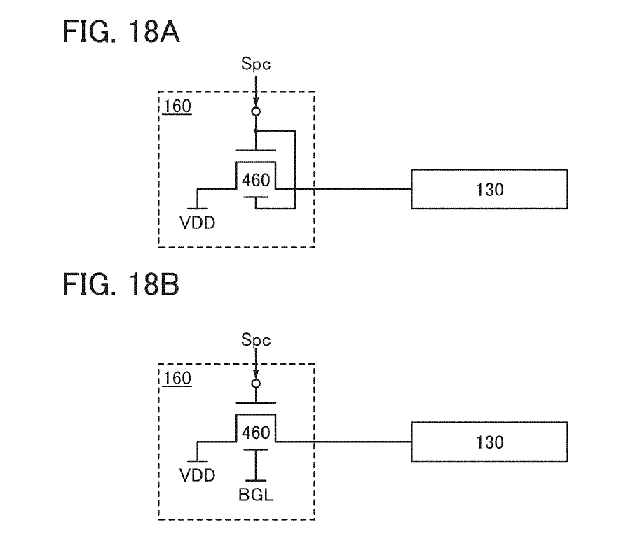

Note that the transistor 460 may include a pair of gates. FIGS. 18A and 18B each illustrate a structure example in which the transistor 460 includes a pair of gate electrodes. Here, the transistor 460 is an OS transistor. Note that when a transistor includes a pair of gates, one gate may be referred to as a first gate, a front gate, or simply a gate, and the other gate may be referred to as a second gate or a back gate.

The transistor 460 illustrated in FIG. 18A includes a back gate. The back gate is connected to a front gate. In this case, the potential of the front gate is equal to the potential of the backgate.

The transistor 460 illustrated in FIG. 18B includes a backgate connected to a wiring BGL. The wiring BGL has a function of supplying a predetermined potential to the backgate. The threshold voltage of the transistor 460 can be controlled by controlling the potential of the wiring BGL. The potential supplied to the wiring BGL may be either a fixed potential or a varied potential. In the case where a varied potential is supplied to the wiring BGL, by changing the potential of the wiring BGL between a period in which the transistor 460 is turned on and a period in which the transistor 460 is turned off, for example, the threshold voltage of the transistor 460 may be changed. Note that in the case where the switch circuit 160 includes the plurality of transistors 460, the wiring BGL can be shared by some or all of the transistors 460.

This embodiment can be combined with any of the other embodiments as appropriate.

### Embodiment 4

In this embodiment, a more detailed structure example of the display system described in the above embodiments is described. Here, a display portion including a plurality of display units will be described as an example.

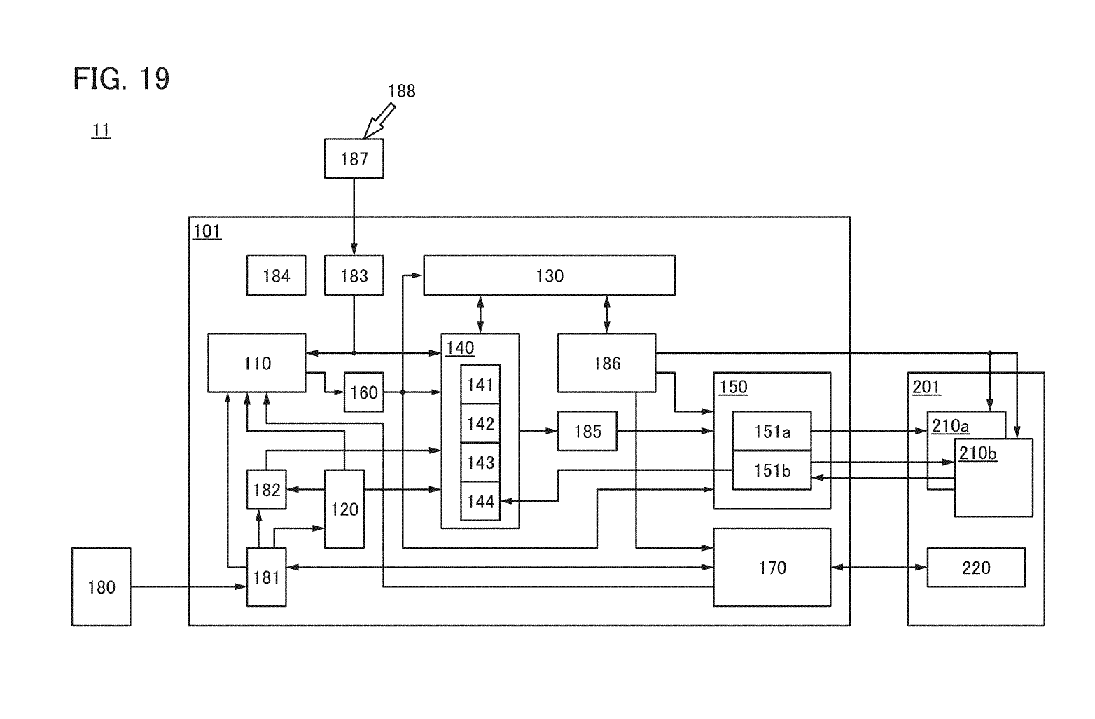

FIG. 19 shows a structure example of a display system 11. The display system 11 includes a semiconductor device 101 and a display portion 201.

The semiconductor device 101 includes, in addition to the variety of circuits shown in FIG. 7, an interface 181, a decoder 182, a sensor controller 183, a clock generation circuit 184, a memory device 185, and a timing controller 186. The display portion 201 is equal to the display portion 200 shown in FIG. 7 including a plurality of display units 210 (210a and 210b).

As the display unit 210, a display unit which performs display using a liquid crystal element, a display unit which performs display using a light-emitting element, or the like can be used. FIG. 19 illustrates a structure example in which the display portion 201 includes the display unit 210a which performs display using a reflective liquid crystal element and the display unit 210b which performs display using a light-emitting element.

Note that a reflective display element other than a reflective liquid crystal element can be used as the display unit 210. For example, as the display unit 210, a Micro Electro Mechanical Systems (MEMS) shutter element, an optical interference type MEMS element, and a display element using a microcapsule method, an electrophoretic method, an electrowetting method, an Electronic Liquid Powder (registered trademark) method, or the like can be used.

As the light-emitting element, a self-luminous light-emitting element such as an organic light-emitting diode (OLED), a light-emitting diode (LED), a quantum-dot light-emitting diode (QLED), and a semiconductor laser can be used.

The driver circuit 150 includes a source driver 151. The source driver 151 is a circuit having a function of supplying video signals to the display unit 210. In FIG. 19, the display portion 201 includes the display units 210a and 210b; thus, the driver circuit 150 includes source drivers 151a and 151b. The source driver 151a has a function of supplying a video signal to the display unit 210a and the source driver 151b has a function of supplying a video signal to the display unit 210b. The source drivers 151 may be provided in the display portion 201.

The semiconductor device 101 has a function of communicating with the host 180 through the interface 181 therebetween. The image data Di, the signal Sch containing information on change of video displayed on the display portion 200, a variety of control signals, and the like are transmitted from the host 180 to the semiconductor device 101. Touch information or the like which is obtained by the touch sensor controller 170 is transmitted from the semiconductor device 101 to the host 180. Note that the circuits included in the semiconductor device 101 are chosen as appropriate depending on the standard of the host 180, the specifications of the display portion 201, and the like.

In the case where compressed image data is transmitted from the host 180 to the semiconductor device 101, the frame memory 120 can store the compressed image data. The decoder 182 is a circuit for decompressing the compressed image data. When decompression of the image data is not needed, processing is not performed in the decoder 182. Note that the decoder 182 can be provided between the frame memory 120 and the interface 181.

Note that as described above, the signal Sco containing information on power consumption is input from the frame memory 120 to the controller 110.

The image processing portion 140 has a function of performing a variety of image processings on the image data input from the frame memory 120 or the decoder 182 to generate a video signal. The image processing portion 140 includes a gamma correction circuit 141, a dimming circuit 142, and a toning circuit 143.

When the source driver 151b includes a circuit (current detection circuit) having a function of detecting current flowing through a light-emitting element included in the display unit 210b, an EL correction circuit 144 may be provided in the image processing portion 140. The EL correction circuit 144 has a function of adjusting luminance of the light-emitting element on the basis of a signal transmitted from the current detection circuit.

The video signal generated in the image processing portion 140 is output to the driver circuit 150 through the memory device 185. The memory device 185 has a function of temporarily storing the video signal. The source drivers 151a and 151b have functions of performing a variety of processings on the video signal input from the memory device 185 and outputting the signal to the display units 210a and 210b.

The timing controller 186 has a function of generating a timing signal or the like that is used in the driver circuit 150, the touch sensor controller 170, and gate drivers included in the display units 210a and 210b.

A signal containing touch information detected by the touch sensor unit 220 is processed in the touch sensor controller 170 and transmitted to the host 180 through the interface 181. The host 180 generates image data reflecting the touch information and transmits the image data to the semiconductor device 101. Note that the semiconductor device 101 may reflect the touch information in the image data. The touch sensor controller 170 may be provided in the touch sensor unit 220.

Note that as described above, the signal Sto containing touch information is input from the touch sensor controller 170 to the controller 110.

The clock generation circuit 184 has a function of generating a clock signal to be used in the semiconductor device 101. The controller 110 has functions of processing a variety of control signals transmitted from the host 180 through the interface 181 and controlling a variety of circuits in the semiconductor device 101. The controller 110 also has a function of controlling power supply to the variety of circuits in the semiconductor device 101. The controller 110 can temporarily stop power supply to a circuit that is not used, for example.

A parameter used to perform correction processing in the image processing portion 140, parameters used to generate waveforms of a variety of timing signals in the timing controller 186, and the like are stored in the register 130.

The sensor controller 183 connected to an optical sensor 187 can be provided in the semiconductor device 101. The optical sensor 187 has a function of detecting outside light 188 and generating a detection signal. The sensor controller 183 has a function of generating a control signal on the basis of the detection signal. The control signal generated by the sensor controller 183 is output to the controller 110, for example.

The image processing portion 140 has a function of generating a video signal for the display unit 210a and a video signal for the display unit 210b separately when one video image is displayed using the display unit 210a and the display unit 210b. In that case, reflection intensity of the reflective liquid crystal element of the display unit 210a and emission intensity of the light-emitting element of the display unit 210b can be adjusted in response to brightness of the external light 188 measured using the optical sensor 187 and the sensor controller 183. Here, the adjustment is referred to as dimming or dimming treatment. In addition, a circuit that performs the treatment is referred to as a dimming circuit.

For example, in the case where a video image is displayed on the display portion 201 in the outdoor environment at daytime on a sunny day, the video image can be displayed only by the reflective liquid crystal element without using the light-emitting element. In the case where a video image is displayed on the display portion 201 during night or in a dark environment, the video image can be displayed by making the light-emitting element emit light.

Depending on the brightness of external light, the image processing portion 140 can selectively generate a video signal for performing display only with the display unit 210a, a video signal for performing display only with the display unit 210b, or a video signal for performing display with the display unit 210a and the display unit 210b in combination. Accordingly, favorable display can be performed even in an environment with bright external light or an environment with weak external light. Furthermore, power consumption can be reduced by making the light-emitting element emit no light or reducing the luminance of the light-emitting element in the environment with bright external light.

Color tones can be corrected by combining the display by the light-emitting element with the display by the reflective liquid crystal element. A function of measuring the color tones of the outside light 188 may be added to the optical sensor 187 and the sensor controller 183 to perform such tone correction. For example, in the case where a video image is displayed on the display portion 201 in a red environment at evening, a blue (B) component is not sufficient only with the display by the reflective liquid crystal element; thus, the color tones can be corrected by making the light-emitting element emit light. Here, the correction is referred to as toning or toning treatment. In addition, a circuit that performs the toning treatment is referred to as a toning circuit.

The image processing portion 140 might include another processing circuit such as an RGB-RGBW conversion circuit depending on the specifications of the display portion 201. The RGB-RGBW conversion circuit has a function of converting image data of red, green, and blue (RGB) into video signals of red, green, blue, and white (RGBW). That is, in the case where the display portion 201 includes pixels of four colors of RGBW, power consumption can be reduced by displaying a white (W) component in the image data using the white (W) pixel. Note that in the case where the display unit 110 includes pixels of four colors of RGBY, an RGB-RGBY (red, green, blue, and yellow) conversion circuit can be used, for example.

The display unit 210a and the display unit 210b can display different video images. Operation speed of the reflective liquid crystal element is low as compared with the light-emitting element, so that it takes time to display a video image in some cases. Thus, a still image used as a background can be displayed by the reflective liquid crystal element and a moving image can be displayed by the light-emitting element. In that case, the frequency of rewriting an image which is displayed by the reflective liquid crystal element can be reduced and the operation of the source driver 151a and the gate driver included in the display unit 210a can be stopped in the period during which the video image is not rewritten. Consequently, display of a smooth moving image and a reduction of power consumption can be achieved at the same time. In this case, the frame memory 120 includes a region in which a video signal supplied to the reflective liquid crystal element is stored and a region in which a video signal supplied to the light-emitting element is stored.

The prediction circuit 112 shown in FIG. 1 or other drawings may be provided in the controller 110 in FIG. 19 and can be provided in the host 180. When the prediction circuit 112 is provided in the host 180, the signal Spr corresponding to the results of prediction by the prediction circuit 112 is input from the host 180 to the controller 110 through the interface 181. The signal Sco and the signal Sto are transmitted to the host 180 through the interface 181.

This embodiment can be combined with any of the other embodiments as appropriate.

### Embodiment 5

In this embodiment, structure examples of a display device that can be used for the display system described in the above embodiment will be described.

A display device described below can be used in the display portion 200 in FIG. 1, FIG. 6, and FIG. 7, the display portion 201 in FIG. 19, and the like. In particular, a display device which can perform display using a reflective element and a light-emitting element will be described.

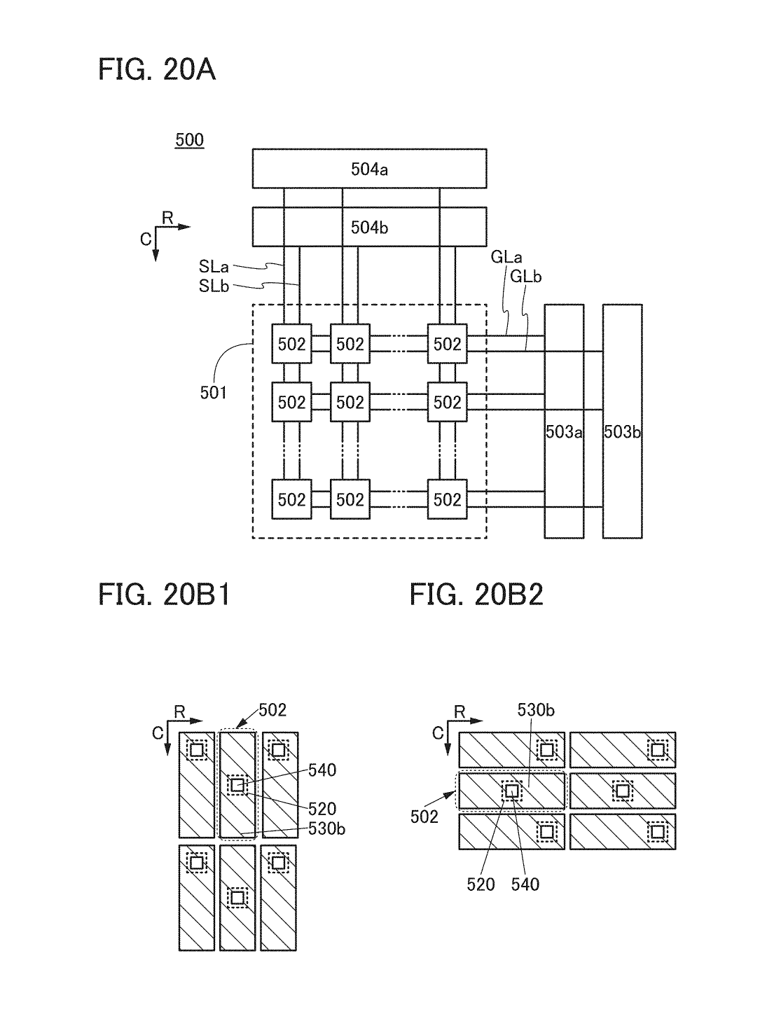

FIG. 20A is a block diagram illustrating an example of the structure of a display device 500 which can be used in the display portion. The display device 500 includes a plurality of pixel units 502 arranged in a matrix in a pixel portion 501. The display device 500 includes driver circuits 503a and 503b and driver circuits 504a and 504b. The display device 500 also includes a plurality of wirings GLa connected to the driver circuit 503a and the plurality of pixel units 502 arranged in a direction R, and a plurality of wirings GLb connected to the driver circuit 503b and the plurality of pixel units 502 arranged in the direction R. In addition, the display device 500 includes a plurality of wirings SLa connected to the driver circuit 504a and the plurality of pixel units 502 arranged in a direction C, and a plurality of wirings SLb connected to the driver circuit 504b and the plurality of pixel units 502 arranged in the direction C.

The driver circuit 504a and 504b correspond to the source drivers 151a and 151b in FIG. 19, respectively. That is, in the display device 500, the source drivers 151a and 151b in FIG. 19 are provided in the display portion 201. Note that the driver circuit 504a and 504b may be provided in the semiconductor device 101 in FIG. 19.

The pixel unit 502 includes a reflective liquid crystal element and a light-emitting element. In the pixel unit 502, the liquid crystal element and the light-emitting element partly overlap with each other.

FIG. 20B1 illustrates a structure example of a conductive layer 530b included in the pixel unit 502. The conductive layer 530b serves as a reflective electrode of the liquid crystal element in the pixel unit 502. The conductive layer 530b includes an opening 540.

In FIG. 20B1, a light-emitting element 520 in a region overlapping with the conductive layer 530b is denoted by a dashed line. The light-emitting element 520 overlaps with the opening 540 included in the conductive layer 530b. Thus, light from the light-emitting element 520 is emitted to the display surface side through the opening 540.

In FIG. 20B1, the pixel units 502 adjacent in the direction R correspond to different emission colors. As illustrated in FIG. 20B1, the openings 540 are preferably provided in different positions in the conductive layers 530b so as not to be aligned in the two pixels adjacent to each other in the direction R. This allows the two light-emitting elements 520 to be apart from each other, thereby preventing light emitted from the light-emitting element 520 from entering a coloring layer in the adjacent pixel unit 502 (such a phenomenon is also referred to as “crosstalk”). Furthermore, since the two adjacent light-emitting elements 520 can be arranged apart from each other, a high-resolution display device can be achieved even when EL layers of the light-emitting elements 520 are separately formed with a shadow mask or the like.

Alternatively, arrangement illustrated in FIG. 20B2 may be employed.

If the ratio of the total area of the opening 540 to the total area except for the opening is too high, display performed using the liquid crystal element is dark. If the ratio of the total area of the opening 540 to the total area except for the opening is too low, display performed using the light-emitting element 520 is dark.

If the area of the opening 540 in the conductive layer 530b serving as a reflective electrode is too small, light emitted from the light-emitting element 520 is extracted less efficiently.

The shape of the opening 540 can be, for example, polygonal, quadrangular, elliptical, circular, or cross-shaped. Alternatively, the opening 540 may have a stripe shape, a slit shape, or a checkered pattern. The opening 540 may be close to the adjacent pixel. Preferably, the opening 540 is provided close to another pixel emitting light of the same color, in which case crosstalk can be suppressed.

### <Configuration Example of Circuit>

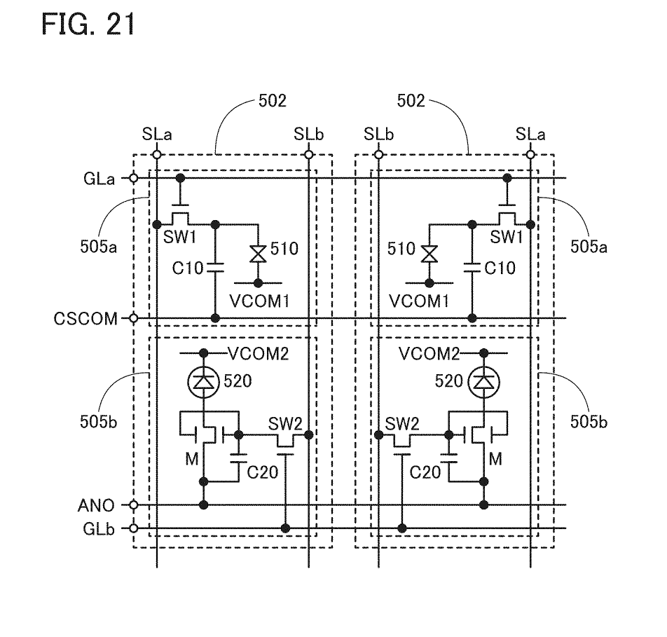

FIG. 21 is a circuit diagram illustrating a configuration example of the pixel unit 502. FIG. 21 illustrates two adjacent pixel units 502. The pixel units 502 each include a pixel 505a and a pixel 505b.

The pixel 505a includes a switch SW1, a capacitor C10, and a liquid crystal element 510, and the pixel 505b includes a switch SW2, a transistor M, a capacitor C20, and the light-emitting element 520. The pixel 505a is connected to the wiring SLa, the wiring GLa, and a wiring CSCOM. The pixel 505b is connected to the wiring GLb, the wiring SLb, and a wiring ANO. Note that in FIG. 21, a wiring VCOM1 connected to the liquid crystal element 510 and a wiring VCOM2 connected to the light-emitting element 520 are illustrated. FIG. 21 illustrates an example in which a transistor is used as each of the switches SW1 and SW2.

A gate of the switch SW1 is connected to the wiring GLa. One of a source and a drain of the switch SW1 is connected to the wiring SLa, and the other of the source and the drain is connected to one electrode of the capacitor C10 and one electrode of the liquid crystal element 510. The other electrode of the capacitor C10 is connected to the wiring CSCOM. The other electrode of the liquid crystal element 510 is connected to the wiring VCOM1.

A gate of the switch SW2 is connected to the wiring GLb. One of a source and a drain of the switch SW2 is connected to the wiring SLb, and the other of the source and the drain is connected to one electrode of the capacitor C20 and a gate of the transistor M. The other electrode of the capacitor C20 is connected to one of a source and a drain of the transistor M and the wiring ANO. The other of the source and the drain of the transistor M is connected to one electrode of the light-emitting element 520. Furthermore, the other electrode of the light-emitting element 520 is connected to the wiring VCOM2.

FIG. 21 illustrates an example in which the transistor M includes a pair of gates which are connected to each other. This structure can increase the amount of current flowing through the transistor M.

A predetermined potential can be supplied to each of the wirings VCOM1 and CSCOM. A potential which can generate a potential difference capable of making the light-emitting element 520 emit light can be supplied to each of the wirings VCOM2 and ANO.

In the pixel unit 502 illustrated in FIG. 21, for example, in the case where display in the reflective mode is performed, a video can be displayed by driving the pixel 505a with the signals supplied to the wirings GLa and SLa and utilizing the optical modulation of the liquid crystal element 510. In the case where display is performed in the transmissive mode, a video can be displayed by driving the pixel 505b with the signals supplied to the wirings GLb and SLb and making the light-emitting element 520 emit light. In the case where driving is performed in both the modes, the pixels 505a and 505b can be driven with the signals supplied to the wirings GLa, GLb, SLa, and SLb.

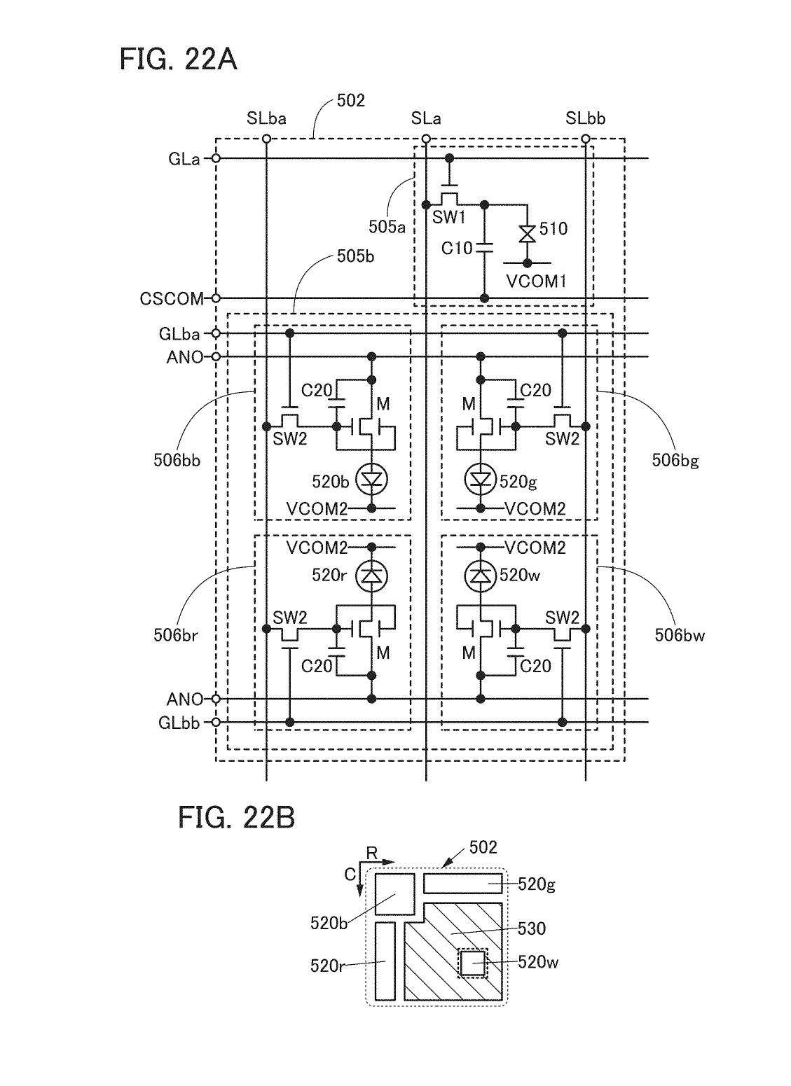

Although FIG. 21 illustrates an example in which one liquid crystal element 510 and one light-emitting element 520 are provided in one pixel unit 502, one embodiment of the present invention is not limited thereto. For example, as illustrated in FIG. 22A, the pixel 505b may include a plurality of subpixels 506b (506br, 506bg, 506bb, and 506bw). The subpixels 506br, 506bg, 506bb, and 506bw include light-emitting elements 520r, 520g, 520b, and 520w, respectively. The pixel unit 502 in FIG. 22A is capable of full color display by one pixel unit, which is different from the pixel unit in FIG. 21.

In FIG. 22A, the pixel 505b is connected to wirings GLba, GLbb, SLba, and SLbb.

In the example illustrated in FIG. 22A, for example, light-emitting elements which exhibit red (R), green (G), blue (B), and white (W) can be used as the four light-emitting elements 520. Furthermore, as the liquid crystal element 510, a reflective liquid crystal element emitting white light can be used. Thus, in the case of performing display in the reflective mode, white display with high reflectivity can be performed. In the case of performing display in the transmissive mode, images can be displayed with a higher color rendering property at low power consumption.

FIG. 22B illustrates a configuration example of the pixel unit 502. The pixel unit 502 includes the light-emitting element 520w overlapping with an opening of a conductive layer 530 as well as the light-emitting element 520r, the light-emitting element 520g, and the light-emitting element 520b which are provided around the conductive layer 530. It is preferable that the light-emitting elements 520r, 520g, and 520b have substantially the same light-emitting area.

As the switches SW1 and SW2, an OS transistor is preferably used. With the use of an OS transistor, charge can be retained in the capacitors C10 and C20 for an extremely long time. Therefore, also in a period during which a video signal is not generated by the semiconductor devices 100 and 101, a video displayed in the pixel unit can be kept for a long time. Accordingly, power gating can be performed in the semiconductor devices 100 and 101 described in the above embodiment for a long time.

### <Structure Example of Display Device>

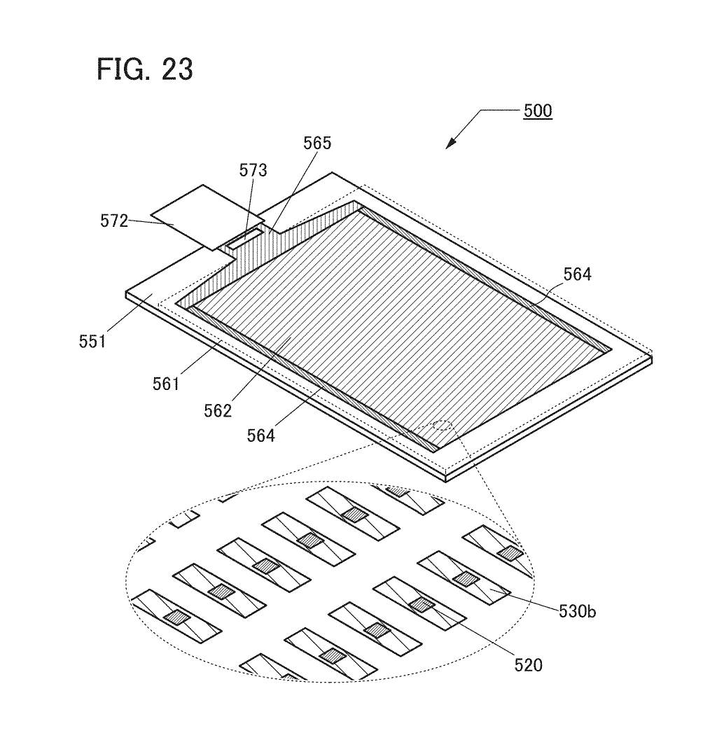

FIG. 23 is a schematic perspective view illustrating the display device 500 of one embodiment of the present invention. In the display device 500, a substrate 551 and a substrate 561 are attached to each other. In FIG. 23, the substrate 561 is denoted by a dashed line.

The display device 500 includes a display region 562, circuits 564, a wiring 565, and the like. The substrate 551 is provided with the circuit 564, the wiring 565, the conductive layer 530b which serves as a pixel electrode, and the like. In FIG. 23, an IC 573 and an FPC 572 are mounted on the substrate 551. Thus, the structure illustrated in FIG. 23 can be referred to as a display module including the display device 500, the FPC 572, and the IC 573.

As each of the circuits 564, for example, a circuit serving as the driver circuit 504 can be used.

The wiring 565 has a function of supplying a signal or electric power to the display region 562 or the circuit 564. The signal or electric power is input to the wiring 565 from the outside through the FPC 572 or from the IC 573.

FIG. 23 illustrates an example in which the IC 573 is provided on the substrate 551 by a chip on glass (COG) method or the like. As the IC 573, an IC functioning as the driver circuit 503 or 504, or the like can be used. Note that it is possible that the IC 573 is not provided when, for example, the display device 500 includes circuits serving as the driver circuit 503 or 504 and when the circuits serving as the driver circuit 503 or 504 are provided outside and a signal for driving the display device 500 is input through the FPC 572. Alternatively, the IC 573 may be mounted on the FPC 572 by a chip on film (COF) method or the like.

FIG. 23 also illustrates an enlarged view of part of the display region 562. The conductive layers 530b included in a plurality of display elements are arranged in a matrix in the display region 562. The conductive layer 530b has a function of reflecting visible light and serves as a reflective electrode of the liquid crystal element 510 described later.

As illustrated in FIG. 23, the conductive layer 530b includes an opening. The light-emitting element 520 is provided on the substrate 551 side of the conductor layer 530b. Light is emitted from the light-emitting element 520 to the substrate 561 side through the opening in the conductive layer 530b.

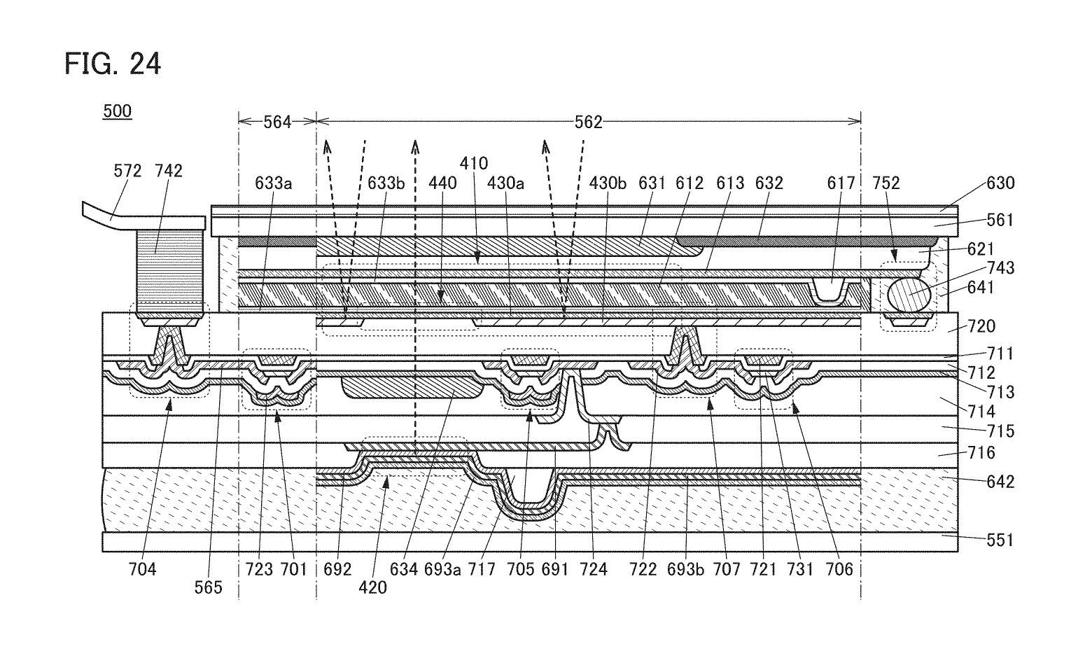

FIG. 24 illustrates an example of cross sections of part of a region including the FPC 572, part of a region including the circuit 564, and part of a region including the display region 562 of the display device illustrated in FIG. 23.

The display device 500 includes an insulating layer 720 between the substrates 551 and 561. The display device 500 also includes the light-emitting element 520, a transistor 701, a transistor 705, a transistor 706, a coloring layer 634, and the like between the substrate 551 and the insulating layer 720. Furthermore, the display device 500 includes the liquid crystal element 510, a coloring layer 631, and the like between the insulating layer 720 and the substrate 561. The substrate 561 and the insulating layer 720 are bonded with an adhesive layer 641. The substrate 551 and the insulating layer 720 are bonded with an adhesive layer 642.

The transistor 706 is connected to the liquid crystal element 510, and the transistor 705 is connected to the light-emitting element 520. Since the transistors 705 and 706 are formed on a surface of the insulating layer 720 which is on the substrate 551 side, the transistors 705 and 706 can be formed through the same process.

The coloring layer 631, a light-blocking layer 632, an insulating layer 621, and a conductive layer 613 serving as a common electrode of the liquid crystal element 510, an alignment film 633b, an insulating layer 617, and the like are provided over the substrate 561. The insulating layer 617 serves as a spacer for keeping a cell gap of the liquid crystal element 510.

Insulating layers such as an insulating layer 711, an insulating layer 712, an insulating layer 713, an insulating layer 714, an insulating layer 715, an insulating layer 716, and the like are provided on the substrate 551 side of the insulating layer 720. Part of the insulating layer 711 functions as a gate insulating layer of each transistor. The insulating layer 712, the insulating layer 713, and the insulating layer 714 are provided to cover each transistor. The insulating layer 716 is provided to cover the insulating layer 714. The insulating layers 714 and 716 each function as a planarization layer. Note that an example in which the three insulating layers, the insulating layers 712, 713, and 714, are provided to cover the transistors and the like is described here; however, one embodiment of the present invention is not limited to this example, and four or more insulating layers, a single insulating layer, or two insulating layers may be provided. The insulating layer 714 functioning as a planarization layer is not necessarily provided when not needed.

The transistors 701, 705, and 706 each include a conductive layer 721 part of which functions as a gate, conductive layers 722 part of which functions as a source and a drain, and a semiconductor layer 731. Here, a plurality of layers obtained by processing the same conductive film are shown with the same hatching pattern.

The liquid crystal element 510 is a reflective liquid crystal element. The liquid crystal element 510 has a stacked structure of a conductive layer 530a, liquid crystal 612, and a conductive layer 613. A conductive layer 530b which reflects visible light is provided in contact with the surface of the conductive layer 530a that faces the substrate 551. The conductive layer 530b includes the opening 540. The conductive layers 530a and 613 contain a material transmitting visible light. In addition, an alignment film 633a is provided between the liquid crystal 612 and the conductive layer 530a, and the alignment film 633b is provided between the liquid crystal 612 and the conductive layer 613. A polarizing plate 630 is provided on an outer surface of the substrate 561.

In the liquid crystal element 510, the conductive layer 530b has a function of reflecting visible light, and the conductive layer 613 has a function of transmitting visible light. Light entering from the substrate 561 side is polarized by the polarizing plate 630, passes through the conductive layer 613 and the liquid crystal 612, and is reflected by the conductive layer 530b. Then, the light passes through the liquid crystal 612 and the conductive layer 613 again and reaches the polarizing plate 630. In that case, alignment of the liquid crystal is controlled with a voltage that is applied between the conductive layer 530b and the conductive layer 613, and thus optical modulation of light can be controlled. That is, the intensity of light emitted through the polarizing plate 630 can be controlled. In addition, when light excluding light in a particular wavelength region is absorbed by the coloring layer 631, emitted light is red light, for example.

The light-emitting element 520 is a bottom-emission light-emitting element. The light-emitting element 520 has a structure in which a conductive layer 691, an EL layer 692, and a conductive layer 693b are stacked in this order from the insulating layer 720 side. In addition, a conductive layer 693a is provided to cover the conductive layer 693b. The conductive layer 693b contains a material reflecting visible light, and the conductive layers 691 and 693a contain a material transmitting visible light. Light is emitted from the light-emitting element 520 to the substrate 561 side through the coloring layer 634, the insulating layer 720, the opening 540, the conductive layer 613, and the like.

Here, as illustrated in FIG. 24, the conductive layer 530a transmitting visible light is preferably provided in the opening 540. Accordingly, the liquid crystal 612 is aligned in a region overlapping with the opening 540 as well as in the other regions, in which case an alignment defect of the liquid crystal is prevented from being generated in the boundary portion of these regions and undesired light leakage can be suppressed.

As the polarizing plate 630 provided on an outer surface of the substrate 561, a linear polarizing plate or a circularly polarizing plate can be used. An example of a circularly polarizing plate is a stack including a linear polarizing plate and a quarter-wave retardation plate. Such a structure can reduce reflection of external light. The cell gap, alignment, drive voltage, and the like of the liquid crystal element used as the liquid crystal element 510 are controlled depending on the kind of the polarizing plate so that a desirable contrast is obtained.

An insulating layer 717 is provided on the insulating layer 716 covering an end portion of the conductive layer 691. The insulating layer 717 has a function as a spacer for preventing the insulating layer 720 and the substrate 551 from getting closer more than necessary. In addition, in the case where the EL layer 692 or the conductive layer 693a is formed using a blocking mask (metal mask), the insulating layer 717 may have a function of preventing the blocking mask from being in contact with a surface on which the EL layer 692 or the conductive layer 693a is formed. Note that the insulating layer 717 is not necessarily provided when not needed.

One of a source and a drain of the transistor 705 is connected to the conductive layer 691 of the light-emitting element 520 through a conductive layer 724.

One of a source and a drain of the transistor 706 is connected to the conductive layer 530b through a connection portion 707. The conductive layers 530b and 530a are in contact with and connected to each other. Here, in the connection portion 707, the conductive layers provided on both surfaces of the insulating layer 720 are connected to each other through openings in the insulating layer 720.

A connection portion 704 is provided in a region where the substrates 551 and 561 do not overlap with each other. The connection portion 704 is connected to the FPC 572 through an insulating layer 742. The connection portion 704 has a structure similar to that of the connection portion 707. On the top surface of the connection portion 704, a conductive layer obtained by processing the same conductive film as the conductive layer 530a is exposed. Thus, the connection portion 704 and the FPC 572 can be connected to each other through the connection layer 742.

A connection portion 752 is provided in part of a region where the adhesive layer 641 is provided. In the connection portion 752, the conductive layer obtained by processing the same conductive film as the conductive layer 530a is connected to part of the conductive layer 613 with a connector 743. Accordingly, a signal or a potential input from the FPC 572 connected to the substrate 551 side can be supplied to the conductive layer 613 formed on the substrate 561 side through the connection portion 752.

As the connector 743, a conductive particle can be used, for example. As the conductive particle, a particle of an organic resin, silica, or the like coated with a metal material can be used. It is preferable to use nickel or gold as the metal material because contact resistance can be decreased. It is also preferable to use a particle coated with layers of two or more kinds of metal materials, such as a particle coated with nickel and further with gold. As the connector 743, a material capable of elastic deformation or plastic deformation is preferably used. As illustrated in FIG. 24, the connector 743 which is the conductive particle has a shape that is vertically crushed in some cases. With the crushed shape, the contact area between the connector 743 and a conductive layer electrically connected to the connector 743 can be increased, thereby reducing contact resistance and suppressing the generation of problems such as disconnection.

The connector 743 is preferably provided so as to be covered with the adhesive layer 641. For example, the connectors 743 may be dispersed in the adhesive layer 641 before curing of the adhesive layer 641.

FIG. 24 illustrates an example of the circuit 564 in which the transistor 701 is provided.

The structure in which the semiconductor layer 731 where a channel is formed is provided between a pair of gates is used as an example of the transistors 701 and 705 in FIG. 24. One gate is formed with the conductive layer 721, and the other gate is formed with a conductive layer 723 overlapping with the semiconductor layer 731 with the insulating layer 712 provided therebetween. Such a structure enables control of threshold voltages of the transistors. In that case, the two gates may be connected to each other and supplied with the same signal to operate the transistors. Such transistors can have a higher field-effect mobility and thus have a higher on-state current than other transistors. Consequently, a circuit capable of high-speed operation can be obtained. Furthermore, the area occupied by a circuit portion can be reduced. The use of the transistor having a high on-state current can reduce signal delay in wirings and can reduce display unevenness even in a display device in which the number of wirings is increased because of increase in size or definition.

Note that the transistor included in the circuit 564 and the transistor included in the display region 562 may have the same structure. A plurality of transistors included in the circuit 564 may have the same structure or different structures. A plurality of transistors included in the display region 562 may have the same structure or different structures.

A material through which impurities such as water or hydrogen do not easily diffuse is preferably used for at least one of the insulating layers 712 and 713 which cover the transistors. That is, the insulating layer 712 or the insulating layer 713 can function as a barrier film. Such a structure can effectively suppress diffusion of the impurities into the transistors from the outside, and a highly reliable display device can be achieved.

The insulating layer 621 is provided on the substrate 561 side to cover the coloring layer 631 and the light-blocking layer 632. The insulating layer 621 may have a function of a planarization layer. The insulating layer 621 enables the conductive layer 613 to have an almost flat surface, resulting in a uniform alignment state of the liquid crystal 612.

An example of a method for manufacturing the display device 500 is described. For example, the conductive layer 530a, the conductive layer 530b, and the insulating layer 720 are formed in order over a support substrate provided with a separation layer, and the transistor 705, the transistor 706, the light-emitting element 520, and the like are formed. Then, the substrate 551 and the support substrate are bonded with the adhesive layer 642. After that, separation is made to occur at the interface between the separation layer and each of the insulating layer 720 and the conductive layer 530a, whereby the support substrate and the separation layer are removed. Separately, the coloring layer 631, the light-blocking layer 632, the conductive layer 613, and the like are formed over the substrate 561 in advance. Then, the liquid crystal 612 is dropped onto the substrate 551 or 561 and the substrates 551 and 561 are bonded with the adhesive layer 641, whereby the display device 500 can be manufactured.

A material for the separation layer can be selected as appropriate such that separation at the interface with the insulating layer 720 and the conductive layer 530a occurs. In particular, it is preferable that a stacked layer of a layer including a high-melting-point metal material, such as tungsten, and a layer including an oxide of the metal material be used as the separation layer, and a stacked layer of a plurality of layers, such as a silicon nitride layer, a silicon oxynitride layer, and a silicon nitride oxide layer be used as the insulating layer 720 over the separation layer. The use of the high-melting-point metal material for the separation layer can increase the formation temperature of a layer formed in a later step, which reduces the impurity concentration and achieves a highly reliable display device.

A metal oxide, a metal nitride, or the like is preferably used for the conductive layer 530a. In the case of using a metal oxide, a material in which at least one of the concentrations of hydrogen, boron, phosphorus, nitrogen, and other impurities and the number of oxygen vacancies is made to be higher than those in the semiconductor layer of the transistor is used for the conductive layer 530a.

The above components will be described below.

### [Substrate]

A material having a flat surface can be used as the substrate included in the display device. The substrate through which light emitted from the display element is extracted is formed using a material that transmits the light. For example, a material such as glass, quartz, ceramics, sapphire, or an organic resin can be used.

The weight and thickness of the display device can be decreased by using a thin substrate. Furthermore, a flexible display device can be obtained by using a substrate that is thin enough to have flexibility.

Since the substrate through which light emission is not extracted does not need to have a light-transmitting property, a metal substrate or the like can be used in addition to the above-mentioned substrates. A metal substrate, which has high thermal conductivity, is preferable because it can easily conduct heat to the whole substrate and accordingly can prevent a local temperature rise in the display device. To obtain flexibility or bendability, the thickness of a metal substrate is preferably greater than or equal to 10 μm and less than or equal to 200 μm, more preferably greater than or equal to 20 μm and less than or equal to 50 μm.

Although there is no particular limitation on a material of a metal substrate, it is favorable to use, for example, a metal such as aluminum, copper, and nickel, an aluminum alloy, or an alloy such as stainless steel.

It is preferable to use a substrate subjected to insulation treatment, e.g., a metal substrate whose surface is oxidized or provided with an insulating film. The insulating film may be formed by, for example, a coating method such as a spin-coating method or a dipping method, an electrodeposition method, an evaporation method, or a sputtering method. An oxide film may be formed on the substrate surface by exposure to or heating in an oxygen atmosphere or by an anodic oxidation method or the like.

Examples of a material having flexibility and a light-transmitting property with respect to visible light include glass that is thin enough to have flexibility, polyester resins such as polyethylene terephthalate (PET) and polyethylene naphthalate (PEN), a polyacrylonitrile resin, a polyimide resin, a polymethyl methacrylate resin, a polycarbonate (PC) resin, a polyethersulfone (PES) resin, a polyamide resin, a cycloolefin resin, a polystyrene resin, a polyamide imide resin, a polyvinyl chloride resin, and a polytetrafluoroethylene (PTFE) resin. In particular, a material whose thermal expansion coefficient is low is preferred, and for example, a polyamide imide resin, a polyimide resin, or PET with a thermal expansion coefficient of 30×10⁻⁶/K or less can be suitably used. A substrate in which a glass fiber is impregnated with an organic resin or a substrate whose thermal expansion coefficient is reduced by mixing an organic resin with an inorganic filler can also be used. A substrate using such a material is lightweight, and thus, a display device using this substrate can also be lightweight.

In the case where a fibrous body is included in the above material, a high-strength fiber of an organic compound or an inorganic compound is used as the fibrous body. The high-strength fiber is specifically a fiber with a high tensile elastic modulus or a fiber with a high Young's modulus. Typical examples thereof include a polyvinyl alcohol based fiber, a polyester based fiber, a polyamide based fiber, a polyethylene based fiber, an aramid based fiber, a polyparaphenylene benzobisoxazole fiber, a glass fiber, and a carbon fiber. As the glass fiber, a glass fiber using E glass, S glass, D glass, Q glass, and the like can be given. These fibers may be used in a state of a woven or nonwoven fabric, and a structure body in which this fibrous body is impregnated with a resin and the resin is cured may be used as the flexible substrate. The structure body including the fibrous body and the resin is preferably used as the flexible substrate, in which case the reliability against bending or breaking due to local pressure can be increased.

Alternatively, glass, metal, or the like that is thin enough to have flexibility can be used as the substrate. Alternatively, a composite material in which glass and a resin material are attached to each other with an adhesive layer may be used.

A hard coat layer (e.g., a silicon nitride layer and an aluminum oxide layer) by which a surface of a display device is protected from damage, a layer (e.g., an aramid resin layer) that can disperse pressure, or the like may be stacked over the flexible substrate. Furthermore, to suppress a decrease in lifetime of the display element due to moisture and the like, an insulating film with low water permeability may be stacked over the flexible substrate. For example, an inorganic insulating material such as silicon nitride, silicon oxynitride, silicon nitride oxide, aluminum oxide, or aluminum nitride can be used.

The substrate may be formed by stacking a plurality of layers. In particular, when a glass layer is used, a barrier property against water and oxygen can be improved, and thus, a highly reliable display device can be provided.

### [Transistor]

The transistors each include a conductive layer functioning as the gate electrode, the semiconductor layer, a conductive layer functioning as the source electrode, a conductive layer functioning as the drain electrode, and an insulating layer functioning as the gate insulating layer. In the above, a bottom-gate transistor is used.

Note that there is no particular limitation on the structure of the transistor included in the display device of one embodiment of the present invention. For example, a planar transistor, a staggered transistor, or an inverted staggered transistor may be used. A top-gate transistor or a bottom-gate transistor may be used. Gate electrodes may be provided above and below a channel.

There is no particular limitation on the crystallinity of a semiconductor material used for the transistor, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be suppressed.

As a semiconductor material used for the transistor, an element of Group 14 (e.g., silicon or germanium) or a metal oxide can be used, for example. A semiconductor containing silicon, a semiconductor containing gallium arsenide, a metal oxide containing indium, or the like can be typically used.

In particular, a metal oxide having a wider band gap than silicon is preferably used. A semiconductor material having a wider band gap and a lower carrier density than silicon is preferably used because the on-state current of the transistor can be reduced.

A transistor with a metal oxide whose band gap is wider than that of silicon can hold charge stored in a capacitor that is series-connected to the transistor for a long time, owing to a low off-state current of the transistor. The use of such a transistor in pixels allows a driver circuit to stop while the gray level of an image displayed in display regions is maintained. As a result, a display device with an extremely low power consumption can be obtained.

The semiconductor layer preferably includes, for example, a film represented by an In-M-Zn-based oxide that contains at least indium, zinc, and M (a metal such as aluminum, titanium, gallium, germanium, yttrium, zirconium, lanthanum, cerium, tin, neodymium, or hafnium). In order to reduce variations in electric characteristics of the transistors including the semiconductor layer, the semiconductor layer preferably contains a stabilizer in addition to the above.

Examples of the stabilizer, including metals that can be used as M, are gallium, tin, hafnium, aluminum, and zirconium. As another stabilizer, lanthanoid such as lanthanum, cerium, praseodymium, neodymium, samarium, europium, gadolinium, terbium, dysprosium, holmium, erbium, thulium, ytterbium, or lutetium can be given.

As a metal oxide included in the semiconductor layer, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

Note that here, for example, an “In—Ga—Zn-based oxide” means an oxide containing In, Ga, and Zn as its main components and there is no limitation on the ratio of In:Ga:Zn. Furthermore, a metal element in addition to In, Ga, and Zn may be contained.

The semiconductor layer and the conductive layer may include the same metal elements contained in the above oxides. The use of the same metal elements for the semiconductor layer and the conductive layer can reduce the manufacturing cost. For example, the use of metal oxide targets with the same metal composition can reduce the manufacturing cost. In addition, the same etching gas or the same etchant can be used in processing the semiconductor layer and the conductive layer. Note that even when the semiconductor layer and the conductive layer include the same metal elements, they have different compositions in some cases. For example, a metal element in a film is released during the manufacturing process of the transistor and the capacitor, which might result in different metal compositions.

The energy gap of the metal oxide included in the semiconductor layer is greater than or equal to 2 eV, preferably greater than or equal to 2.5 eV, more preferably greater than or equal to 3 eV. With the use of a metal oxide having such a wide energy gap, the off-state current of the transistor can be reduced.

In the case where the metal oxide contained in the semiconductor layer contains an In-M-Zn-based oxide, it is preferable that the atomic ratio of metal elements of a sputtering target used for forming a film of the In-M-Zn oxide satisfy In≧M and Zn≧M. As the atomic ratio of metal elements of such a sputtering target, In:M:Zn=1:1:1, In:M:Zn=1:1:1.2, In:M:Zn=3:1:2, In:M:Zn=4:2:4.1 and the like are preferable. Note that the atomic ratio of metal elements in the formed semiconductor layer varies from the above atomic ratio of metal elements of the sputtering target within a range of ±40% as an error.

A metal oxide with a low carrier density is preferably used for the semiconductor layer. For example, the semiconductor layer is a metal oxide whose carrier density is lower than or equal to 1×10¹⁷/cm³, preferably lower than or equal to 1×10¹⁵/cm³, more preferably lower than or equal to 1×10¹³/cm³, more preferably lower than or equal to 1×10¹¹/cm³, more preferably lower than 1×10¹⁰/cm³, and higher than or equal to 1×10⁻⁹/cm³. Such a semiconductor layer has a low impurity concentration and a low density of defect states and thus has stable characteristics.

Note that without limitation to the compositions and materials described above, a material with an appropriate composition can be used depending on required semiconductor characteristics and electric characteristics (e.g., field-effect mobility and threshold voltage) of a transistor. To obtain the required semiconductor characteristics of the transistor, it is preferable that the carrier density, the impurity concentration, the defect density, the atomic ratio between a metal element and oxygen, the interatomic distance, the density, and the like of the semiconductor layer be set to appropriate values.

When silicon or carbon that is one of elements belonging to Group 14 is contained in the metal oxide contained in the semiconductor layer, oxygen vacancies are increased in the semiconductor layer, and the semiconductor layer might become n-type. Thus, the concentration of silicon or carbon (measured by secondary ion mass spectrometry) in the semiconductor layer is preferably lower than or equal to 2×10¹⁸ atoms/cm³, more preferably lower than or equal to 2×10¹⁷ atoms/cm³.

An alkali metal and an alkaline earth metal might generate carriers when bonded to a metal oxide, in which case the off-state current of the transistor might be increased. Therefore, the concentration of an alkali metal or alkaline earth metal of the semiconductor layer, which is measured by secondary ion mass spectrometry, is preferably lower than or equal to 1×10¹⁸ atoms/cm³, more preferably lower than or equal to 2×10¹⁶ atoms/cm³.

The semiconductor layer may have a non-single-crystal structure, for example. Non-single-crystal structures include a polycrystalline structure, a microcrystalline structure, and an amorphous structure, for example. Among the non-single-crystal structure, the amorphous structure has the highest density of defect states.

A metal oxide having an amorphous structure has disordered atomic arrangement and no crystalline component, for example. Alternatively, an oxide film having an amorphous structure has, for example, an absolutely amorphous structure and no crystal part.

Note that the semiconductor layer may be a mixed film including two or more of the following: a region having an amorphous structure, a region having a microcrystalline structure, a region having a polycrystalline structure, and a region having a single crystal structure. The mixed film has, for example, a single-layer structure or a stacked-layer structure including two or more of the above regions in some cases.

Alternatively, silicon is preferably used as a semiconductor in which a channel of the transistor is formed. Silicon may be amorphous silicon but is preferably silicon having crystallinity, such as microcrystalline silicon, polycrystalline silicon, or single crystal silicon. In particular, polycrystalline silicon can be formed at a lower temperature than single crystal silicon and has a higher field-effect mobility and higher reliability than amorphous silicon. The use of such a polycrystalline semiconductor in pixels increases the aperture ratio of the pixels. Even in the case where the display portion with an extremely high definition is provided, a driver circuit can be formed over a substrate over which the pixels are formed, and the number of components of an electronic device can be reduced.

The bottom-gate transistor described in this embodiment is preferable because the number of manufacturing steps can be reduced. When amorphous silicon, which can be formed at a lower temperature than polycrystalline silicon, is used, materials with low heat resistance can be used for a wiring, an electrode, or a substrate below the semiconductor layer, resulting in wider choice of materials. For example, an extremely large glass substrate can be favorably used. Meanwhile, the top-gate transistor is preferable because an impurity region is easily formed in a self-aligned manner and variation in characteristics can be reduced. In that case, the use of polycrystalline silicon, single crystal silicon, or the like is particularly preferable.

### [Conductive Layer]

As materials for a gate, a source, and a drain of a transistor, and a conductive layer such as a wiring or an electrode included in a display device, any of metals such as aluminum, titanium, chromium, nickel, copper, yttrium, zirconium, molybdenum, silver, tantalum, and tungsten, an alloy containing any of these metals as its main component, or the like can be used. A single layer structure or stacked-layer structure including a film containing any of these materials can be used. For example, the following structures can be given: a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which a titanium film or a titanium nitride film, an aluminum film or a copper film, and a titanium film or a titanium nitride film are stacked in this order, and a three-layer structure in which a molybdenum film or a molybdenum nitride film, an aluminum film or a copper film, and a molybdenum film or a molybdenum nitride film are stacked in this order. Note that an oxide such as indium oxide, tin oxide, or zinc oxide may be used. Copper containing manganese is preferably used because controllability of the shape by etching is increased.

As a light-transmitting conductive material, a conductive oxide such as indium oxide, indium tin oxide, indium zinc oxide, zinc oxide, or zinc oxide to which gallium is added, or graphene can be used. It is also possible to use a metal material such as gold, silver, platinum, magnesium, nickel, tungsten, chromium, molybdenum, iron, cobalt, copper, palladium, or titanium; an alloy material containing any of these metal materials; or a nitride of the metal material (e.g., titanium nitride). In the case of using the metal material or the alloy material (or the nitride thereof), the film thickness is set small enough to transmit light. Alternatively, a stacked film of any of the above materials can be used for the conductive layers. For example, a stacked film of indium tin oxide and an alloy of silver and magnesium is preferably used because the conductivity can be increased. They can also be used for conductive layers such as a variety of wirings and electrodes included in a display device, and conductive layers (e.g., conductive layers serving as a pixel electrode or a common electrode) included in a display element.

### [Insulating Layer]

Examples of an insulating material that can be used for the insulating layers include a resin such as acrylic or epoxy resin, a resin having a siloxane bond such as silicone, and an inorganic insulating material such as silicon oxide, silicon oxynitride, silicon nitride oxide, silicon nitride, or aluminum oxide.

The light-emitting element is preferably provided between a pair of insulating films with low water permeability, in which case impurities such as water can be prevented from entering the light-emitting element. Thus, a decrease in device reliability can be prevented.

Examples of the insulating film with low water permeability include a film containing nitrogen and silicon (e.g., a silicon nitride film and a silicon nitride oxide film) and a film containing nitrogen and aluminum (e.g., an aluminum nitride film). Alternatively, a silicon oxide film, a silicon oxynitride film, an aluminum oxide film, or the like may be used.

For example, the water vapor transmission rate of the insulating film with low water permeability is lower than or equal to 1×10⁻⁵ [g/(m²·day)], preferably lower than or equal to 1×10⁻⁶ [g/(m²·day)], more preferably lower than or equal to 1×10⁻⁷ [g/(m²·day)], more preferably lower than or equal to 1×10⁻⁸ [g/(m²·day)].

### [Liquid Crystal Element]

The liquid crystal element can employ, for example, a vertical alignment (VA) mode. Examples of the vertical alignment mode include a multi-domain vertical alignment (MVA) mode, a patterned vertical alignment (PVA) mode, and an advanced super view (ASV) mode.

The liquid crystal element can employ a variety of modes. For example, a liquid crystal element using, instead of a VA mode, a twisted nematic (TN) mode, an in-plane switching (IPS) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, or the like can be used.

The liquid crystal element controls transmission or non-transmission of light utilizing an optical modulation action of liquid crystal. The optical modulation action of liquid crystal is controlled by an electric field applied to the liquid crystal (including a horizontal electric field, a vertical electric field, and a diagonal electric field). As the liquid crystal used for the liquid crystal element, thermotropic liquid crystal, low-molecular liquid crystal, high-molecular liquid crystal, polymer dispersed liquid crystal (PDLC), ferroelectric liquid crystal, anti-ferroelectric liquid crystal, or the like can be used. Such a liquid crystal material exhibits a cholesteric phase, a smectic phase, a cubic phase, a chiral nematic phase, an isotropic phase, or the like depending on conditions.

As the liquid crystal material, either a positive liquid crystal or a negative liquid crystal may be used, and an appropriate liquid crystal material can be used depending on the mode or design to be used.

An alignment film can be provided to adjust the alignment of liquid crystal. In the case where a horizontal electric field mode is employed, liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase appears only in a narrow temperature range, a liquid crystal composition in which several weight percent or more of a chiral material is mixed is used for the liquid crystal layer in order to improve the temperature range. The liquid crystal composition which includes liquid crystal exhibiting a blue phase and a chiral material has a short response time and optical isotropy. In addition, the liquid crystal composition that includes liquid crystal exhibiting a blue phase and a chiral material does not need alignment treatment and has small viewing angle dependence. An alignment film does not need to be provided and rubbing treatment is thus not necessary; accordingly, electrostatic discharge damage caused by the rubbing treatment can be prevented and defects and damage of the liquid crystal display device in the manufacturing process can be reduced.

The liquid crystal element may be a transmissive liquid crystal element, a reflective liquid crystal element, a transflective liquid crystal element, or the like. In one embodiment of the present invention, in particular, the reflective liquid crystal element is preferably used.

In the case where a transmissive or transflective liquid crystal element is used, two polarizing plates are provided such that a pair of substrates are sandwiched therebetween. Furthermore, a backlight is provided on the outer side of the polarizing plate. As the backlight, a direct-below backlight or an edge-light type backlight may be used. The direct-below backlight including a light-emitting diode (LED) is preferably used because local dimming is easily performed to improve the contrast. The edge-light type backlight is preferably used because the thickness of a module including the backlight can be reduced.

In the case where a reflective liquid crystal element is used, a polarizing plate is provided on a display surface. In addition, a light diffusion plate is preferably provided on the display surface to improve the visibility.

In the case where the reflective or the transflective liquid crystal element is used, a front light may be provided outside the polarizing plate. As the front light, an edge-light type front light is preferably used. A front light including a light-emitting diode (LED) is preferably used to reduce the power consumption.

### [Light-Emitting Element]

The light-emitting element has a top emission structure, a bottom emission structure, a dual emission structure, or the like. A conductive film that transmits visible light is used as the electrode through which light is extracted. A conductive film that reflects visible light is preferably used as the electrode through which light is not extracted. In one embodiment of the present invention, in particular, a bottom-emission light-emitting element is preferably used.

The EL layer includes at least a light-emitting layer. In addition to the light-emitting layer, the EL layer may further include one or more layers containing any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

For the EL layer, either a low-molecular compound or a high-molecular compound can be used, and an inorganic compound may also be used. Each of the layers included in the EL layer can be formed by any of the following methods: an evaporation method (including a vacuum evaporation method), a transfer method, a printing method, an inkjet method, a coating method, and the like.

When a voltage higher than the threshold voltage of the light-emitting element is applied between a cathode and an anode, holes are injected to the EL layer from the anode side and electrons are injected to the EL layer from the cathode side. The injected electrons and holes are recombined in the EL layer and a light-emitting substance contained in the EL layer emits light.

In the case where a light-emitting element emitting white light is used as the light-emitting element, the EL layer preferably contains two or more kinds of light-emitting substances. For example, the two or more kinds of light-emitting substances are selected so as to emit light of complementary colors to obtain white light emission. Specifically, it is preferable to contain two or more selected from light-emitting substances emitting light of red (R), green (G), blue (B), yellow (Y), orange (O), and the like and light-emitting substances emitting light containing two or more of spectral components of R, G, and B. The light-emitting element preferably emits light with a spectrum having two or more peaks in the wavelength range of a visible light region (e.g., greater than or equal to 350 nm and less than or equal to 750 nm). An emission spectrum of a material emitting light having a peak in a yellow wavelength range preferably includes spectral components also in green and red wavelength ranges.

More preferably, a light-emitting layer containing a light-emitting material emitting light of one color and a light-emitting layer containing a light-emitting material emitting light of another color are stacked in the EL layer. For example, the plurality of light-emitting layers in the EL layer may be stacked in contact with each other or may be stacked with a region which does not include any light-emitting material therebetween. For example, between a fluorescent layer and a phosphorescent layer, a region containing the same material as one in the fluorescent layer or phosphorescent layer (for example, a host material or an assist material) and no light-emitting material may be provided. This facilitates the manufacture of the light-emitting element and reduces the drive voltage.

The light-emitting element may be a single element including one EL layer or a tandem element in which a plurality of EL layers are stacked with a charge generation layer therebetween.

The conductive film that transmits visible light can be formed using, for example, indium oxide, indium tin oxide, indium zinc oxide, zinc oxide, or zinc oxide to which gallium is added. Alternatively, a film of a metal material such as gold, silver, platinum, magnesium, nickel, tungsten, chromium, molybdenum, iron, cobalt, copper, palladium, or titanium; an alloy containing any of these metal materials; or a nitride of any of these metal materials (e.g., titanium nitride) can be formed thin so as to have a light-transmitting property. Alternatively, a stacked film of any of the above materials can be used for the conductive layers. For example, a stacked film of indium tin oxide and an alloy of silver and magnesium is preferably used, in which case the conductivity can be increased. Further alternatively, graphene or the like may be used.

For the conductive film that reflects visible light, for example, a metal material such as aluminum, gold, platinum, silver, nickel, tungsten, chromium, molybdenum, iron, cobalt, copper, or palladium or an alloy containing any of these metal materials can be used. Furthermore, lanthanum, neodymium, germanium, or the like may be added to the metal material or the alloy. Alternatively, an alloy containing aluminum (an aluminum alloy) such as an alloy of aluminum and titanium, an alloy of aluminum and nickel, or an alloy of aluminum and neodymium may be used. Alternatively, an alloy containing silver such as an alloy of silver and copper, an alloy of silver and palladium, or an alloy of silver and magnesium may be used. An alloy containing silver and copper is preferable because of its high heat resistance. Furthermore, when a metal film or a metal oxide film is stacked in contact with an aluminum film or an aluminum alloy film, oxidation can be suppressed. Examples of a material for the metal film or the metal oxide film include titanium and titanium oxide. Alternatively, the above conductive film that transmits visible light and a film containing a metal material may be stacked. For example, a stack of silver and indium tin oxide, a stack of an alloy of silver and magnesium and indium tin oxide, or the like can be used.

Each of the electrodes can be formed by an evaporation method or a sputtering method. Alternatively, a discharging method such as an inkjet method, a printing method such as a screen printing method, or a plating method may be used.

Note that the aforementioned light-emitting layer and layers containing a substance with a high hole-injection property, a substance with a high hole-transport property, a substance with a high electron-transport property, a substance with a high electron-injection property, and a substance with a bipolar property may include an inorganic compound such as a quantum dot or a high molecular compound (e.g., an oligomer, a dendrimer, and a polymer). For example, a quantum dot used for the light-emitting layer can function as a light-emitting material.

The quantum dot may be a colloidal quantum dot, an alloyed quantum dot, a core-shell quantum dot, a core quantum dot, or the like. The quantum dot containing elements belonging to Groups 12 and 16, elements belonging to Groups 13 and 15, or elements belonging to Groups 14 and 16, may be used. Alternatively, the quantum dot containing an element such as cadmium, selenium, zinc, sulfur, phosphorus, indium, tellurium, lead, gallium, arsenic, or aluminum may be used.

### [Adhesive Layer]

As the adhesive layers, a variety of curable adhesives such as a reactive curable adhesive, a thermosetting adhesive, an anaerobic adhesive, and a photo-curable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, and the like. In particular, a material with low moisture permeability, such as an epoxy resin, is preferred. Alternatively, a two-component type resin may be used. Still alternatively, an adhesive sheet or the like may be used.

Furthermore, the resin may include a drying agent. For example, a substance that adsorbs moisture by chemical adsorption, such as oxide of an alkaline earth metal (e.g., calcium oxide or barium oxide), can be used. Alternatively, a substance that adsorbs moisture by physical adsorption, such as zeolite or silica gel, may be used. The drying agent is preferably included because it can prevent impurities such as moisture from entering the element, thereby improving the reliability of the display device.

In addition, it is preferable to mix a filler with a high refractive index or light-scattering member into the resin, in which case the light extraction efficiency can be enhanced. For example, titanium oxide, barium oxide, zeolite, zirconium, or the like can be used.

### [Connection Layer]

As the connection layers, an anisotropic conductive film (ACF), an anisotropic conductive paste (ACP), or the like can be used.

### [Coloring Layer]

As examples of a material that can be used for the coloring layers, a metal material, a resin material, and a resin material containing a pigment or dye can be given.

### [Light-Blocking Layer]

Examples of a material that can be used for the light-blocking layer include carbon black, titanium black, a metal, a metal oxide, and a composite oxide containing a solid solution of a plurality of metal oxides. The light-blocking layer may be a film containing a resin material or a thin film of an inorganic material such as a metal. Stacked films containing the material of the coloring layer can also be used for the light-blocking layer. For example, a stacked-layer structure of a film containing a material of a coloring layer which transmits light of a certain color and a film containing a material of a coloring layer which transmits light of another color can be employed. It is preferable that the coloring layer and the light-blocking layer be formed using the same material because the same manufacturing apparatus can be used and the process can be simplified.

The above is the description of the components.

### [Example of Manufacturing Method]

Next, a manufacturing method example of a display device using a flexible substrate is described.

Here, layers including a display element, a circuit, a wiring, an electrode, optical members such as a coloring layer and a light-blocking layer, an insulating layer, and the like, are collectively referred to as an element layer. The element layer includes, for example, a display element, and may additionally include a wiring electrically connected to the display element or an element such as a transistor used in a pixel or a circuit.

In addition, here, a flexible member which supports the element layer at a stage at which the display element is completed (the manufacturing process is finished) is referred to as a substrate. For example, a substrate includes an extremely thin film with a thickness greater than or equal to 10 nm and less than or equal to 300 μm and the like.

As a method for forming an element layer over a flexible substrate provided with an insulating surface, typically, there are two methods shown below. One of them is to directly form an element layer over the substrate. The other method is to form an element layer over a supporting substrate that is different from the substrate and then to separate the element layer from the supporting substrate to be transferred to the substrate. Although not described in detail here, in addition to the above two methods, there is a method in which the element layer is formed over a substrate which does not have flexibility and the substrate is thinned by polishing or the like to have flexibility.

In the case where a material of the substrate can withstand heating temperature in a process for forming the element layer, it is preferable that the element layer be formed directly over the substrate, in which case the manufacturing process can be simplified. At this time, the element layer is preferably formed in a state where the substrate is fixed to the supporting substrate, in which case transfer thereof in an apparatus and between apparatuses can be easy.

In the case of employing the method in which the element layer is formed over the supporting substrate and then transferred to the substrate, first, a separation layer and an insulating layer are stacked over the supporting substrate, and then the element layer is formed over the insulating layer. Next, the element layer is separated from the supporting substrate and then transferred to the substrate. At this time, a material is selected that would cause separation at the interface between the supporting substrate and the separation layer, at the interface between the separation layer and the insulating layer, or in the separation layer. In the method, it is preferred that a material having high heat resistance be used for the supporting substrate or the separation layer, in which case the upper limit of the temperature applied when the element layer is formed can be higher, and an element layer including a more reliable element can be formed.

For example, it is preferable that a stack of a layer containing a high-melting-point metal material, such as tungsten, and a layer containing an oxide of the metal material be used as the separation layer, and a stack of a plurality of layers, such as a silicon oxide layer, a silicon nitride layer, a silicon oxynitride layer, and a silicon nitride oxide layer be used as the insulating layer over the separation layer. Note that in this specification, oxynitride contains more oxygen than nitrogen, and nitride oxide contains more nitrogen than oxygen.

The element layer and the supporting substrate can be separated by applying mechanical power, by etching the separation layer, by injecting a liquid into the separation interface, or the like. Alternatively, separation may be performed by heating or cooling two layers of the separation interface by utilizing a difference in thermal expansion coefficient.

The separation layer is not necessarily provided in the case where separation can occur at the interface between the supporting substrate and the insulating layer.

For example, glass and an organic resin such as polyimide can be used as the supporting substrate and the insulating layer, respectively. In that case, a separation trigger may be formed by, for example, locally heating part of the organic resin with laser light or the like, or by physically cutting part of or making a hole through the organic resin with a sharp tool, so that separation may be performed at the interface between the glass and the organic resin.

Alternatively, a heat-generation layer may be provided between the supporting substrate and the insulating layer formed of an organic resin, and separation may be performed at the interface between the heat-generation layer and the insulating layer by heating the heat-generation layer. The heat-generation layer can be formed using a variety of materials such as a material that generates heat when current flows therethrough, a material that generates heat when absorbs light, or a material that generates heat when applied with a magnetic field. For example, a semiconductor, a metal, or an insulator can be selected for the heat-generation layer.

In the aforementioned methods, the insulating layer formed of an organic resin can be used as a substrate after the separation.

The above is the description of a manufacturing method of a flexible display device.

This embodiment can be combined with any of the other embodiments as appropriate.

### Embodiment 6

In this embodiment, a structure example of an OS transistor that can be used in the above embodiment will be described.

### <Structural Example of Transistor>

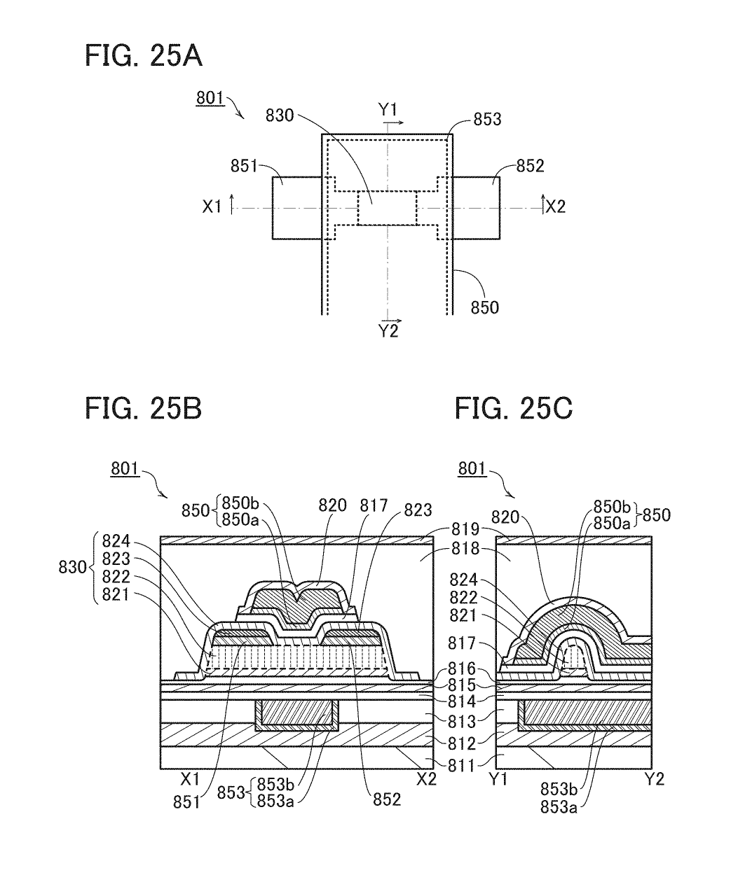

FIG. 25A is a top view illustrating a structure example of a transistor. FIG. 25B is a cross-sectional view taken along line X1-X2 in FIG. 25A. FIG. 25C is a cross-sectional view taken along line Y1-Y2 in FIG. 25A. In some cases, the direction of line X1-X2 is referred to as a channel length direction, and the direction of line Y1-Y2 is referred to as a channel width direction. FIG. 25B illustrates a cross-sectional structure of the transistor in the channel length direction, and FIG. 25C illustrates a cross-sectional structure of the transistor in the channel width direction. Note that to clarify the device structure, FIG. 25A does not illustrate some components.

The semiconductor device of one embodiment of the present invention includes insulating layers 812 to 820, metal oxide films 821 to 824, and conductive layers 850 to 853. A transistor 801 is formed over an insulating surface. FIGS. 25A to 25C illustrate the case where the transistor 801 is formed over an insulating layer 811. The transistor 801 is covered with the insulating layer 818 and an insulating layer 819.

Note that the insulating layers, the metal oxide films, the conductive layers, and the like that constitute the transistor 801 may each be a single film, or a stack including a plurality of films. They can be formed by any of a variety of deposition methods such as a sputtering method, a molecular beam epitaxy (MBE) method, a pulsed laser ablation (PLA) method, a CVD method, an atomic layer deposition (ALD) method, and the like. Note that examples of CVD methods include a plasma-enhanced CVD method, a thermal CVD method, a metal organic CVD method, and the like.

The conductive layer 850 includes a region that functions as a gate electrode of the transistor 801. A conductive layer 851 and a conductive layer 852 include regions that function as a source electrode and a drain electrode. The conductive layer 853 includes a region that functions as a back gate electrode. The insulating layer 817 includes a region that functions as a gate insulating layer on the gate electrode (front gate electrode) side, and an insulating layer that is a stack of the insulating layers 814 to 816 includes a region that functions as a gate insulating layer on the back gate electrode side. The insulating layer 818 functions as an interlayer insulating layer. The insulating layer 819 functions as a barrier layer.

The metal oxide films 821 to 824 are collectively referred to as an oxide layer 830. As illustrated in FIGS. 25B and 25C, the oxide layer 830 includes a region where the metal oxide film 821, the metal oxide film 822, and the metal oxide film 824 are stacked in this order. In addition, a pair of the metal oxide films 823 are positioned over the conductive layer 851 and the conductive layer 852. When the transistor 801 is on, a channel formation region is mainly formed in the metal oxide film 822 of the oxide layer 830.

The metal oxide film 824 covers the metal oxide films 821 to 823, the conductive layer 851, and the conductive layer 852. The insulating layer 817 is positioned between the metal oxide film 823 and the conductive layer 850. The conductive layers 851 and 852 each include a region that overlaps with the conductive layer 850 with the metal oxide film 823, the metal oxide film 824, and the insulating layer 817 positioned therebetween.

The conductive layers 851 and 852 are formed from a hard mask that is used in the formation of the metal oxide films 821 and 822. Thus, the conductive layers 851 and 852 do not include a region that is in contact with the side surfaces of the metal oxide films 821 and 822. For example, the metal oxide films 821 and 822 and the conductive layers 851 and 852 can be formed through the following steps. First, a conductive film is formed over a metal oxide film including a stack of two layers. The conductive film is processed (etched) into a desired shape so that a hard mask is formed. The hard mask is used to process the shape of the two-layered metal oxide film, forming the metal oxide films 821 and 822 that are stacked. Next, the hard mask is processed into a desired shape, forming the conductive layers 851 and 852.

Examples of insulating materials used for the insulating layers 811 to 818 include aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, and aluminum silicate. The insulating layers 811 to 818 are formed using a single-layer structure or a stacked-layer structure containing any of these insulating materials. The layers used for the insulating layers 811 to 818 may include a plurality of insulating materials.

In this specification and the like, oxynitride refers to a compound in which the oxygen content is higher than the nitrogen content, and nitride oxide refers to a compound in which the nitrogen content is higher than the oxygen content.

In order to suppress an increase in oxygen vacancies in the oxide layer 830, the insulating layers 816 to 818 preferably contain oxygen. More preferably, the insulating layers 816 to 818 are formed using an insulating film from which oxygen is released by heating (hereinafter such an insulating film is also referred to as an insulating film containing excess oxygen). When oxygen is supplied from the insulating film containing excess oxygen to the oxide layer 830, the oxygen vacancies in the oxide layer 830 can be compensated. Thus, the reliability and electric characteristics of the transistor 801 can be improved.

The insulating layer containing excess oxygen is a film from which oxygen molecules at more than or equal to 1.0×10¹⁸ molecules/cm³ are released in thermal desorption spectroscopy (TDS) at a surface temperature of the film of higher than or equal to 100° C. and lower than or equal to 700° C., or higher than or equal to 100° C. and lower than or equal to 500° C. The amount of released oxygen molecules is preferably more than or equal to 3.0×10²⁰ atoms/cm³.

The insulating film containing excess oxygen can be formed by performing treatment for adding oxygen to an insulating film. The treatment for adding oxygen can be performed by heat treatment under an oxygen atmosphere, an ion implantation method, an ion doping method, a plasma immersion ion implantation method, plasma treatment, or the like. As a gas for adding oxygen, an oxygen gas of ¹⁶O₂, ¹⁸O₂, or the like, a nitrous oxide gas, an ozone gas, or the like can be used.

The concentration of hydrogen in the insulating layers 812 to 819 is preferably low in order to prevent an increase in the concentration of hydrogen in the oxide layer 830. In particular, the concentration of hydrogen in the insulating layers 813 to 818 is preferably low. Specifically, the concentration of hydrogen is lower than or equal to 2×10²⁰ atoms/cm³, preferably lower than or equal to 5×10¹⁹ atoms/cm³, more preferably lower than or equal to 1×10¹⁹ atoms/cm³, more preferably lower than or equal to 5×10¹⁸ atoms/cm³.

The concentration of nitrogen in the insulating layers 813 to 818 is preferably low in order to prevent an increase in the concentration of nitrogen in the oxide layer 830. Specifically, the concentration of nitrogen is lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

The hydrogen concentration and nitrogen concentration are measured by secondary ion mass spectrometry (SIMS).

In the transistor 801, the oxide layer 830 is preferably surrounded by an insulating layer with oxygen and hydrogen barrier properties (hereinafter such an insulating layer is also referred to as a barrier layer). The use of such a structure prevents release of oxygen from the oxide layer 830 and entry of hydrogen into the oxide layer 830. Thus, the reliability and electric characteristics of the transistor 801 can be improved.

For example, the insulating layer 819 functions as a barrier layer and at least one of the insulating layers 811, 812, and 814 functions as a barrier layer. The barrier layer can be formed using a material such as aluminum oxide, aluminum oxynitride, gallium oxide, gallium oxynitride, yttrium oxide, yttrium oxynitride, hafnium oxide, hafnium oxynitride, or silicon nitride.

A structure example of the insulating layers 811 to 818 is described. In this example, each of the insulating layers 811, 812, 815, and 819 functions as a barrier layer. The insulating layers 816 to 818 are oxide layers containing excess oxygen. The insulating layer 811 is formed using silicon nitride. The insulating layer 812 is formed using aluminum oxide. The insulating layer 813 is formed using silicon oxynitride. The insulating layers 814 to 816 functioning as the gate insulating layers on the back gate electrode side are formed using a stack including silicon oxide, aluminum oxide, and silicon oxide. The insulating layer 817 functioning as the gate insulating layer on the front gate side is formed using silicon oxynitride. The insulating layer 818 functioning as the interlayer insulating layer is formed using silicon oxide. The insulating layer 819 is formed using aluminum oxide.

Examples of a conductive material used for the conductive layers 850 to 853 include a metal such as molybdenum, titanium, tantalum, tungsten, aluminum, copper, chromium, neodymium, or scandium; and a metal nitride containing any of the above metals as its component (e.g., tantalum nitride, titanium nitride, molybdenum nitride, or tungsten nitride). A conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added can be used.

A structure example of the conductive layers 850 to 853 is described. The conductive layer 850 is a single layer of tantalum nitride or tungsten. Alternatively, the conductive layer 850 is a stack including tantalum nitride, tantalum, and tantalum nitride. The conductive layer 851 is formed with a single layer of tantalum nitride, or a stack including tantalum nitride and tungsten. The structure of the conductive layer 852 is the same as that of the conductive layer 851. The conductive layer 853 is formed using tantalum nitride. The conductor is formed using tungsten.

In order to reduce the off-state current of the transistor 801, for example, the energy gap of the metal oxide film 822 is preferably large. The energy gap of the metal oxide film 822 is greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

The oxide layer 830 preferably exhibits crystallinity. At least the metal oxide film 822 preferably exhibits crystallinity. With the structure described above, the transistor 801 can have high reliability and favorable electric characteristics.

As the oxide of the metal oxide film 822, for example, an In—Ga oxide, an In—Zn oxide, or an In-M-Zn oxide (M is Al, Ga, Y, or Sn) can be used. The metal oxide film 822 is not limited to the oxide layer containing indium. The metal oxide film 822 can be formed using a Zn—Sn oxide, a Ga—Sn oxide, or a Zn—Mg oxide, for example. The metal oxide films 821, 823, and 824 can be formed using an oxide that is similar to the oxide of the metal oxide film 822. In particular, each of the metal oxide films 821, 823 and 824 can be formed with a Ga oxide.

When an interface state is formed at the interface between the metal oxide film 822 and the metal oxide film 821, a channel formation region is formed also in the vicinity of the interface, which causes a change in the threshold voltage of the transistor 801. It is preferable that the metal oxide film 821 contain at least one of the metal elements contained in the metal oxide film 822 as its component. Accordingly, an interface state is unlikely to be formed at the interface between the metal oxide film 822 and the metal oxide film 821, and variations in the electric characteristics of the transistor 801, such as the threshold voltage, can be reduced.

The metal oxide film 824 preferably contains at least one of the metal elements contained in the metal oxide film 822 as its component because interface scattering is unlikely to occur at the interface between the metal oxide film 822 and the metal oxide film 824, and carrier transfer is not inhibited. Thus, the field-effect mobility of the transistor 801 can be increased.

It is preferable that the metal oxide film 822 have the highest carrier mobility among the metal oxide films 821 to 824. Accordingly, a channel can be formed in the metal oxide film 822 that is apart from the insulating layers 816 and 817.

For example, in a metal oxide containing In such as an In-M-Zn oxide, carrier mobility can be increased by an increase in the In content. In the In-M-Zn oxide, the s orbital of heavy metal mainly contributes to carrier transfer, and when the indium content in the oxide semiconductor is increased, overlaps of the s orbitals of In atoms are increased; therefore, an oxide having a high content of indium has higher mobility than an oxide having a low content of indium. Therefore, an oxide having a high content of indium is used as the metal oxide film, so that carrier mobility can be increased.

Thus, for example, the metal oxide film 822 is formed using an In—Ga—Zn oxide, and the metal oxide films 821 and 823 are formed using a Ga oxide. For example, when the metal oxide films 821 to 823 are formed using an In-M-Zn oxide, the In content of the metal oxide film 822 is made higher than the In content of the metal oxide films 821 and 823. In the case where the In-M-Zn oxide is formed by a sputtering method, the In content can be changed by a change in the atomic ratio of metal elements of a target.

For example, it is preferable that the atomic ratio of metal elements of a target used for depositing the metal oxide film 822 be In:M:Zn=1:1:1, 3:1:2, or 4:2:4.1. For example, it is preferable that the atomic ratio of metal elements of a target used for depositing the metal oxide films 821 and 823 be In:M:Zn=1:3:2, or 1:3:4. The atomic ratio of an In-M-Zn oxide deposited using a target of In:M:Zn=4:2:4.1 is approximately In:M:Zn=4:2:3.

In order that the transistor 801 have stable electric characteristics, it is preferable to reduce the concentration of impurities in the oxide layer 830. In the metal oxide, hydrogen, nitrogen, carbon, silicon, and a metal element other than a main component are impurities. For example, hydrogen and nitrogen form donor states to increase the carrier density. In addition, silicon and carbon form impurity states in the metal oxide. The impurity states serve as traps and might cause the electric characteristics of the transistor to deteriorate.

For example, the oxide layer 830 includes a region where the concentration of silicon is lower than or equal to 2×10¹⁸ atoms/cm³, preferably lower than or equal to 2×10¹⁷ atoms/cm³. The same applies to the concentration of carbon in the oxide layer 830.

The oxide layer 830 includes a region where the concentration of an alkali metal is lower than or equal to 1×10¹⁸ atoms/cm³, preferably lower than or equal to 2×10¹⁶ atoms/cm³. The same applies to the concentration of an alkaline earth metal in the metal oxide film 822.

The oxide layer 830 includes a region where the concentration of nitrogen is lower than 5×10¹⁹ atoms/cm³, preferably lower than 5×10¹⁸ atoms/cm³, more preferably lower than 1×10¹⁸ atoms/cm³, more preferably lower than 5×10¹⁷ atoms/cm³.

The oxide layer 830 includes a region where the concentration of hydrogen is lower than 1×10²⁰ atoms/cm³, preferably lower than 1×10¹⁹ atoms/cm³, more preferably lower than 5×10¹⁸ atoms/cm³, more preferably lower than 1×10¹⁸ atoms/cm³.

The above concentrations of the impurities in the metal oxide film 822 are measured by SIMS.

In the case where the metal oxide film 822 contains oxygen vacancies, donor states are formed by entry of hydrogen into sites of oxygen vacancies in some cases. The oxygen vacancy is a factor in decreasing the on-state current of the transistor 801. Note that sites of oxygen vacancies become more stable by entry of oxygen than by entry of hydrogen. Thus, by reducing oxygen vacancies in the metal oxide film 822, the on-state current of the transistor 801 can be increased in some cases. Consequently, preventing entry of hydrogen into sites of oxygen vacancies by a reduction in hydrogen in the metal oxide film 822 is effective in improving on-state current characteristics.

Hydrogen contained in a metal oxide reacts with oxygen bonded to a metal atom to be water, and thus causes an oxygen vacancy, in some cases. Due to entry of hydrogen into the oxygen vacancy, an electron serving as a carrier is generated in some cases. Furthermore, in some cases, bonding of part of hydrogen to oxygen bonded to a metal atom causes generation of an electron serving as a carrier. Thus, the transistor 801 is likely to be normally-on when the metal oxide film 822 contains hydrogen because the metal oxide film 822 includes a channel formation region. Accordingly, it is preferable that hydrogen in the metal oxide film 822 be reduced as much as possible.

FIGS. 25A to 25C illustrate an example in which the oxide layer 830 has a four-layer structure; however, one embodiment of the present invention is not limited thereto. For example, the oxide layer 830 can have a three-layer structure without the metal oxide film 821 or without the metal oxide film 823. Alternatively, the oxide layer 830 may include one or more metal oxide films that are similar to the metal oxide films 821 to 824 at two or more of the following positions: between given layers in the oxide layer 830, over the oxide layer 830, and below the oxide layer 830.

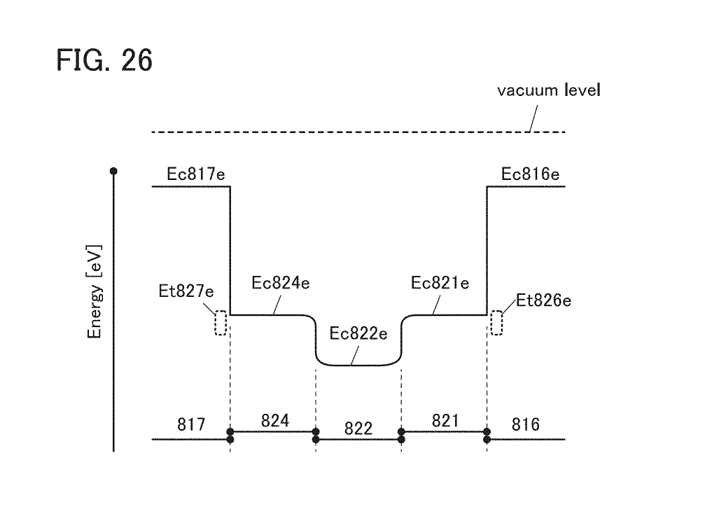

Effects of the stack including the metal oxide films 821, 822, and 824 are described with reference to FIG. 26. FIG. 26 is a schematic diagram showing the energy band structure of a channel formation region of the transistor 801.

In FIG. 26, Ec816e, Ec821e, Ec822e, Ec824e, and Ec817e indicate the energy of the conduction band minimums of the insulating layer 816, the metal oxide film 821, the metal oxide film 822, the metal oxide film 824, and the insulating layer 817, respectively.

Here, the energy difference between the vacuum level and the conduction band minimum (the difference is also referred to as electron affinity) corresponds to a value obtained by subtracting an energy gap from the energy difference between the vacuum level and the valence band maximum (the difference is also referred to as an ionization potential). The energy gap can be measured using a spectroscopic ellipsometer (UT-300 manufactured by HORIBA JOBIN YVON S.A.S.). The energy difference between the vacuum level and the valence band maximum can be measured using an ultraviolet photoelectron spectroscopy (UPS) device (VersaProbe manufactured by ULVAC-PHI, Inc.).

Since the insulating layers 816 and 817 are insulators, Ec816e and Ec817e are closer to the vacuum level than Ec821e, Ec822e, and Ec824e (i.e., the insulating layers 816 and 817 have lower electron affinities than the metal oxide films 821, 822, and 824).

The metal oxide film 822 has a higher electron affinity than the metal oxide films 821 and 824. For example, the difference in electron affinity between the metal oxide films 822 and 821 and the difference in electron affinity between the metal oxide films 822 and 824 are each greater than or equal to 0.07 eV and less than or equal to 1.3 eV, preferably greater than or equal to 0.1 eV and less than or equal to 0.7 eV, more preferably greater than or equal to 0.15 eV and less than or equal to 0.4 eV. Note that the electron affinity refers to an energy difference between the vacuum level and the conduction band minimum.

When voltage is applied to the gate electrode (the conductive layer 850) of the transistor 801, a channel is mainly formed in the metal oxide film 822 having the highest electron affinity among the metal oxide films 821, 822, and 824.

An indium gallium oxide has a small electron affinity and a high oxygen-blocking property. Therefore, the metal oxide film 824 preferably includes an indium gallium oxide. The gallium atomic ratio [Ga/(In+Ga)] is, for example, higher than or equal to 70%, preferably higher than or equal to 80%, more preferably higher than or equal to 90%.

In some cases, there is a mixed region of the metal oxide films 821 and 822 between the metal oxide films 821 and 822. Furthermore, in some cases, there is a mixed region of the metal oxide films 824 and 822 between the metal oxide films 824 and 822. Because the mixed region has a low interface state density, a region with a stack formed with the metal oxide films 821, 822, and 824 has a band structure where energy at each interface and in the vicinity of the interface is changed continuously (continuous junction).

Electrons transfer mainly through the metal oxide film 822 in the oxide layer 830 having such an energy band structure. Therefore, even when an interface state exists at the interface between the metal oxide film 821 and the insulating layer 812 or the interface between the metal oxide film 824 and the insulating layer 813, electron transfer in the oxide layer 830 is less likely to be inhibited and the on-state current of the transistor 801 can be increased.

Although trap states Et826e and Et827e due to impurities or defects might be formed in the vicinity of the interface between the metal oxide film 821 and the insulating layer 816 and the vicinity of the interface between the metal oxide film 824 and the insulating layer 817 as illustrated in FIG. 26, the metal oxide film 822 can be separated from the trap states Et826e and Et827e owing to the existence of the metal oxide films 821 and 824.

Note that when a difference between Ec821e and Ec822e is small, an electron in the metal oxide film 822 might reach the trap state Et826e by passing over the difference in energy. Since the electron is trapped at the trap state Et826e, negative fixed charge is generated at the interface with the insulating film, causing the threshold voltage of the transistor to be shifted in a positive direction. The same applies to the case where a difference in energy between Ec822e and Ec824e is small.

Each of the difference in energy between Ec821e and Ec822e and the difference in energy between Ec824e and Ec822e is preferably greater than or equal to 0.1 eV, more preferably greater than or equal to 0.15 eV so that a change in the threshold voltage of the transistor 801 can be reduced and the transistor 801 can have favorable electric characteristics.

Note that the transistor 801 does not necessarily include a back gate electrode.

### <Example of Stacked-Layer Structure>

Next, a stacked-layer structure of an OS transistor and another transistor is described. A stacked-layer structure described below can be used for various circuits described in any of the above embodiments.

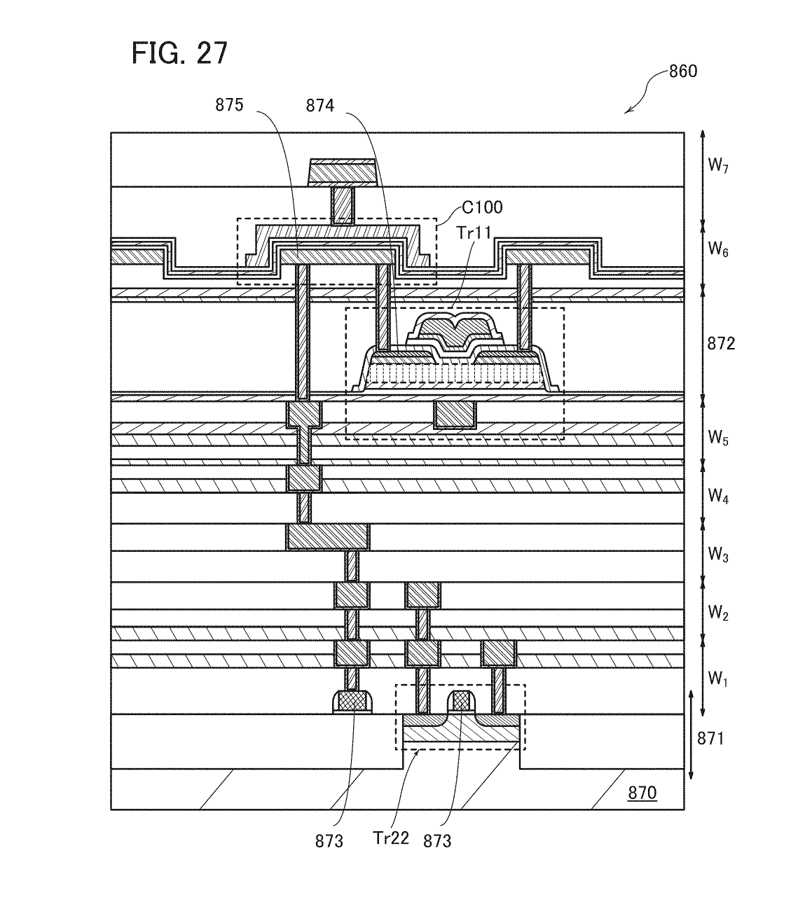

FIG. 27 illustrates an example of a stacked-layer structure of a circuit 860 in which a transistor Tr22 that is a Si Transistor, a transistor Tr11 that is an OS transistor, and a capacitor C100 are stacked.

A memory cell MC includes a stack including a CMOS layer 871, wiring layers W₁ to W₅, a transistor layer 872, and wiring layers W₆ and W₇.

The transistor Tr22 is provided in the CMOS layer 871. A channel formation region of the transistor Tr22 is provided in a single crystal silicon wafer 870. A gate electrode 873 of the transistor Tr22 is connected to one electrode 875 of the capacitor C100 through the wiring layers W₁ to W₅.

The transistor Tr11 is provided in the transistor layer 872. In FIG. 27, the transistor Tr11 has a structure similar to that of the transistor 801 (FIGS. 25A to 25C). An electrode 874 corresponding to one of a source and a drain of the transistor Tr11 is connected to the one electrode 875 of the capacitor C100. Note that in FIG. 27, the transistor Tr11 includes its back gate electrode in the wiring layer W₅. The capacitor C100 is formed in the wiring layer W₆.

The structure of the circuit 860 can be used for a circuit including an OS transistor and other elements (such as an Si transistor and a capacitor) in the above embodiments. For example, the structure can be used for the memory device in FIGS. 14A and 14B, the register 130 in FIG. 16, and the like.

The OS transistor and other components are stacked in this manner, whereby the area of the circuit can be reduced.

### <Metal Oxide>

Next, a metal oxide that can be used in the OS transistor is described. In particular, the details of a metal oxide and a cloud-aligned composite (CAC)-OS are described below.

A CAC-OS or a CAC metal oxide has a conducting function in part of the material and has an insulating function in another part of the material; as a whole, the CAC-OS or the CAC metal oxide has a function of a semiconductor. In the case where the CAC-OS or the CAC metal oxide is used in a channel formation region of a transistor, the conducting function is to allow electrons (or holes) serving as carriers to flow, and the insulating function is to not allow electrons serving as carriers to flow. By the complementary action of the conducting function and the insulating function, the CAC-OS or the CAC metal oxide can have a switching function (on/off function). In the CAC-OS or CAC-metal oxide, separation of the functions can maximize each function.

The CAC-OS or the CAC metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

Furthermore, in the CAC-OS or the CAC metal oxide, the conductive regions and the insulating regions each have a size greater than or equal to 0.5 nm and less than or equal to 10 nm, preferably greater than or equal to 0.5 nm and less than or equal to 3 nm and are dispersed in the material, in some cases.

The CAC-OS or the CAC metal oxide includes components having different bandgaps. For example, the CAC-OS or the CAC metal oxide includes a component having a wide gap due to the insulating region and a component having a narrow gap due to the conductive region. In the case of such a composition, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS or the CAC metal oxide is used in a channel formation region of a transistor, high current drive capability in the on state of the transistor, that is, a high on-state current and high field-effect mobility, can be obtained.

In other words, the CAC-OS or the CAC-metal oxide can be called a matrix composite or a metal matrix composite.

The CAC-OS has, for example, a composition in which elements included in a metal oxide are unevenly distributed. The unevenly distributed elements each have a size greater than or equal to 0.5 nm and less than or equal to 10 nm, preferably greater than or equal to 1 nm and less than or equal to 2 nm, or a similar size. Note that in the following description of a metal oxide, a state in which one or more metal elements are unevenly distributed and regions including the metal element(s) are mixed is referred to as a mosaic pattern or a patch-like pattern. The regions each have a size greater than or equal to 0.5 nm and less than or equal to 10 nm, preferably greater than or equal to 1 nm and less than or equal to 2 nm, or a similar size.

Note that a metal oxide preferably contains at least indium. In particular, indium and zinc are preferably contained. In addition, one or more of aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, of the CAC-OS, an In—Ga—Zn oxide with the CAC composition (such an In—Ga—Zn oxide may be particularly referred to as CAC-IGZO) has a composition in which materials are separated into indium oxide (InO_{X1}, where X1 is a real number greater than 0) or indium zinc oxide (In_{X2}Zn_{Y2}O_{Z2}, where X2, Y2, and Z2 are real numbers greater than 0), and gallium oxide (GaO_{X3}, where X3 is a real number greater than 0), gallium zinc oxide (Ga_{X4}Zn_{Y4}O_{Z4}, where X4, Y4, and Z4 are real numbers greater than 0), or the like, and a mosaic pattern is formed. Then, InO_{X1} or In_{X2}Zn_{Y2}O_{Z2} forming the mosaic pattern is evenly distributed in the film. This composition is also referred to as a cloud-like composition.

That is, the CAC-OS is a composite metal oxide with a composition in which a region including GaO_{X3} as a main component and a region including In_{X2}Zn_{Y2}O_{Z2} or InO_{X1} as a main component are mixed. Note that in this specification, for example, when the atomic ratio of In to an element M in a first region is greater than the atomic ratio of In to an element M in a second region, the first region has higher In concentration than the second region.

Note that a compound including In, Ga, Zn, and O is also known as IGZO. Typical examples of IGZO include a crystalline compound represented by InGaO₃(ZnO)ₘ₁ (m1 is a natural number) and a crystalline compound represented by In₍₁₊ₓ₀₎Ga₍₁₋ₓ₀₎O₃(ZnO)ₘ₀ (−1≦x0≦1; m0 is a given number).

The above crystalline compounds have a single crystal structure, a polycrystalline structure, or a c-axis-aligned crystalline (CAAC) structure. Note that the CAAC structure is a crystal structure in which a plurality of IGZO nanocrystals have c-axis alignment and are connected in the a-b plane direction without alignment.

On the other hand, the CAC-OS relates to the material composition of a metal oxide. In a material composition of a CAC-OS including In, Ga, Zn, and O, nanoparticle regions including Ga as a main component are observed in part of the CAC-OS and nanoparticle regions including In as a main component are observed in part thereof. These nanoparticle regions are randomly dispersed to form a mosaic pattern. Therefore, the crystal structure is a secondary element for the CAC-OS.

Note that in the CAC-OS, a stacked-layer structure including two or more films with different compositions is not included. For example, a two-layer structure of a film including In as a main component and a film including Ga as a main component is not included.

A boundary between the region including GaO_{X3} as a main component and the region including In_{X2}Zn_{Y2}O_{Z2} or InO_{X1} as a main component is not clearly observed in some cases.

In the case where one or more of aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium in a CAC-OS, nanoparticle regions including the selected metal element(s) as a main component(s) are observed in part of the CAC-OS and nanoparticle regions including In as a main component are observed in part thereof, and these nanoparticle regions are randomly dispersed to form a mosaic pattern in the CAC-OS.

The CAC-OS can be formed by a sputtering method under conditions where a substrate is not heated intentionally, for example. In the case of forming the CAC-OS by a sputtering method, one or more selected from an inert gas (typically, argon), an oxygen gas, and a nitrogen gas may be used as a deposition gas. The ratio of the flow rate of an oxygen gas to the total flow rate of the deposition gas at the time of deposition is preferably as low as possible, and for example, the flow ratio of an oxygen gas is preferably higher than or equal to 0% and lower than 30%, more preferably higher than or equal to 0% and low than or equal to 10%.

The CAC-OS is characterized in that no clear peak is observed in measurement using θ/2θ scan by an out-of-plane method, which is an X-ray diffraction (XRD) measurement method. That is, X-ray diffraction shows no alignment in the a-b plane direction and the c-axis direction in a measured region.

In an electron diffraction pattern of the CAC-OS which is obtained by irradiation with an electron beam with a probe diameter of 1 nm (also referred to as a nanometer-sized electron beam), a ring-like region with high luminance and a plurality of bright spots in the ring-like region are observed. Therefore, the electron diffraction pattern indicates that the crystal structure of the CAC-OS includes a nanocrystal (nc) structure with no alignment in plan-view and cross-sectional directions.

For example, an energy dispersive X-ray spectroscopy (EDX) mapping image confirms that an In—Ga—Zn oxide with the CAC composition has a structure in which a region including GaO_{X3} as a main component and a region including In_{X2}Zn_{Y2}O_{Z2} or InO_{X1} as a main component are unevenly distributed and mixed.

The CAC-OS has a structure different from that of an IGZO compound in which metal elements are evenly distributed, and has characteristics different from those of the IGZO compound. That is, in the CAC-OS, regions including GaO_{X3} or the like as a main component and regions including In_{X2}Zn_{Y2}O_{Z2} or InO_{X1} as a main component are separated to form a mosaic pattern.

The conductivity of a region including In_{X2}Zn_{Y2}O_{Z2} or InO_{X1} as a main component is higher than that of a region including GaO_{X3} or the like as a main component. In other words, when carriers flow through regions including In_{X2}Zn_{Y2}O_{Z2} or InO_{X1} as a main component, the conductivity of an oxide semiconductor is exhibited. Accordingly, when regions including In_{X2}Zn_{Y2}O_{Z2} or InO_{X1} as a main component are distributed in an oxide semiconductor like a cloud, high field-effect mobility (μ) can be achieved.

In contrast, the insulating property of a region including GaO_{X3} or the like as a main component is higher than that of a region including In_{X2}Zn_{Y2}O_{Z2} or InO_{X1} as a main component. In other words, when regions including GaO_{X3} or the like as a main component are distributed in an oxide semiconductor, leakage current can be suppressed and favorable switching operation can be achieved.

Accordingly, when a CAC-OS is used for a semiconductor element, the insulating property derived from GaO_{X3} or the like and the conductivity derived from In_{X2}Zn_{Y2}O_{Z2} or InO_{X1} complement each other, whereby high on-state current (Ion) and high field-effect mobility (μ) can be achieved.

A semiconductor element including a CAC-OS has high reliability. Thus, the CAC-OS is suitably used in a variety of semiconductor devices.

This embodiment can be combined with any of the other embodiments as appropriate.

### Embodiment 7

In this embodiment, a structure example of a display module including any of the display devices described in the above embodiments will be described.

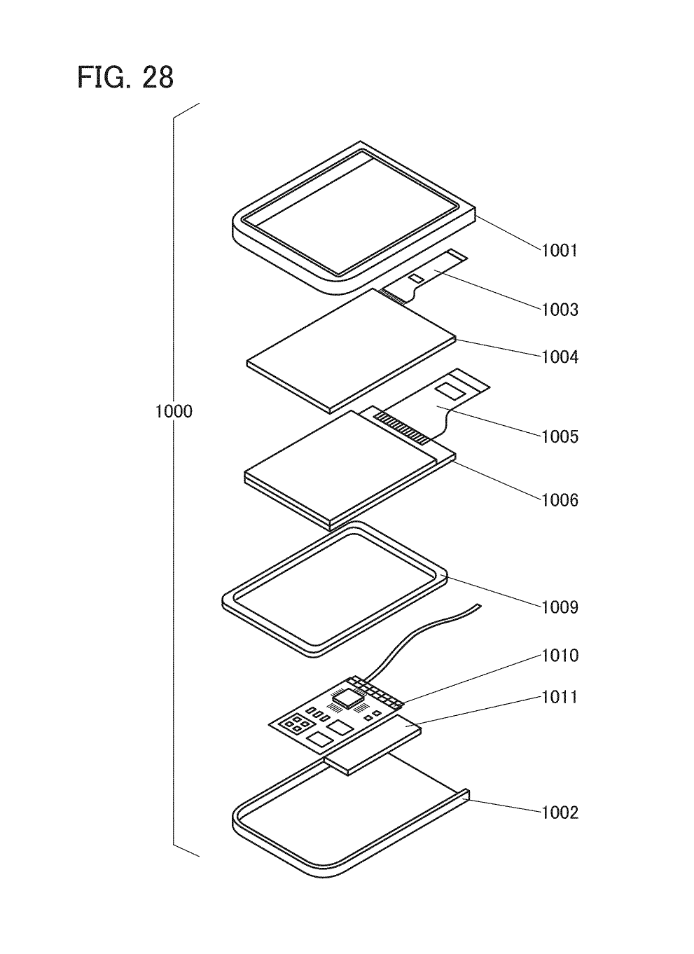

In a display module 1000 illustrated in FIG. 28, a touch panel 1004 connected to an FPC 1003, a display device 1006 connected to an FPC 1005, a frame 1009, a printed circuit board 1010, and a battery 1011 are provided between an upper cover 1001 and a lower cover 1002.

The display device described in the above embodiment can be used as the display device 1006.

The shapes and sizes of the upper cover 1001 and the lower cover 1002 can be changed as appropriate in accordance with the sizes of the touch panel 1004 and the display device 1006.

The touch panel 1004 can be a resistive touch panel or a capacitive touch panel and may be formed to overlap with the display device 1006. Instead of providing the touch panel 1004, the display device 1006 can have a touch panel function.

The frame 1009 protects the display device 1006 and also functions as an electromagnetic shield for blocking electromagnetic waves generated by the operation of the printed circuit board 1010. The frame 1009 may also function as a radiator plate.

The printed circuit board 1010 is provided with a power supply circuit and a signal processing circuit for outputting a video signal and a clock signal. As a power source for supplying power to the power supply circuit, an external commercial power source or a power source using the battery 1011 provided separately may be used. The battery 1011 can be omitted in the case of using a commercial power source.

The display module 1000 may be additionally provided with a member such as a polarizing plate, a retardation plate, or a prism sheet.

This embodiment can be combined with any of the other embodiments as appropriate.

### Embodiment 8

In this embodiment, electronic devices to which the display system of one embodiment of the present invention can be applied will be described.

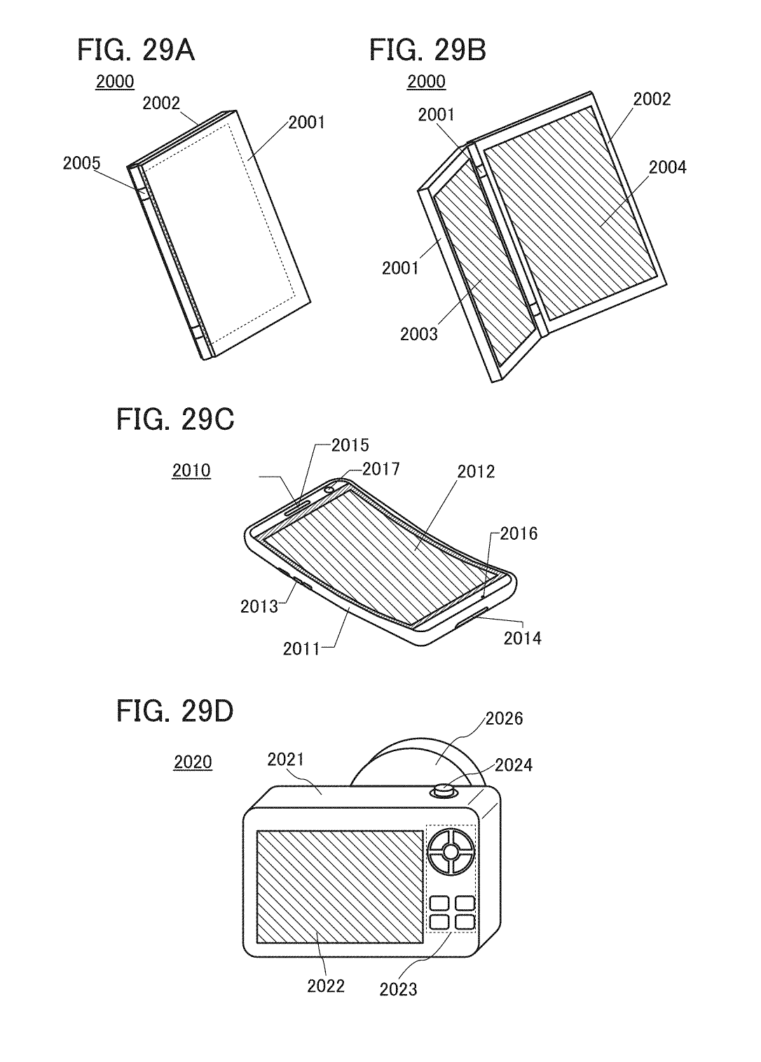

The display device of one embodiment of the present invention can achieve high visibility regardless of the intensity of external light. Therefore, the display device of one embodiment of the present invention can be favorably used in portable electronic devices, wearable electronic devices (wearable devices), e-book readers, and the like. FIGS. 29A to 29D illustrate examples of an electronic device including the display device of one embodiment of the present invention.

FIGS. 29A and 29B illustrate an example of a portable information terminal 2000. The portable information terminal 2000 includes a housing 2001, a housing 2002, a display portion 2003, a display portion 2004, a hinge portion 2005, and the like.

The housing 2001 and the housing 2002 are connected with the hinge portion 2005. The portable information terminal 2000 folded as in FIG. 29A can be changed into the state illustrated in FIG. 29B, in which the housing 2001 and the housing 2002 are opened.

For example, the portable information terminal 2000 can also be used as an e-book reader, in which the display portion 2003 and the display portion 2004 can each display text data. In addition, the display portion 2003 and the display portion 2004 can each display a still image or a moving image. Furthermore, the display portion 2003 may be provided with a touch panel.

In this manner, the portable information terminal 2000 has high versatility because it can be folded when carried.

Note that the housing 2001 and the housing 2002 may include a power switch, an operation button, an external connection port, a speaker, a microphone, and/or the like.

Note that the portable information terminal 2000 may have a function of identifying a character, a figure, or an image using a touch sensor provided in the display portion 2003. In that case, learning in the following mode becomes possible, for example: an answer is written with a finger, a stylus pen, or the like on an information terminal that displays a workbook or the like for studying mathematics or for learning language, and then the portable information terminal 2000 determines whether the answer is correct or not. The portable information terminal 2000 may have a function of performing speech interpretation. In that case, for example, the portable information terminal 2000 can be used in learning a foreign language. Such a portable information terminal is suitable for use as a teaching material such as a textbook, a notebook, or the like.

Note that the touch information obtained by the touch sensor of the display portion 2003 can be used for prediction of the necessity of power supply by the semiconductor device according to one embodiment of the present invention.

FIG. 29C illustrates an example of a portable information terminal. A portable information terminal 2010 illustrated in FIG. 29C includes a housing 2011, a display portion 2012, an operation button 2013, an external connection port 2014, a speaker 2015, a microphone 2016, a camera 2017, and the like.

The portable information terminal 2010 includes a touch sensor in the display portion 2012. Operations such as making a call and inputting a letter can be performed by touch on the display portion 2012 with a finger, a stylus, or the like.

With the operation button 2013, power on or off can be switched. In addition, types of images displayed on the display portion 2012 can be switched; for example, switching images from a mail creation screen to a main menu screen is performed.

When a sensing device such as a gyroscope sensor or an acceleration sensor is provided inside the portable information terminal 2010, the direction of display on the screen of the display portion 2012 can be automatically changed by determining the orientation of the portable information terminal 2010 (whether the portable information terminal 2010 is placed horizontally or vertically). Furthermore, the direction of display on the screen can be changed by touch on the display portion 2012, operation with the operation button 2013, sound input using the microphone 2016, or the like.

The portable information terminal 2010 functions as, for example, one or more of a telephone set, a notebook, and an information browsing system. For example, the portable information terminal 2010 can be used as a smartphone. The portable information terminal 2010 is capable of executing a variety of applications such as mobile phone calls, e-mailing, viewing and editing texts, music reproduction, reproducing a moving image, Internet communication, and computer games, for example.

FIG. 29D illustrates an example of a camera. A camera 2020 includes a housing 2021, a display portion 2022, operation buttons 2023, a shutter button 2024, and the like. Furthermore, a detachable lens 2026 is attached to the camera 2020.

Although the lens 2026 of the camera 2020 here is detachable from the housing 2021 for replacement, the lens 2026 may be included in the housing.

Still and moving images can be taken with the camera 2020 at the press of the shutter button 2024. In addition, images can be taken at the touch of the display portion 2022 which serves as a touch panel.

Note that a stroboscope, a viewfinder, and the like can be additionally attached to the camera 2020. Alternatively, these components may be included in the housing 2021.

The display system described in the above embodiments can be provided in the electronic devices shown in FIGS. 29A to 29D. The display portion described in the above embodiments can be used as the display portion in each of the electronic devices in FIGS. 29A to 29D. Thus, the display system of one embodiment of the present invention can be mounted on the electronic device.

Note that the prediction circuit 112 in FIG. 1 and other drawings may be provided outside of the electronic device. In this case, prediction results by the prediction circuit 112 are input to the electronic device.

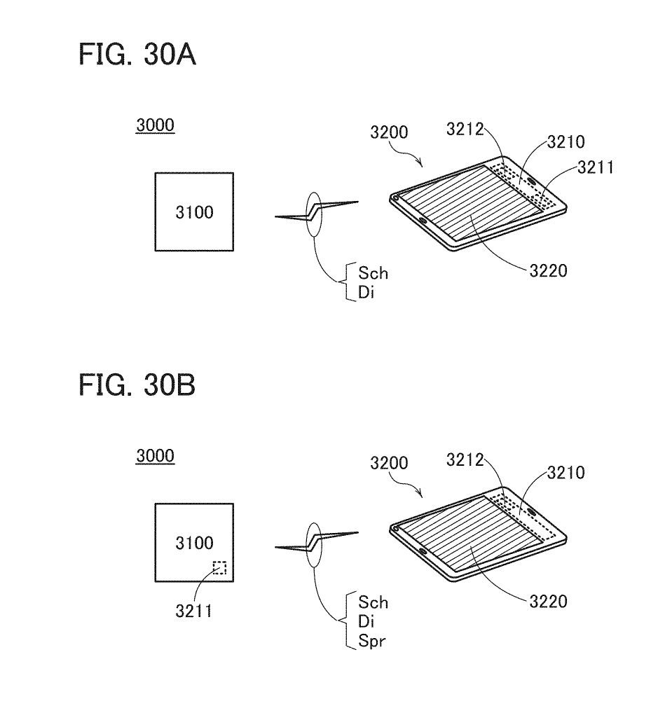

FIGS. 30A and 30B show examples of communication system composed of the electronic device and a host. A communication system 3000 shown in FIG. 30A is composed of a host 3100 and an electronic device 3200. The electronic device 3200 includes a control portion 3210 and a display portion 3220 which respectively correspond to the semiconductor device and the display portion described in the above embodiments. In other words, the display system of one embodiment of the present invention is mounted on the electronic device 3200. A prediction circuit 3211 and an interface 3212 which are one embodiment of the present invention are included in the control portion 3210.

The host 3100 transmits the data Di corresponding to video displayed on the display portion 3220 and the signal Sch showing the presence or absence of a change of the video displayed on the display portion 3220. The data Di and the signal Sch are transmitted with or without wire.

The electronic device 3200 receives the data Di and the signal Sch using the interface 3212 in the control portion 3210. Then, the electronic device 3200 controls display on the display portion 3220 using the data Di. The signal Sch is input to the prediction circuit 3211 and used for the learning with a neural network.

Note that the prediction circuit 3211 may be provided in the host 3100 as in FIG. 30B. In this case, prediction by a neural network is performed in the host 3100, so that the signal Spr corresponding to the prediction results is transmitted together with the data Di and the signal Sch. Then, the electronic device 3200 receives the signal Spr using the interface 3212 and controls power supply in the control portion 3210. The signal Sco or the signal Sto obtained in the control portion 3210 is transmitted from the electronic device 3200 to the host 3100 via the interface 3212. Then, the host 3100 preforms prediction.

This embodiment can be combined with any of the other embodiments as appropriate.

This application is based on Japanese Patent Application serial No. 2016-139038 filed with Japan Patent Office on Jul. 14, 2016, the entire contents of which are hereby incorporated by reference.

What is claimed is:

1. A semiconductor device comprising:
a controller;
a frame memory; and
a register,
wherein the controller comprises a control circuit and a prediction circuit,
wherein the frame memory comprises a memory device and a monitor circuit,
wherein the register comprises a first memory circuit and a second memory circuit,
wherein the second memory circuit comprises a transistor which includes a metal oxide in a channel formation region,
wherein the prediction circuit is configured to predict the necessity of power supply to the register using a neural network and to output a first signal corresponding to a result of the prediction to the control circuit,
wherein the control circuit is configured to save data stored in the first memory circuit to the second memory circuit on the basis of the first signal,
wherein the monitor circuit is configured to output a second signal containing information on power consumption of the memory device to the prediction circuit, and
wherein the prediction is performed using the second signal as input data.

2. The semiconductor device according to claim 1,
wherein the neural network is configured to perform learning with use of a learning signal and a teacher signal,
wherein the learning signal is the second signal, and
wherein the teacher signal is a third signal containing information on a change of a video image displayed on a display portion.

3. The semiconductor device according to claim 2,
wherein the neural network is configured to perform the learning when the prediction is wrong.

4. The semiconductor device according to claim 1,
wherein the neural network comprises a neuron circuit and a synapse circuit,
wherein the synapse circuit comprises an analog memory, and
wherein the analog memory comprises a transistor comprising a metal oxide in a channel formation region.

5. A display system comprising:
a control portion using the semiconductor device according to claim 1; and
a display portion,
wherein the control portion is configured to control display on the display portion,
wherein the display portion comprises a first display unit and a second display unit,
wherein the first display unit comprises a reflective liquid crystal element, and
wherein the second display unit comprises a light-emitting element.

6. The display system according to claim 5,
wherein each of the first display unit and the second display unit comprises a transistor comprising a metal oxide in a channel formation region.

7. An electronic device comprising:
the display system according to claim 5,
wherein the electronic device is configured to generate a video signal in response to image data input from the outside and to display video on the basis of the video signal.
